(19) United States
(12) Patent Application Publication
(10) Pub. No.: US 2015/0104636 A1
(43) Pub. Date: Apr. 16, 2015

(54) METHOD FOR MANUFACTURING TRANSPARENT CONDUCTIVE FILM, TRANSPARENT CONDUCTIVE FILM, AND ELECTRONIC DEVICE

(71) Applicant: Konica Minolta, Inc., Tokyo (JP)

(72) Inventor: Chiyoko Takemura, Tokyo (JP)

(73) Assignee: Konica Minolta, Inc., Tokyo (JP)

(21) Appl. No.: 14/395,124

(22) PCT Filed: Apr. 15, 2013
(86) PCT No.: PCT/JP2013/061168

§ 371 Date: Oct. 17, 2014

(30) Foreign Application Priority Data
Apr. 19, 2012 (JP) 2012-095513

(51) Int. Cl. H01L 51/52; H01L 51/00

(52) U.S. Cl. CPC H01L 51/5215; H01L 51/0094; H01L 51/0072; H01L 51/0021; H01L 51/5234; H01L 51/5253; H01L 2251/558
USPC 428/336; 428/447; 204/157.74; 427/125; 427/535; 427/558

(57) ABSTRACT

A method for manufacturing a transparent conductive film, said method comprising: forming a compound layer containing a silazane compound on a substrate; supplying energy to the compound layer and thus converting at least a part of the silazane compound into a compound having a siloxane bond to thereby modify the compound layer; and then forming a metal layer, that is configured from silver or an alloy comprising silver as the main component, on the unmodified compound layer or the modified compound layer.

### TECHNICAL FIELD

The present invention relates to a method for manufacturing a transparent conductive film, and to a transparent conductive film and an electronic device provided with the same.

### BACKGROUND ART

In recent years, in various electronic devices such as a liquid crystal display element (LCD), photovoltaic (PV) and organic electroluminescence element (hereinafter, described as an organic EL element), weight saving and flexibility of electronic devices are required from the viewpoint of improving the safety, actualizing cost reduction, expanding the application range thereof and the like. In order to give flexibility to these electronic devices, it is necessary to use a plastic base material instead of a glass base material having been used conventionally as a base material of an electronic device. Furthermore, for example, when an organic EL element is used as light sources for backlight of various displays, for display boards such as a signboard and an emergency lamp, and for lighting, the use of a transparent electrode (transparent conductive film) as an electrode is necessary in order to extract the light having been caused to perform surface emission.

As a material for forming a transparent electrode, generally, an oxide semiconductor-based material such as indium-tin oxide (SnO₂—In₂O₃:ITO) is used, but ITO contains indium being a rare metal. Therefore, in the transparent electrode, there are such problems that material cost is high and an annealing treatment at around 300° C. is necessary after the film formation in order to reduce the resistance, and the like. Furthermore, there is also a problem in which further reduction in the resistance value of a transparent electrode is necessary in order to expand the area of an organic EL element, but that ITO has limitations in the reduction of the resistance value.

Consequently, in order to reduce the resistance of a transparent electrode, various technologies are conventionally proposed (for example, see Patent Literatures 1 to 3).

In Patent Literature 1, a technology of forming a transparent electrode by laminating a transparent high refractive index thin film layer formed of ITO and a transparent metal thin film layer formed of silver or a silver alloy is proposed. In Patent Literature 2, a technology of forming a transparent electrode by laminating a silver oxide-based thin film and a second transparent electrode film formed of ITO in this order on a first transparent electrode film, for example, formed of ITO is proposed. In Patent Literature 3, a technology of constituting a transparent electrode with an alloy thin film containing silver and aluminum as main components is proposed. In Patent Literature 3, conductivity is secured with a film thickness thinner than the thickness of a single silver film in the transparent electrode by the technology to thereby achieve both the securement of light transmittance and the reduction in resistance.

### CITATION LIST

### Patent Literature

PTL 1: Japanese Patent Application Laid-Open No. 2002-15623
PTL 2: Japanese Patent Application Laid-Open No. 2006-164961
PTL 3: Japanese Patent Application Laid-Open No. 2009-151963

### SUMMARY OF INVENTION

### Technical Problem

As described above, conventionally, transparent electrodes (transparent conductive film) of various configurations have been proposed. However, for example, in technologies proposed in Patent Literatures 1 and 2, ITO is used as one of materials for forming a transparent electrode, and thus the above-mentioned problems of ITO remain. Furthermore, in technology proposed in Patent Literature 3, since aluminum contained in the transparent electrode is easily oxidized and aluminum oxide generated after the oxidation serves as a very high resistive body, there is a problem of the increase in resistance of the transparent electrode at the time of the electrode production and/or due to change with the passage of time.

Furthermore, conventionally, the use of a metal thin film formed of silver or the like having a high electric conductivity has been examined as a transparent electrode. However, it is generally known that a silver thin film, for example, having a thickness of 10 nm or less is not a uniformly continuous film but becomes a film of a discontinuous island structure. Therefore, in order to make a silver thin film function as a conductive film, it is necessary to make the thickness thereof be thick to some extent (for example, 15 nm or more). However, in this case, the securement of light transmission property becomes difficult.

If a silver thin film can be formed as a uniformly continuous film even when the thickness thereof is 10 nm or less, a transparent electrode provided with both low resistance and light transmission property is obtained and thus the problem of a silver thin film is solved. However, until now, practically a sufficient suggestion has not been proposed about such a technology.

Furthermore, it is known generally that, when a voltage is applied to a silver electrode under an environment of high humidity, ion migration arises easily by an electrolysis action in the silver electrode. When the ion migration arises in the silver electrode, a wiring short circuit may arise. Therefore, under the present conditions where the utilization of a plastic base material is required as the base material of an electronic device as described above, the suppression of moisture permeation from the base material at a high level is necessary in order to stably maintain a silver thin film.

The present invention has been made in consideration of the above situation. An object of the present invention is to provide a method for manufacturing a transparent conductive film that has both sufficient conductivity and light transmission property and that is excellent in property stability (excellent in water vapor barrier property), a transparent conductive film, and an electronic device provided with the same.

### Solution to Problem

In order to solve the problem, the method for manufacturing a transparent conductive film of the preset invention is carried out according to the following procedure. First, a compound layer containing a silazane compound is formed on a base material. Subsequently, the compound layer is modified by supply of energy to the compound layer and by conversion of at least a part of the silazane compound into a compound having a siloxane bond. In addition, on the compound layer before the modification or on the compound layer after the modification, a metal film is formed of silver or an alloy containing silver as the main component, and has transparency is formed.

Furthermore, the transparent conductive film of the present invention is a transparent conductive film that is manufactured by the method for manufacturing a transparent conductive film of the present invention, and includes the base material, the modified compound layer provided on the base material, and the metal layer provided on the modified compound layer. In addition, the modified compound layer contains a compound having a siloxane bond obtained by modifying the silazane compound. Furthermore, the metal layer is formed of silver or an alloy containing silver as the main component, and has transparency.

Moreover, the electronic device of the present invention includes the transparent conductive film of the present invention.

### Advantageous Effects of Invention

As described above, in the method for manufacturing a transparent conductive film of the present invention, energy is supplied to the compound layer that is formed between the base material and the metal layer and that contains a silazane compound, and the compound layer is modified by conversion of at least a part of the silazane compound into a compound having a siloxane bond. Therefore, according to the present invention, a transparent conductive film that has both sufficient conductivity and light transmission property and that is excellent in property stability (excellent in water vapor barrier property), and an electronic device provided with the same can be obtained.

### BRIEF DESCRIPTION OF DRAWINGS

FIG. 1 is a schematic configuration cross-sectional view of the transparent conductive film according to a first embodiment of the present invention.

FIGS. 2A to 2C are process charts illustrating a procedure of manufacturing technique of the transparent conductive film according to the first embodiment.

FIGS. 3A to 3C are process charts illustrating another procedure of manufacturing technique (modification 1) of the transparent conductive film according to the first embodiment.

FIGS. 4A to 4D are process charts illustrating another procedure of manufacturing technique (modification 2) of the transparent conductive film according to the first embodiment.

FIG. 5 is a schematic configuration cross-sectional view of the transparent conductive film according to a second embodiment of the present invention.

FIGS. 6A to 6D are process charts illustrating a procedure of manufacturing technique of the transparent conductive film according to the second embodiment.

FIG. 7 is a schematic configuration cross-sectional view of the electronic device (organic EL element) according to a third embodiment of the present invention.

FIG. 8 is a schematic configuration cross-sectional view of the electronic device of a modification 3.

### DESCRIPTION OF EMBODIMENTS

Hereinafter, the transparent conductive film according to the embodiment of the present invention and the method for manufacturing the same, and an example of an electronic device provided with the transparent conductive film according to the embodiment of the present invention will be explained in the order described below, with reference to the drawings. Meanwhile, the technical scope of the present invention should be determined on the basis of the description of the claims, and is not limited to the following embodiments. Furthermore, the dimensional ratio of respective portions illustrated in the drawings is exaggerated for convenience of explanation, and may be different from an actual dimensional ratio.

1. First embodiment: a first configuration example of transparent conductive film

2. Second embodiment: a second configuration example of transparent conductive film

3. Third embodiment: a configuration example of an electronic device

4. Various Examples

### 1. First Embodiment

### First Configuration Example of Transparent Conductive Film

### [Whole Configuration of Transparent Conductive Film]

In FIG. 1, a schematic configuration cross-sectional view of the transparent conductive film according to a first embodiment is illustrated. Meanwhile, “transparent” mentioned in the present description means that light transmittance at a wavelength of 550 nm is 50% or more.

A transparent conductive film 10 is provided with a base material 11, a modified compound layer 12 and a metal layer 13 as illustrated in FIG. 1. Furthermore, in the embodiment, the modified compound layer 12 and the metal layer 13 are laminated in this order on one surface of the base material 11. Meanwhile, although not illustrated in FIG. 1, on the surface on the modified compound layer 12 side of the base material 11, a bleed-out preventing layer may be provided. The bleed-out preventing layer is a layer for preventing the precipitation of various addition agents incorporated in the base material 11 on the surface of the base material 11 along with the lapse of time. Meanwhile, the configuration of respective portions will be described later in detail.

### [Manufacturing Technique of Transparent Conductive Film]

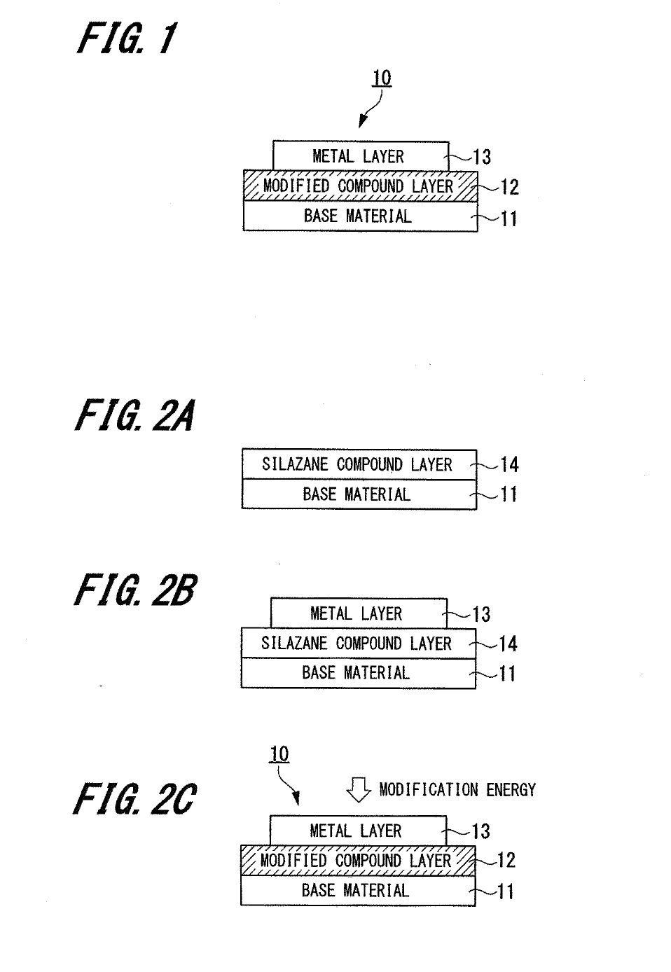

Here, one example of the manufacturing technique of the transparent conductive film 10 of the present embodiment will be explained simply while referring to FIGS. 2A to 2C. Meanwhile, FIGS. 2A to 2C are diagrams illustrating the procedure of the manufacturing process of the transparent conductive film 10, and each diagram is a schematic configuration cross-sectional view of a laminated member at the time of completion of respective processes. More detailed treatment conditions and the like in respective manufacturing processes will be explained in detailed explanations of respective portions to be described later.

First, the base material 11 having a bleed out-preventing layer (not illustrated) provided on the surface is prepared. Next, a coating liquid containing a silazane compound is coated on the surface on the bleed-out preventing layer side of the base material 11. Then, a silazane compound layer 14 (compound layer) having a prescribed thickness is formed by drying the coating liquid coated onto the base material 11 (a state in FIG. 2A).

Subsequently, the metal layer 13 constituted of silver (Ag) or an alloy containing silver as the main component is formed on the silazane compound layer 14 (a state in FIG. 2B). At this time, in the present embodiment, the metal layer 13 is formed on the silazane compound layer 14 by a conventionally known technique, and the thickness thereof is set, for example, to be about 4 to 12 nm, preferably about 4 to 9 nm.

In addition, at least a part of the silazane compound in the silazane compound layer 14 (layer to be modified) is modified by giving energy such as light, plasma or heat (hereinafter, referred to as modification energy) to a laminated member (laminated body) in which the silazane compound layer 14 and the metal layer 13 have been formed on the base material 11, and thus the modified compound layer 12 is generated (a state in FIG. 2C).

In the present embodiment, the transparent conductive film 10 is produced in this way. Meanwhile, in the modification treatment of the silazane compound layer 14, at least a part of the silazane compound in the silazane compound layer 14 is converted into a compound having a siloxane bond (such as a silicon oxynitride compound).

In the manufacturing technique of the transparent conductive film 10 in the present embodiment, as described above, the metal layer 13 of a thin film is formed on the silazane compound layer 14. At this time, aggregation of silver is suppressed by the interaction between silver in the metal layer 13 and a compound having a nitrogen atom in the silazane compound layer 14. As the result, in the present embodiment, the metal layer 13 that is a uniform thin film (continuous film) can be formed stably on the silazane compound layer 14, and the metal layer 13 that is excellent in both conductivity and light transmission property can be obtained. Meanwhile, the effect will be described in detail later.

Furthermore, in the manufacturing technique of the transparent conductive film 10 of the present embodiment, as described above, the modified compound layer 12 is generated by subjecting the silazane compound layer 14 to a modification treatment. In this case, the denseness of the modified compound layer 12 can be improved, and water vapor barrier property can be imparted to the modified compound layer 12. That is, in the manufacturing technique of the present embodiment, the transparent conductive film 10 having both sufficient conductivity and light transmission property, and having high property stability (excellent also in water vapor barrier property) can be produced.

[Modifications of Manufacturing Technique]

The manufacturing technique of the transparent conductive film 10 of the present embodiment is not limited to the example illustrated in FIGS. 2A to 2C. For example, the modification treatment may be carried out for a laminated member before laminating the metal layer 13 on the silazane compound layer 14 (modification 1). Furthermore, for example, the modification treatment may be executed for each of laminated members before and after laminating the metal layer 13 on the silazane compound layer 14 (modification 2).

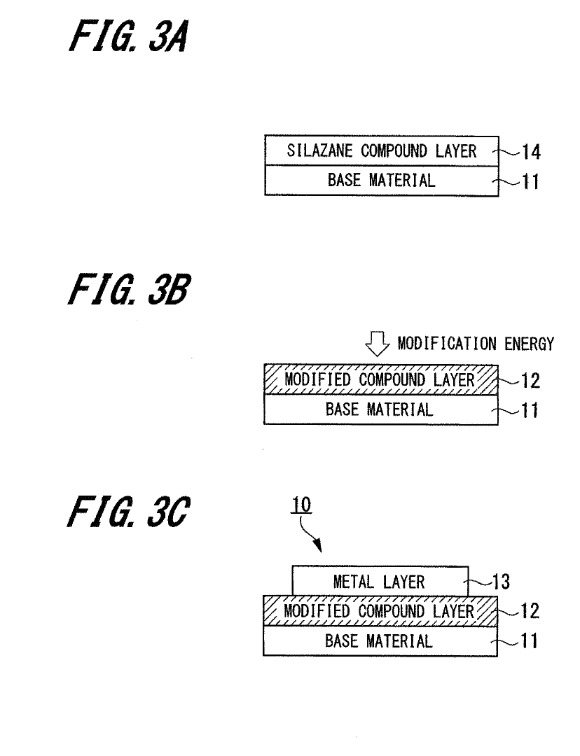

In FIGS. 3A to 3C, the procedure of manufacturing process of the transparent conductive film 10 in the modification 1 is illustrated. Meanwhile, each drawing of FIGS. 3A to 3C is a schematic configuration cross-sectional view of a laminated member at the time of completion of respective processes.

In the modification 1, first, in the same way as that in the above-described embodiment, the silazane compound layer 14 is formed on the surface on the bleed-out preventing layer (not illustrated) side of the base material 11 (a state in FIG. 3A).

Subsequently, the modification energy is given to the laminated member in which the silazane compound layer 14 is formed on the base material 11, and modification of at least apart of the silazane compound generates the modified compound layer 12 (a state in FIG. 3B).

In addition, the metal layer 13 constituted of silver or an alloy containing silver as the main component is formed on the modified compound layer 12 (a state in FIG. 3C). In the modification 1, the transparent conductive film 10 is produced in this way.

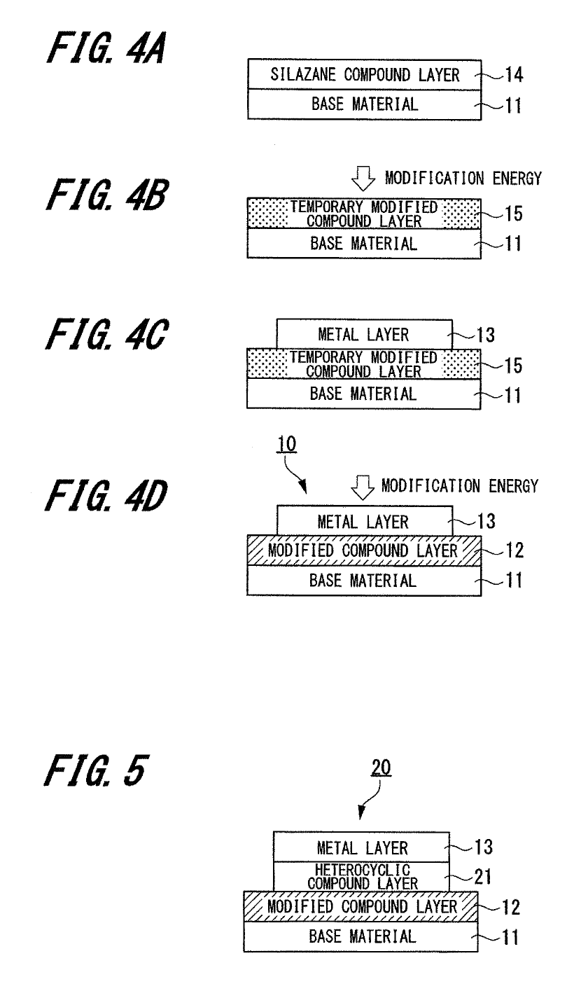

Furthermore, in FIGS. 4A to 4D, the procedure of the manufacturing process of the transparent conductive film 10 in the modification 2 is illustrated. Meanwhile, each drawing of FIGS. 4A to 4D is a schematic configuration cross-sectional view of the laminated member at the time of completion of respective processes.

In the modification 2, first, in the same way as that in the above-described embodiment, the silazane compound layer 14 is formed on the surface on the bleed-out preventing layer (not illustrated) side of the base material 11 (a state in FIG. 4A).

Subsequently, the modification energy is supplied to the laminated member in which the silazane compound layer 14 is formed on the base material 11, and a first modification treatment for the silazane compound layer 14 generates a modified compound layer 15 of the silazane compound layer 14 (a state in FIG. 4B). Meanwhile, the first modification treatment aims at making the silazane compound layer 14 flat, and it is assumed that the first modification treatment is carried out to the extent that the surface layer of the silazane compound layer 14 is not completely modified. Consequently, the modified compound layer 15 produced by the first modification treatment is generated in a state where a certain degree of nitrogen is left on the surface layer thereof, and then close adherence to a layer to be formed in the upper portion thereof is ensured.

Subsequently, the metal layer 13 constituted of silver or an alloy containing silver as the main component is formed on the modified compound layer 15 by the first modification treatment (a state in FIG. 4C). Then, the modification energy is given again to the laminated member in which the modified compound layer 15 and the metal layer 13 are formed on the base material 11, and a second modification treatment for the modified compound layer 15 generates the modified compound layer 12 obtained by further advancing the modification of the modified compound layer 15 (a state in FIG. 4D). In the modification 2, the transparent conductive film 10 is produced in this way.

Also in manufacturing techniques in above-described modifications 1 and 2, the transparent conductive film 10 of the present embodiment can be produced and the same effect can be obtained. In particular, as is the case of modifications 1 and 2, when a laminated member is subjected to the modification treatment (in the case of the modification 2, the first modification treatment) before lamination of the metal layer 13, a uniform metal film can be obtained more stably, and as the result, a laminated body can be produced more stably also in the laminating process subsequent to it.

[Details of Configurations of Respective Portions and Modification Treatment]

Next, respective portions constituting the transparent conductive film 10 will be explained in more detail.

(1) Base Material

The base material 11 can be constituted of any base material only if it is a base material having transparency. Meanwhile, in the present embodiment, the base material 11 is preferably constituted of a resin film excellent in flexibility and light transmission property.

As the resin film, a resin film formed of a material such as acrylic acid ester, methacrylic acid ester, polyethylene terephthalate (PET), polybutylene terephthalate, polyethylene naphthalate (PEN), polycarbonate (PC), polyarylate, polyvinyl chloride (PVC), polyethylene (PE), polypropylene (PP), polystyrene (PS), nylon (Ny), aromatic polyamide, polyether ether ketone, polysulfone, polyether sulfone, polyimide or polyetherimide can be used. In addition, as the resin film, a heat-resistant transparent film formed of a material having silsesquioxane as the basic skeleton and has an organic-inorganic hybrid structure (for example, Sila-DEC (registered trademark): manufactured by CHISSO CORPORATION) or the like can also be used.

Among the above various films, from the viewpoints of cost and ease of availability, the use of a resin film formed of polyethylene terephthalate (PET), polybutylene terephthalate, polyethylene naphthalate (PEN) or polycarbonate (PC) is preferable. Furthermore, from the viewpoints of optical transparency, heat-resisting properties and the like, the use of a heat-resistant transparent film having an organic-inorganic hybrid structure as a resin film is preferable. Meanwhile, in the present embodiment, each of above-described various films may be used alone or in combination of two or more kinds thereof.

Moreover, the base material 11 using above-described various resin films may be a non-stretched film, or may be a stretched film. In this case, the resin film can be manufactured by a conventionally known general technique. A non-stretched film that is substantially amorphous and has no orientation can be manufactured, for example, by melting a resin to be the material with an extruder, extruding the molten resin with a ring die or a T die, and after that, cooling the same rapidly. Furthermore, a stretched film can be manufactured by stretching the non-stretched film in the flow (longitudinal axis) direction of the resin base material or the direction orthogonal to the flow direction (horizontal direction) of the resin base material through the use of a known technique such as uniaxial stretching, tenter style sequential biaxial stretching, tenter style simultaneous biaxial stretching or tubular type simultaneous biaxial stretching. The stretching magnification in this case can be appropriately selected in accordance with a resin to be a raw material of the resin base material, and for example, the stretching magnification in respective directions is preferably about 2 times to 10 times.

When a resin film is used as the base material 11, the thickness of the resin film is preferably about 5 to 500 μm, more preferably about 25 to 250 μm.

Moreover, when a resin film is used as the base material 11, the linear expansion coefficient of the resin film is preferably about 50 ppm/° C. or less, more preferably about 1 to 50 ppm/° C. By setting the linear expansion coefficient of a resin film to be 50 ppm/° C. or less, the generation of color shifting and deformation of the resin film (base material 11) due to the change in environmental temperature or the like can be suppressed when the transparent conductive film 10 of the present embodiment is applied to an electronic device such as a liquid crystal display element (LCD panel) or an organic EL element.

Meanwhile, in the present description, the “linear expansion coefficient” is referred to as the value of linear expansion coefficient measured by a method described below. Specifically, the base material 11 is heated to 30 to 50° C. at 5° C./min under a nitrogen atmosphere through the use of an EXSTAR TMA/SS6000 type thermal stress-strain measuring apparatus (manufactured by Seiko Instruments, Inc.), and after that, the temperature is maintained temporarily. Subsequently, again, the base material 11 is heated to 30 to 150° C. at 5° C./min, and at this time, the dimensional change in the base material 11 is measured in a tensile mode (load of 5 g). Then, the linear expansion coefficient is obtained from the dimensional change in the base material 11 at this time.

Furthermore, in the present embodiment, the light transmittance of the base material 11 to visible light (400 nm to 700 nm) is preferably about 80% or more, more preferably about 90% or more. By setting the light transmittance of the base material 11 to be 80% or more, high luminance can be obtained when the transparent conductive film 10 of the present embodiment is applied to an electronic device such as a liquid crystal display apparatus (LCD panel) or an organic EL element.

Meanwhile, in the present description, the “light transmittance” means average transmittance in the visible light region calculated by measuring a total amount of transmitted light relative to an incident light amount of visible light through the use of a spectrophotometer (visible-ultraviolet ray spectrophotometer UV-2500PC: manufactured by Shimadzu Corporation) in accordance with ASTM D-1003.

Moreover, in the present embodiment, a hydrophilizing treatment such as a corona treatment may have been performed on the base material 11. In this case, the close adherence between the base material 11 and a layer to be laminated thereon can be enhanced.

Furthermore, in the present embodiment, on the surface of the base material 11 on which, for example, the modified compound layer 12 or the like is to be laminated, the following various layers may be provided as necessary. An anchor coating layer (easy adhesion layer) may be provided, for example, on the surface of the base material 11. In this case, the close adherence between the base material 11 and the modified compound layer 12 (or the silazane compound layer 14) or a smooth layer to be described later can be enhanced.

An arbitrary anchor coating agent can be used as a material for forming the anchor coating layer (anchor coating agent), and for example, the use of a silane coupling agent is preferable. In this case, a thin film of from a single molecule level to nano level is formed on the base material 11, a molecular bond can be formed at the layer interface, and thus high adhesiveness can be obtained.

Moreover, a smooth layer for smoothing the surface of the base material 11 may be provided, for example, on the surface of the base material 11 formed of such a material as acrylic resin or siloxane polymer. Meanwhile, the smooth layer is preferably a layer having combined properties of interlayer close adherence, stress relaxation and bleed-out prevention from the base material 11 and the like.

Furthermore, in the present embodiment, a back coating layer may be provided on the rear surface of the base material 11 (the surface opposite to the surface on which the modified compound layer 12 and the like. are to be laminated). In this case, resistance characteristics, handling aptness and the like of the transparent conductive film 10 at the time of curl balance adjustment and production processes of a device can be improved.

(2) Modified Compound Layer and Technique for Producing the Same

(2-1) Configuration of Modified Compound Layer

The modified compound layer 12 is generated, as described above, by giving modification energy such as light, plasma or heat to the silazane compound layer 14. By the application treatment of the modification energy (modification treatment), at least apart of the silazane compound in the silazane compound layer 14 is converted (modified) into a compound having a siloxane bond.

Meanwhile, in the present embodiment, a part of the inside of the modified compound layer 12 may be in a state of having been modified, ort the whole inside of the modified compound layer 12 may be in a state of having been modified. In the former case, the silazane compound and a compound having a siloxane bond generated by modifying the silazane compound are put into a state of coexisting in the inside of the modified compound layer 12, and in the latter case, the compound having a siloxane bond is put into a state of being generated over approximately the whole inside of the modified compound layer 12.

Furthermore, the thickness of the modified compound layer 12 is preferably about 1 nm to 10 μm, more preferably about 2 nm to 1 μm, and most preferably about 5 to 600 nm. The transparent conductive film 10 (modified compound layer 12) of the present embodiment preferably has a water vapor barrier property, and the water vapor barrier property can be added to the transparent conductive film 10 by setting the thickness of the modified compound layer 12 to be 1 nm or more. Moreover, by setting the thickness of the modified compound layer 12 to be 10 μm or less, a crack hardly arises in the modified compound layer 12.

Meanwhile, in the present description, the phrase “has a water vapor barrier property” means that water vapor transmission rate measured in accordance with JIS K 7129-1992 (temperature: 40±0.5° C., relative humidity (RH): 90±2%) is 0.01 g/(m²·24 h) or less, or that water vapor permeability measured by the calcium method is 0.01 g/(m²·24 h) or less. Meanwhile, in the present embodiment, the transparent conductive film 10 has preferably an oxygen permeability measured in accordance with JIS K 7126-1987 of 0.01 mL/(m²·24 h·atm) or less.

Furthermore, in the present embodiment, the modified compound layer 12 may be constituted of a single layer, or of a plurality of layers.

For example, when the modified compound layer 12 is set to have a two-layer configuration, first, a first silazane compound layer is provided on the base material in the same way as in the first embodiment. Next, a sufficient modification treatment is performed on the first silazane compound layer to thereby form a first modified compound layer. Subsequently, again, a second silazane compound layer is laminated on the first modified compound layer. Subsequently, a metal layer formed of silver or an alloy containing silver as the main component is provided on the second silazane compound layer. Then, again, the modification treatment is performed on the laminated member in which various layers have been formed. In this way, a transparent conductive film in which the modified compound layer has a two-layer configuration can be produced.

As described above, when a plurality of modified compound layers is provided, nano level defects such as a defect or a pinhole caused by foreign materials can be restored effectively, and a transparent conductive film having a higher water vapor barrier property can be produced.

(2-2) Silazane Compound Layer

(2-2-A) Silazane Compound

The silazane compound to be a material for forming the silazane compound layer 14 is a compound having a Si—N bond in the structure thereof, and a compound that is converted into a compound having a siloxane bond by the application of the modification energy. Specifically, a silane coupling agent such as hexamethyldisilazane or a silazane compound such as polysilazane, which is known as an inorganic precursor can be used as a material for forming the silazane compound layer 14. Among them, the use of polysilazane that is modified effectively to an inorganic compound having a siloxane bond by giving modification energy as a material for forming the silazane compound layer 14 is preferable.

Polysilazane is a polymer having bonds such as Si—N, Si—H and N—H in the structure thereof, and functions as an inorganic precursor of SiO₂, Si₃N₄, an intermediate solid solution of SiOₓN_{y} and the like. Meanwhile, an arbitrary compound can be used as polysilazane, but in consideration of the modification treatment of a silazane compound to be described later, the use of a compound that changes into ceramic at comparatively low temperatures to thereby be modified into silica is preferable. Specifically, for example, polysilazane is preferably a compound having a main skeleton formed of a unit represented by a general formula (1) below described in Japanese Patent Application Laid-Open No. 08-112879.

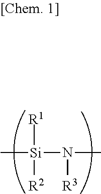

Each of “R¹,” “R²” and “R³” in the above general formula (1) is a hydrogen atom, an alkyl group, an alkenyl group, a cycloalkyl group, an aryl group, an alkylsilyl group, an alkylamino group or an alkoxy group. In the present embodiment, from the viewpoint of denseness of the modified compound layer (gas barrier inorganic layer) to be obtained after the modification, perhydropolysilazane (PHPS) in which all of “R¹,” “R²” and “R³” in the general formula (1) are hydrogen atoms is particularly preferably used as a material for forming the silazane compound layer 14.

Perhydropolysilazane is presumed to have a structure in which a linear chain structure and a ring structure centering on a six-membered ring and an eight-membered ring coexist. The molecular weight of perhydropolysilazane is about 600 to 2000 (based on polystyrene) in terms of number-average molecular weight (Mn), and perhydropolysilazane becomes a liquid material or a solid material according to the molecular weight. For example, a commercial product such as AQUAMICA (registered trade mark) NN120, NN110, NAX120, NAX110, NL120A, NL110A, NL150A, NP110 or NP140 (manufactured by AZ ELECTRONIC MATERIALS) can be used as the perhydropolysilazane described above.

Furthermore, other examples of polysilazane changing into ceramic at low temperatures include siliconalkoxide-added polysilazane obtained by causing polysilazane represented by the general formula (1) to react with siliconalkoxide (for example, Japanese Patent Application Laid-Open No. 05-238827), glycidol-added polysilazane obtained by causing the polysilazane to react with glycidol (for example, Japanese Patent Application Laid-Open No. 06-122852), alcohol-added polysilazane obtained by causing the polysilazane to react with alcohol (for example, Japanese Patent Application Laid-Open No. 06-240208), metal carboxylate-added polysilazane obtained by causing the polysilazane to react with metal carboxylate (for example, Japanese Patent Application Laid-Open No. 06-299118), acetylacetonate complex-added polysilazane obtained by causing the polysilazane to react with acetylacetonate complex containing a metal (for example, Japanese Patent Application Laid-Open No. 06-306329), metal-fine-particle-added polysilazane obtained by adding metal fine particles (for example, Japanese Patent Application Laid-Open No. 07-196986) and the like.

(2-2-B) Technique for Forming Silazane Compound Layer

In the present embodiment, as described above, preferably the silazane compound layer 14 is formed by applying a coating liquid containing a silazane compound onto the base material 11. Meanwhile, as a technique for applying a coating liquid containing a silazane compound, a conventionally known technique can be employed, and for example, a technique such as a spin coating method, a roll coating method, a flow coating method, an inkjet method, a spray coating method, a printing method, a dip coating method, a casting film-forming method, a bar coating method or a gravure printing method can be used.

Furthermore, the coating amount of the coating liquid is not particularly limited, and is adjusted appropriately so that the thickness of the modified compound layer 12 becomes an intended thickness. Then, after applying the coating liquid onto the base material 11, as described above, drying the coating liquid is preferable. Meanwhile, from the viewpoint of obtaining a uniform coating film, it is more preferable to anneal the base material 11 after applying the coating liquid onto the base material 11. In this case, the annealing temperature is not particularly limited, but is preferably about 60 to 200° C., more preferably about 70 to 160° C. Furthermore, in the annealing treatment, annealing temperature may be constant or may be changed with time. In particular, in the latter case, the annealing temperature may be changed with time in a stepwise manner, or may be changed continuously (temperature rise and/or temperature fall). Annealing time is not particularly limited, but it is preferably about 5 seconds to 24 hours, more preferably about 10 seconds to 2 hours.

(2-2-C) Coating Liquid

Although the content of the silazane compound in the coating liquid for forming the silazane compound layer 14 is different depending on conditions such as the thickness of the modified compound layer 12 and pot life of the coating liquid, to be required, preferably it is about 0.2% by mass to 35% by mass relative to the total amount of the coating liquid. Furthermore, the coating liquid containing a silazane compound may further contain an amine catalyst, a metal and a solvent.

(2-2-D) Amine Catalyst and Metal

When an amine catalyst and a metal are included in the coating liquid containing a silazane compound, the amine catalyst and the metal can accelerate the transformation of the silazane compound to a silicon oxide compound in the modification treatment and a coating film having uniform thickness and the like can be stably obtained.

For example, N,N,N′,N′-tetramethyl-1,6-diaminohexane can be used as the amine catalyst. Furthermore, for example, palladium can be used as the metal. The amine catalyst and the metal are preferably contained in the coating liquid in a ratio of about 0.1 to 10% by mass relative to the silazane compound. In particular, the amine catalyst is more preferably contained in the coating liquid in a ratio of about 0.5 to 5% by mass relative to the silazane compound from the viewpoints of improving coating properties and shortening reaction time.

(2-2-E) Solvent

As the solvent contained in the coating liquid containing a silazane compound, arbitrary solvent can be used as long as the solvent does not react with the silazane compound, and a known solvent can be used. Specifically, as the solvent, for example, a hydrocarbon-based solvent such as aliphatic hydrocarbon, alicyclic hydrocarbon, aromatic hydrocarbon or halogenated hydrocarbon, an ether-based solvent such as aliphatic ether or alicyclic ether, or the like can be used. In more detail, examples of the hydrocarbon solvent include pentane, hexane, cyclohexane, toluene, xylene, solvesso, turpene, methylene chloride, trichloroethane and the like. Furthermore, examples of the ether-based solvent include dibutyl ether, dioxane, tetrahydrofuran and the like. Meanwhile, these solvents may be used alone or in combination of two or more kinds thereof.

(2-3) Compound Having Siloxane Bond

In the present description, a compound having a siloxane bond is a modified compound obtained by giving the modification energy to a silazane compound. The compound having a siloxane bond is generated by oxidation of the silazane compound by modification energy given under an environment in which an oxygen source such as a small amount of moisture, active oxygen or ozone exists. Specifically, examples of the compound having a siloxane bond include siloxane bond compounds (inorganic substance) such as silicon oxide and silicon oxynitride.

Since the film containing such an inorganic substance generated by the modification of the silazane compound (modified compound layer 12) serves as a dense film, the transparent conductive film 10 to be obtained finally has a water vapor barrier property. Therefore, in the transparent conductive film 10 in the present embodiment, even when the metal layer 13 constituted of, for example, silver or a silver alloy (alloy containing silver as the main component) is formed on the base material 11 at a thin thickness, the property of the metal layer 13 can be stably maintained.

Furthermore, as is the case for the present embodiment, when the modified compound layer 12 is provided between the base material 11 and the metal layer 13, the effect of relaxing stress to be applied to the metal layer 13 in bending the transparent conductive film 10, by the modified compound layer 12 is also expected, and thus the improvement in bending resistance of the transparent conductive film 10 becomes possible.

(2-4) Modification Treatment and Modification Energy Source

The modification treatment (transformation reaction treatment) of the silazane compound layer 14 is carried out by giving modification energy to the silazane compound layer 14 under an environment in which oxygen exists and in a low humidity environment.

In the modification treatment, when modification energy is given to a silazane compound layer, the modification energy (for example, ultraviolet rays), or active oxygen and/or ozone arising from oxygen by applying the modification energy causes the silazane compound being an inorganic precursor to generate an oxidation reaction. As the result, the silazane compound is converted (modified) into a compound having a siloxane bond. In particular, since active oxygen and ozone have very high reactivity, for example, polysilazane is oxidized directly without going through silanol.

In the present embodiment, by the above-described transformation reaction of the silazane compound, the modified compound layer 12 having higher density and fewer defects and containing silicon oxide and/or silicon oxynitride can be generated. Meanwhile, in the case where ozone generated from oxygen at the time of the modification treatment is insufficient, the modification treatment may be carried out while generating separately ozone by a known method such as a discharge method.

Arbitrary energy may be used as the modification energy to be applied to the silazane compound, as long as it is an energy that is sufficient for converting at least a part of the silazane compound in the silazane compound layer 14 into a compound having a siloxane bond. In the present embodiment, the use of photo energy, plasma energy or thermal energy is preferable as the modification energy.

Meanwhile, among the above-described various modification energies, the use of ultraviolet ray energy as the modification energy is most preferable from the viewpoint of generating the modified compound layer 12 having higher denseness, higher hardness and a higher water vapor barrier property. In this case, the wavelength of ultraviolet rays with which irradiation is performed is not particularly limited, but, for example, it is preferably about 10 to 450 nm, more preferably about 100 to 300 nm, further more preferably about 100 to 200 nm, and particularly preferably about 100 to 180 nm. Meanwhile, in the present description, ultraviolet rays with high energy having a wavelength of 200 nm or less is referred to as, in particular, “vacuum ultraviolet ray (VUV).”

When ultraviolet rays are to be used for the modification treatment, the vacuum ultraviolet ray is preferably used as ultraviolet rays for advancing the transformation reaction (modification) at a lower temperature in a shorter time. The vacuum ultraviolet ray has a high energy, and thus, in a modification treatment using the vacuum ultraviolet ray, the transformation reaction advances easily and the conversion of oxygen into active oxygen or ozone is also carried out easily, and the transformation reaction can be executed effectively. As the result, the modified compound layer 12 (functional inorganic film) obtained by the modification treatment becomes a more dense film, and the gas barrier property of the modified compound layer 12 can be enhanced.

An arbitrary ultraviolet ray light source can be used as the light source of ultraviolet rays, and for example, a low pressure mercury lamp, a deuterium lamp, a rare gas excimer lamp, a metal halide lamp, an excimer laser or the like can be used. Meanwhile, the output power of these various lamps is preferably about 400 W to 30 kW. Furthermore, the illuminance is preferably about 1 mW/cm² to 100 kW/cm², more preferably about 1 mW/cm² to 10 W/cm². Moreover, the irradiation energy is preferably about 10 to 10000 mJ/cm², more preferably about 100 to 8000 mJ/cm².

In the present embodiment, among these light sources, the use of a rare gas excimer lamp such as a xenon excimer lamp that can emit the vacuum ultraviolet ray is preferable. In rare gases such as Xe, Kr, Ar and Ne which are used for the rare gas excimer lamp, the outermost electrons of the atom form a closed shell, and thus they are very inactive chemically and referred to as an inactive gas. However, a molecule obtained an energy by discharge and the like (excited atom) can be bound to another atom and form a molecule (excimer molecule).

When the rare gas is xenon, through an excitation process below,

e+Xe→Xe*

Xe*+2Xe→Xe₂*+Xe

Xe₂* being an excimer molecule is generated, and when the excited excimer molecule Xe₂* transitions to the ground state (Xe₂^{*}→Xe+Xe+hν), excimer light having a wavelength of 172 nm (vacuum ultraviolet ray) is emitted. In the case of a xenon excimer lamp, excimer light thus emitted is utilized.

Meanwhile, methods for obtaining excimer light includes, for example, a method for using dielectric barrier discharge and a method for using electrodeless field discharge.

The dielectric barrier discharge is discharge referred to as micro discharge that is generated in the gas space, that has a similarity to thunder, and that is very thin, when a gas space is provided between two electrodes via a dielectric substance (transparent quartz in the case of an excimer lamp) and a high-frequency high voltage of several 10 s of kHz is applied between both electrodes. In addition, when the streamer of the micro discharge reaches a tube wall (dielectric substance), the micro discharge disappears since charges are accumulated on the surface of the dielectric substance. That is, in the dielectric barrier discharge, the micro discharge spreads over the whole tube wall and repeats the generation and disappearance and, therefore, flickering of the light that can be recognized with the naked eye arises. Meanwhile, in the dielectric barrier discharge, since a very high-temperature streamer reaches locally and directly the tube wall, deterioration of the tube wall may be accelerated.

On the other hand, the electrodeless field discharge is electrodeless field discharge caused by capacitive coupling, and is also referred to as RF (radio-frequency wave) discharge. Specifically, the electrodeless field discharge is spatially and temporally uniform discharge that arises when a high-frequency voltage of several MHz is applied between the electrodes, in a state where a lamp, electrodes and the like are arranged in the same way as is the case for the dielectric barrier discharge. In the method of using the electrodeless field discharge, a lamp that does not exhibit flickering of light and has a long life time can be obtained.

When the dielectric barrier discharge is utilized as a method for obtaining excimer light, the micro discharge arises only between the electrodes. Therefore, in order to generate discharge in the whole discharge space, it is necessary to give a configuration in which the whole outer surface of a vessel is covered with an outside electrode and the outside electrode has light transmission property for the purpose of taking out the light to the outside. In order to achieve this, for example, the outside electrode is constituted of a net-like electrode using a thin metal wire so as not to shield the emitting light. However, in the case of the outside electrode with the configuration, the electrode may be damaged by ozone or the like that is generated by the vacuum ultraviolet ray irradiation. Therefore, when the outside electrode of the configuration is to be used, in order to prevent the damage of the outside electrode, it becomes necessary to set the circumference of the lamp, that is, the inside of the irradiation apparatus to be an atmosphere of inert gas such as nitrogen and to take out irradiation right by providing a window of synthesized quartz.

Meanwhile, when a double cylindrical type lamp is used as an excimer lamp, since the double cylindrical type lamp has an outer diameter of about 25 mm, the difference between the distance between a lamp axis and irradiation surface and between a lamp side surface and the irradiation surface cannot be neglected, and a large difference in illuminance may arise due to the distance difference. Therefore, in this case, if double cylindrical type lamps are aligned in close contact, uniform illuminance distribution cannot always be obtained. In addition, when an irradiation apparatus provided with a window of synthesized quartz is used as an excimer lamp, the distance in an oxygen atmosphere can be uniformed and uniform illuminance distribution can be obtained. However, the window of synthesized quartz is a high-priced expendable item, and may generate loss of light.

On the other hand, when the electrodeless field discharge is utilized as a method for obtaining excimer light, it is not necessary to make the outside electrode be in a net state, and glow discharge spreading over the whole discharge space can be obtained only by provision of the outside electrode on a part of the lamp outer surface. Furthermore, in this case, the outside electrode is usually produced by an aluminum block and functions as a reflection plate of light. In addition, the outside electrode of the configuration is provided on the rear side of the lamp. However, since the lamp outer diameter is large as is the case for the dielectric barrier discharge, synthesized quartz becomes necessary in order to uniform the illumination distribution.

Moreover, a thin tube excimer lamp can also be used as an excimer lamp. The greatest characteristic of the thin tube excimer lamp is that the structure thereof is simple. Specifically, the structure of the thin tube excimer lamp is only that both ends of a quartz tube are closed and gas for generating excimer emission is filled in the inside. Meanwhile, the outer diameter of the tube of the thin tube excimer lamp is preferably about 6 to 12 mm. When a tube having an outer diameter larger than the range is used, a high application voltage becomes necessary at the starting of the thin tube excimer lamp.

In the present embodiment, the form of discharge in the modification treatment may be either dielectric barrier discharge or electrodeless field discharge. As to the shape of the outside electrode, the plane to be in contact with a lamp may be flat, or may have a shape in accordance with a curved plane of a lamp. In the latter case, the outside electrode can be fixed firmly to the lamp, and since the outside electrode adheres closely to the lamp, more stable discharge can be obtained. In addition, when the outside electrode is formed of aluminum, the shape thereof is made to be a curved plane and the electrode plane is made to be a mirror plane, the outside electrode can be caused to function also as a reflection plate of light. A commercially available lamp (for example, lamp manufactured by Ushio, Inc.) can be used as an irradiation lamp of excimer light (vacuum ultraviolet ray) having the configuration (excimer lamp).

Furthermore, the excimer lamp has characteristics of concentrating on one wavelength and emitting almost no light other than light having a necessary wavelength, and has a high efficiency. Therefore, the excimer lamp also has characteristics of being able to keep the temperature of an object to be irradiated (transparent conductive film 10) low because the lamp does not emit excessive light. Furthermore, the excimer lamp has characteristics of being able to turn light on and off instantaneously becomes possible because the starting/restarting thereof does not require time. Among excimer lamps having the characteristics, in particular, a xenon excimer lamp emits a vacuum ultraviolet ray having a short wavelength (wavelength of 172 nm) at a single wavelength, and thus is excellent in emission efficiency.

It is known that the xenon excimer lamp has emission light of a short wavelength (172 nm) and has a high energy of the emission light, and thus, has high cutting ability of an organic compound. Furthermore, the xenon excimer lamp gives a large absorption coefficient of oxygen, and thus, can effectively generate active oxygen and ozone even under environments of a small amount of oxygen. That is, for example, as compared with a low pressure mercury lamp that emits a vacuum ultraviolet ray having a wavelength of 185 nm, the xenon excimer lamp has a high ability of cutting a bond of an organic compound, can effectively generate active oxygen and ozone, and can carry out the modification treatment of the silazane compound layer 14 at low temperatures and in a short period of time.

Furthermore, as described above, the xenon excimer lamp has a high efficiency of generating light, can turn light on and off instantaneously with low power and can emit light of a single wavelength. Therefore, from the economic viewpoint of the shortening of process time and the reduction of facility area along with high throughput, and from the viewpoint of applicability to a functional film using a base material that is susceptible to damage by heat, the use of the xenon excimer lamp as an energy source of the modification treatment is preferable.

As described above, the excimer lamp has a high efficiency of light generation, and thus, can be lightened at a low power and can suppress the rise in the surface temperature of an object to be irradiated (transparent conductive film 10). Furthermore, when the excimer lamp is used for the modification treatment, since the number of photons entering into the inside of the silazane compound layer 14 also increases, the increase in the modified region in the modified compound layer 12 and/or the densification of the film quality of the modified compound layer 12 become possible.

Meanwhile, when the irradiation time with the excimer light is too long, the planarity (flatness) of the transparent conductive film 10 may be deteriorated, or an adverse effect may arise in another layer (material) of the transparent conductive film 10. Usually, the specification of the transformation reaction (modification treatment) is set using an accumulated light quantity represented by the product of the irradiation intensity and irradiation time of the excimer light as an index, and thus at the time of the modification treatment, the irradiation intensity and the irradiation time of the excimer light are set appropriately so that the above-described adverse effects do not arise in the transparent conductive film 10.

Meanwhile, when a material having various structural forms even if the composition thereof is the same, such as silicon oxide, is used as the material for forming the silazane compound layer 14, the absolute value of the irradiation intensity may become important, in particular, as the setting condition of the transformation reaction (modification treatment). Therefore, in the case where the transformation reaction (modification treatment) is to be carried out by irradiation with vacuum ultraviolet ray, it is preferable to supply at least once the vacuum ultraviolet ray (VUV) having the largest irradiation intensity of about 100 to 200 mW/cm² to an object to be irradiated (transparent conductive film 10). By irradiating an object to be irradiated with the vacuum ultraviolet ray having the largest irradiation intensity of about 100 mW/cm² or more, the modification efficiency of a layer to be modified (silazane compound layer 14) and the transformation reaction can be advanced in a short period of time. Furthermore, by irradiating an object to be irradiated with the vacuum ultraviolet ray having the largest irradiation intensity of 200 mW/cm² or less, the deterioration of the object to be irradiated (transparent conductive film 10) and the deterioration of the lamp itself can be suppressed.

Moreover, when the modification treatment is to be carried out by vacuum ultraviolet ray irradiation, the irradiation time of the vacuum ultraviolet ray (VUV) is arbitrary as long as the time falls within the range not generating the above-described adverse effect in the transparent conductive film 10, and for example, the irradiation time in a process of performing irradiation with a high illuminance vacuum ultraviolet ray is preferably about 0.1 sec to 3 min, more preferably about 0.5 sec to 1 min. Furthermore, an oxygen concentration in an irradiation vessel at the time of the vacuum ultraviolet ray irradiation is preferably about 500 to 10000 ppm (1%), more preferably about 1000 to 5000 ppm. By setting the oxygen concentration to be about 500 ppm or more, the modification efficiency can be enhanced. Furthermore, by setting the oxygen concentration to be about 10000 ppm or less, the substitution treatment time of the air with oxygen can be shortened.

Meanwhile, in the coating film that is an object of the ultraviolet ray irradiation (silazane compound layer 14), oxygen and a small amount of moisture are mixed at the time of coating. Furthermore, adsorbed oxygen or adsorbed water may exist also in the base material 11, another adjacent layer or the like. In addition, oxygen and the like existing in the laminated member in this way can be sufficiently used as an oxygen source that causes the generation of active oxygen or ozone required for the modification treatment. In this case, new introduction of oxygen or the like into an irradiation vessel is unnecessary in the modification treatment.

Furthermore, in using a light source that emits the vacuum ultraviolet ray having a wavelength of 172 nm such as the xenon excimer lamp and in filling oxygen gas in an irradiation atmosphere of the vacuum ultraviolet ray, the vacuum ultraviolet ray amount that reaches a coating film may be reduced because the vacuum ultraviolet ray is absorbed by the oxygen. Therefore, in the case, it is preferable to perform the modification treatment under the condition that the vacuum ultraviolet ray effectively reaches up to the coating film (silazane compound layer 14) by setting the oxygen concentration in the irradiation chamber at the time of the irradiation with the vacuum ultraviolet ray.

Meanwhile, when a gas other than oxygen is to be used as a gas to be filled in the irradiation atmosphere of the vacuum ultraviolet ray, the use of a dry inert gas is preferable, and the use of dry nitrogen gas in particular is more preferable from the viewpoint of cost. Meanwhile, the oxygen concentration in an irradiation vessel can be adjusted by measuring flow rates of gases such as oxygen gas and inert gas to be introduced into the irradiation vessel and changing the flow rate ratio.

Furthermore, in the present embodiment, the vacuum ultraviolet ray that is emitted from the excimer lamp may be reflected by a reflection plate and a layer to be modified (silazane compound layer 14) may be irradiated with the reflected vacuum ultraviolet. In this case, the improvement of irradiation efficiency of the vacuum ultraviolet ray and uniform irradiation with the vacuum ultraviolet ray can be achieved. Moreover, the irradiation treatment of the vacuum ultraviolet ray can be applied to both of a batch treatment and continuous treatment, and one of treatments can be selected appropriately depending on the shape of the base material 11. For example, when the base material 11 is a long film, it is preferable to carry out the modification by continuously irradiating a laminated member with the vacuum ultraviolet ray while conveying the laminated member having a layer to be modified (silazane compound layer 14) formed on the base material 11.

Furthermore, in the present embodiment, it is preferable to perform the modification treatment while combining the irradiation treatment of the excimer light (vacuum ultraviolet ray) and a heat treatment. The combination of the irradiation treatment of the vacuum ultraviolet ray and the heat treatment can further accelerate the transformation reaction.

In this case, an arbitrary heating technique can be used as a heating technique. For example, such techniques can be used as a technique of heating a layer to be modified through thermal conduction by bringing a laminated member including the layer to be modified into contact with a heating body such as a heat block, a technique of heating the atmosphere of the laminated member by an external heater formed of a resistance wire or the like, and a technique of irradiating the laminated member with light in an infrared region such as light from an infrared heater. Meanwhile, as the heating technique, a prescribed technique can appropriately be selected from among these various techniques in consideration of the viewpoint of smoothness or the like of a coating film to be formed on the base material 11.

The heating temperature in the heating treatment can be set to be arbitrary as long as the heating temperature is a temperature capable of accelerating the transformation reaction, and is preferably about 50 to 200° C., more preferably about 80 to 150° C. Furthermore, the heating time is preferably about 1 second to 10 hours, more preferably about 10 seconds to 1 hour.

Meanwhile, when a coating liquid and a coating film containing polysilazane are exposed to a state of high humidity, the removal of absorbed moisture from the coating liquid and coating film becomes difficult, and a hydrolysis reaction may proceed in the coating film due to the moisture. In particular, the coating film becomes susceptible to the moisture with the increase in the surface area. Therefore, when such a coating liquid is to be used, it is preferable to store or treat the laminated member in an atmosphere of a dew point of 10° C. (temperature: 25° C., relative humidity (RH): 39%) or less, preferably of a dew point 8° C. (temperature: 25° C., relative humidity (RH): 10%) or less, and more preferably of dew point of −31° C. (temperature: 25° C., relative humidity (RH): 1%) or less, during the time period from the preparation step of the coating liquid to the completion of the modification treatment, in particular, during the time period from the formation of the coating film to the completion of the modification treatment. Consequently, the generation of Si—OH in a functional inorganic layer (modified compound layer 12) can be suppressed.

Meanwhile, in the present description, the “dew point temperature” means a temperature at which condensation starts when air containing water vapor is cooled, and is an indicator that represents the moisture content in the atmosphere. Usually, the dew point temperature can be measured directly, through the use of a dew point thermometer. Furthermore, the dew point temperature may be obtained by calculating a temperature at which the water vapor pressure is the saturated water vapor pressure after obtaining water vapor pressure from ambient temperature and relative humidity. In this case, a measured temperature at which the relative humidity is 100% becomes the dew point temperature.

The percentage, density and the like of the modified region in the modified compound layer 12 obtained by the above-described modification treatment can be controlled appropriately by coating conditions of a coating liquid containing the silazane compound, and conditions of the modification treatment. For example, when ultraviolet ray irradiation is used as the modification treatment, the percentage, density and the like of the modified region in the modified compound layer 12 can be controlled by selecting appropriately the irradiation intensity and irradiation time of the ultraviolet ray (vacuum ultraviolet ray), the wavelength of the ultraviolet ray (energy density of light), the irradiation technique of the ultraviolet ray, heating temperature and heating time of the layer to be modified, and the like, in addition to coating conditions of the coating liquid.

Meanwhile, as to the irradiation technique of the ultraviolet ray (vacuum ultraviolet ray), a prescribed technique can be selected appropriately from among techniques such as continuous irradiation, irradiation separated into a plurality of times and so-called pulse irradiation in which the time of each of irradiation a plurality of times is short. Furthermore, the level of the modification treatment (percentage, density and the like of the modified region) can be checked by performing XPS (X-ray Photoelectron Spectroscopy) surface analysis on the formed modified compound layer 12 and obtaining composition ratio of respective atoms such as silicon (Si), nitrogen (N) and oxygen (O).

(3) Metal Layer

The metal layer 13 is formed of silver (Ag) or an alloy containing silver as the main component, as described above. The metal layer 13 can be formed by a known method including a technique using a wet process such as an application method, an inkjet method, a coating method and dip method, or a technique using a dry process such as an evaporation method (resistance heating method, EB (Electron Beam) method and the like), a sputtering method and a CVD (Chemical Vapor Deposition) method. In the present embodiment, the formation of the metal layer 13 by an evaporation method is preferable.

Meanwhile, in the present embodiment, since a layer containing a compound having a nitrogen atom is provided in the lower portion of the metal layer 13, the metal layer 13 can obtain sufficiently good conductivity even without being subjected to a high temperature annealing treatment and the like after the film formation thereof. However, even in the present embodiment, as necessary, the metal layer 13 may be subjected to an annealing treatment or the like after the film formation.

When the metal layer 13 is to be formed of an alloy containing silver as the main component, silver-magnesium (AgMg), silver-copper (AgCu), silver-palladium (AgPd), silver-palladium-copper (AgPdCu), silver-indium (AgIn) or the like can be used as the silver alloy. Furthermore, in the present embodiment, metal layer 13 may be constituted of a single layer, or may be constituted of a plurality of layers as necessary. In the latter case, the metal layer 13 may be constituted while laminating alternately a layer formed of silver and a layer formed of the silver alloy, or the metal layer 13 may be constituted while laminating a plurality of layers formed of silver alloys having different compositions and/or formation materials from each other.

The thickness of the metal layer 13 is in the range of about 4 to 12 nm as described above, and is preferably in the range of about 4 to 9 nm. By setting the thickness of the metal layer 13 to be smaller than 9 nm, the absorption component and reflection component of light is suppressed in the metal layer and thus the light transmittance of the transparent conductive film 10 is ensured. Furthermore, by setting the thickness of the metal layer 13 to be thicker than 4 nm, the conductivity of the metal layer 13 is ensured.

Moreover, the upper portion of the metal layer 13 (the portion opposite to the modified compound layer 12 side) may be covered with, for example, a protective layer, or laminated with another conductive film. In this case, in order not to damage the light transmission property of the transparent conductive film 10, preferably the protective film and/or the conductive film is also constituted of a film having light transmission property.

### Various Effects of First Embodiment

As described above, the transparent conductive film 10 of the present embodiment is produced by forming the metal layer 13 formed of silver or an silver alloy containing silver as the main component on the silazane compound layer 14, and after that, giving modification energy to the silazane compound layer 14 (laminated member) at the timing before the formation of the metal layer 13 (modification 1), or before and after the formation of the metal layer 13 (modification 2). Then, by adjusting appropriately the amount of modification energy to be given to the silazane compound layer 14 or the state of treatment atmosphere, the modified compound layer 12, in which at least a part of the silazane compound in the silazane compound layer 14 has been converted into a compound having a siloxane bond (inorganic compound), is formed in the lower portion of the metal layer 13. That is, by the modification treatment, it is possible to cause various compounds having a nitrogen atom such as a silazane compound and a silicon oxynitride compound generated by moderate progress of an oxidation reaction, to exist in the modified compound layer 12.

In the manufacturing technique, in the film formation process of the metal layer 13 formed of silver or an alloy containing silver as the main component, a compound layer containing a nitrogen atom (silazane compound layer 14 or modified compound layer 12) exists in the lower portion of the metal layer 13, and thus the silver atom constituting the metal layer 13 interacts with the compound having a nitrogen atom and the diffusion distance of a silver atom on the surface of the lower layer is reduced. Therefore, in the present embodiment, the effect of suppressing the aggregation of silver can be expected in the film formation process of the metal layer 13 formed of silver or an alloy containing silver as the main component.

Generally, in the film formation process of a metal layer including silver as the main component, the metal layer performs thin film growth of a nuclear growth type (Volumer-Weber: VW type), and thus silver particles tend to be isolated easily, and when the thickness is small, it is difficult to obtain the conductivity of the metal layer and the sheet resistance value becomes high. Therefore, usually, in order to ensure the conductivity of a metal layer including silver as the main component, the thickness thereof has to be increased. However, when the thickness is increased, the light transmittance of the metal layer is reduced, which is not appropriate as a transparent electrode.

In contrast, in the present embodiment, as described above, the aggregation of silver on the lower layer surface is suppressed in the film formation process of the metal layer 13 formed of silver or an alloy containing silver as the main component. That is, in the present embodiment, it can be expected that the metal layer 13 performs a thin film growth of a single layer growth type (Frank-van der Merwe: FM type) in the film formation process of the metal layer 13. Therefore, in the present embodiment, even when the metal layer 13 formed of silver or an alloy containing silver as the main component has a thin thickness, the metal layer becomes a film in which conductivity is ensured and it becomes possible to achieve both of the enhancement of conductivity and the enhancement of light transmission property.

Furthermore, in the present embodiment, since a dense modified inorganic layer (modified compound layer 12) is formed by modification of at least a part of the silazane compound layer 14 provided in the lower portion of the metal layer 13, a water vapor barrier property is also obtained. That is, in the present embodiment, both effects of interaction between silver and a compound having a nitrogen atom in the interface between the metal layer 13 and the lower layer thereof and of property stability of the metal layer 13 can be obtained, and the transparent conductive film 10 having all of excellent conductivity, light transmission property and a water vapor barrier property can be obtained.

Therefore, the transparent conductive film 10 of the present embodiment is suitable as, for example, a sealing film or a base material required for maintaining stably the property of various electronic devices such as liquid crystal display elements (LCD), photovoltaics (PV) and organic EL elements. Furthermore, when the metal layer 13 of the transparent conductive film 10 is appropriately patterned in advance depending on an electronic device to which the transparent conductive film 10 is to be applied, the transparent conductive film 10 can be used as a sealing base material with an electrode. In this case, a manufacturing process of the electronic device can be reduced and thus the process can be made simpler.

### Second Embodiment

### Second Configuration Example of Transparent Conductive Film

[Whole Configuration of Transparent Conductive Film]

In FIG. 5, a schematic configuration cross-sectional view of the transparent conductive film according to the second embodiment is illustrated. Meanwhile, in a transparent conductive film 20 of the present embodiment illustrated in FIG. 5, the same reference sign is attached to the same configuration as that of the transparent conductive film 10 of the first embodiment illustrated in FIG. 1

The transparent conductive film 20 is provided with, as illustrated in FIG. 5, the base material 11, the modified compound layer 12, a compound layer 21 having a heterocyclic ring including a nitrogen atom as a hetero atom (hereinafter, referred to as the heterocyclic compound layer 21) and the metal layer 13. Furthermore, in the present embodiment, the modified compound layer 12, the heterocyclic compound layer 21 and the metal layer 13 are to be laminated in this order on one surface of the base material 11. In addition, although not illustrated in FIG. 5, in the same way as in the first embodiment, a bleed-out preventing layer is to be provided on the surface on the modified compound layer 12 side of the base material 11.

As is clear from the comparison between FIG. 5 and FIG. 1, the transparent conductive film 20 of the present embodiment has a configuration in which the heterocyclic compound layer 21 is further provided between the modified compound layer 12 and the metal layer 13 in the transparent conductive film 10 of the first embodiment. In addition, in the present embodiment, too, the base material 11, the modified compound layer 12 and the metal layer 13 can be constituted in the same way as those in the first embodiment. Therefore, here, the explanation of the configuration of the base material 11, the modified compound layer 12 and the metal layer 13 is omitted. Meanwhile, the configuration of the heterocyclic compound layer 21 will be described in detail later.

[Technique for Manufacturing Transparent Conductive Film]

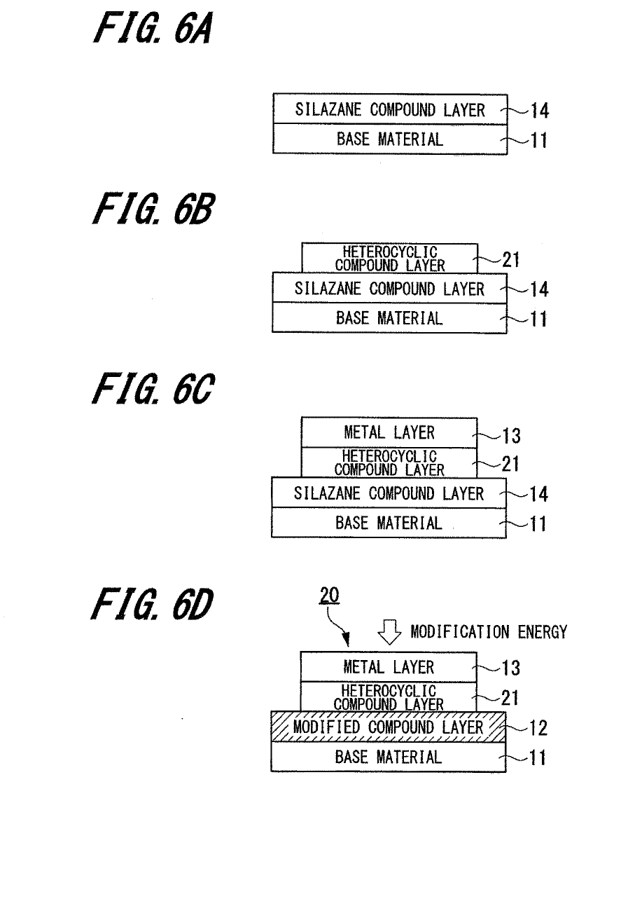

Here, while referring to FIGS. 6A to 6D, a technique for manufacturing the transparent conductive film 20 of the present embodiment will be explained briefly. Meanwhile, FIGS. 6A to 6D are drawings that show the procedure of manufacturing process of the transparent conductive film 20, and each of the drawings is a schematic configuration cross-sectional view of a laminated member at the completion of each of processes. Furthermore, in the present embodiment, process conditions and film formation technique in each of formation processes of the base material 11, the modified compound layer 12 and the metal layer 13 are the same as those in the first embodiment.

First, the base material 11 in which a bleed-out preventing layer (not illustrated) is provided on the surface is prepared. Subsequently, in the same way as in the first embodiment, the silazane compound layer 14 is formed on the surface on the bleed-out preventing layer (not illustrated) side of the base material 11 (a state in FIG. 6A).

Subsequently, a heterocyclic compound layer 21 (a compound layer having a heterocyclic ring containing a nitrogen atom as a hetero atom) is formed on the silazane compound layer 14 (a state in FIG. 6B). At this time, in the present embodiment, the heterocyclic compound layer 21 is formed by a conventionally known technique and the thickness thereof is set to be, for example, about 1 to 500 nm.

Then, the metal layer 13 formed of silver (Ag) or an alloy containing silver as the main component is formed on the heterocyclic compound layer 21 (a state in FIG. 6C). At this time, in the present embodiment, the metal layer 13 is formed by a conventionally known technique in the same way as in the first embodiment, and the thickness thereof is set to be, for example, about 4 to 9 nm.

Then, the modified compound layer 12 was generated by giving the modification energy to a laminated member (laminated body) in which the silazane compound layer 14, the heterocyclic compound layer 21 and the metal layer 13 are formed on the base material 11, and modifying at least a part of the silazane compound (a state in FIG. 6D). In the present embodiment, the transparent conductive film 20 is produced in this way.

Meanwhile, also in the present embodiment, the manufacturing technique of the transparent conductive film 20 is not limited to the example illustrated in FIGS. 6A to 6D, and the transparent conductive film 20 may be produced, for example, in the same way as the manufacturing technique described in the modifications 1 and 2. Specifically, for example, the modification treatment may be performed on a laminated member before laminating the heterocyclic compound layer 21 on the silazane compound layer 14. Furthermore, for example, the modification treatment may be executed for each of laminated members before and after laminating the heterocyclic compound layer 21 and the metal layer 13 on the silazane compound layer 14.

Also in the present embodiment, the aggregation of silver in the metal layer 13 is suppressed by providing the modified compound layer 12 and the heterocyclic compound layer 21 between the base material 11 and the metal layer 13 of a thin film, in the same way as in the first embodiment. Furthermore, also in the present embodiment, since the silazane compound layer 14 is subjected to the modification treatment, a water vapor barrier property can be given to the transparent conductive film 20. That is, also in the present embodiment, the transparent conductive film 20 having both sufficient conductivity and light transmission property and having high property stability (excellent also in water vapor barrier property) can be produced.

[Heterocyclic Compound Layer]

Next, the configuration of the heterocyclic compound layer 21 will be explained in more detail. As described above, the heterocyclic compound layer 21 that is provided between the modified compound layer 12 and the metal layer 13 in the transparent conductive film 20 of the present embodiment is a compound layer having a heterocyclic ring containing a nitrogen atom as a hetero atom.

The heterocyclic compound layer 21 can be formed by a technique using a wet process such as an application method, an inkjet method, a coating method and dip method, or a technique using a dry process such as an evaporation method (resistance heating method, EB method and the like), a sputtering method and a CVD method. Meanwhile, in the present embodiment, the formation of the heterocyclic compound layer 21 by an evaporation method is preferable.

The thickness of the heterocyclic compound layer 21 is preferably about 1 nm to 500 nm, more preferably about 1 nm to 200 nm, and most preferably about 1 nm to 30 nm from the viewpoint of light transmittance. By setting the thickness of the heterocyclic compound layer 21 to be about 1 nm or more, the interaction between the silver in the metal layer 13 and the compound having a nitrogen atom in the lower layer of the metal layer 13 can be expected. Furthermore, by setting the thickness of the heterocyclic compound layer 21 to be about 500 nm or less, the transparency of the heterocyclic compound layer 21 can be maintained.

Examples of the compound having a heterocyclic ring containing a nitrogen atom as a hetero atom (hereinafter, referred to as a heterocyclic compound), the compound forming the heterocyclic compound layer 21, include aziridine, azirine, azetidine, azete, azolidine, azole, azinane, pyridine, azepane, azepine, imidazole, pyrazole, oxazole, thiazole, imidazoline, pyrazine, morpholine, thiazine, indole, isoindole, benzoimidazole, purine, quinoline, isoquinoline, quinoxaline, cinnoline, pteridine, acridine, carbazole, benzo-C-cinnoline, porphyrin, chlorine, choline and the like.

Meanwhile, in the above-described various heterocyclic compounds, particularly preferable compounds are those represented by general formulae (2) to (4) below.

[Heterocyclic Compounds Represented by General Formula (2)]

Heterocyclic compounds represented by the general formula (2) are as follows.

[Chem. 2]

(Ar1)n1-Y1 General formula (2)

Meanwhile, in the general formula (2), “n1” is an integer of 1 or more. “Y1” represents a substituent when “n1” is 1, or represents simply a bond or an n1-valent linking group when “n1” is 2 or more. “Ar1” represents a group represented by a general formula (A) to be described later. Meanwhile, when “n1” is 2 or more, a plurality of “Ar1s” may be the same or may be different from each other.

### (1) Specific Examples of “Y1”

In the general formula (2), examples of the substituent represented by “Y1” include an alkyl group (for example, methyl group, ethyl group, propyl group, isopropyl group, tert-butyl group, pentyl group, hexyl group, octyl group, dodecyl group, tridecyl group, tetradecyl group and pentadecyl group), a cycloalkyl group (such as a cyclopentyl group and a cyclohexyl group), an alkenyl group (for example, vinyl group and allyl group), an alkynyl group (for example, ethynyl group and propargyl group), an aromatic hydrocarbon group (also referred to as an aromatic carbon ring group, an aryl group or the like, and for example, phenyl group, p-chlorophenyl group, mesityl group, tolyl group, xylyl group, naphthyl group, anthryl group, azulenyl group, acenaphthenyl group, fluorenyl group, phenanthryl group, indenyl group, pyrenyl group and biphenylyl group), an aromatic heterocyclic ring group (for example, furyl group, thienyl group, pyridyl group, pyridazinyl group, pyrimidinyl group, pyrazinyl group, triazinyl group, imidazolyl group, pyrazolyl group, thiazolyl group, quinazolinyl group, carbazolyl group, carbolinyl group, diazacarbazolyl group (represents one in which one of arbitrary carbon atoms constituting a carboline ring of the carbolinyl group is substituted with a nitrogen atom) and a phthalazinyl group), a heterocyclic ring group (for example, pyrrolidyl group, imidazolidyl group, morpholyl group and oxazolydyl group), an alkoxy group (for example, methoxy group, ethoxy group, propyloxy group, pentyloxy group, hexyloxy group, octyloxy group and dodecyloxy group), a cycloalkoxy group (for example, cyclopentyloxy group and cyclohexyloxy group), an aryloxy group (for example, phenoxy group and naphthyloxy group), an alkylthio group (for example, methylthio group, ethylthio group, propylthio group, pentylthio group, hexylthio group, octylthio group and dodecylthio group), a cycloalkylthio group (for example, cyclopentylthio group and cyclohexylthio group), an arylthio group (for example, phenylthio group and naphthylthio group), an alkoxycarbonyl group (for example, methyloxycarbonyl group, ethyloxycarbonyl group, butyloxycarbonyl group, octyloxycarbonyl group and dodecyloxycarbonyl group), an aryloxycarbonyl group (for example, phenyloxycarbonyl group and naphthyloxycarbonyl group), a sulfamoyl group (for example, aminosulfonyl group, methylaminosulfonyl group, dimethylaminosulfonyl group, butylaminosulfonyl group, hexylaminosulfonyl group, cyclohexylaminosulfonyl group, octylaminosulfonyl group, dodecylaminosulfonyl group, phenylaminosulfonyl group, naphthylaminosulfonyl group, and 2-pyridylaminosulfonyl group), an acyl group (for example, acetyl group, ethylcarbonyl group, propylcarbonyl group, pentylcarbonyl group, cyclohexylcarbonyl group, octylcarbonyl group, 2-ethylhexylcarbonyl group, dodecylcarbonyl group, phenylcarbonyl group, naphthylcarbonyl group and pyridylcarbonyl group), an acyloxy group (for example, acetyloxy group, ethylcarbonyloxy group, butylcarbonyloxy group, octylcarbonyloxy group, dodecylcarbonyloxy group and phenylcarbonyloxy group), an amide group (for example, methylcarbonylamino group, ethylcarbonylamino group, dimethylcarbonylamino group, propylcarbonylamino group, pentylcarbonylamino group, cyclohexylcarbonylamino group, 2-ethylhexylcarbonylamino group, octylcarbonylamino group, a dodecylcarbonylamino group, a phenylcarbonylamino group and naphthylcarbonylamino group), a carbamoyl group (for example, aminocarbonyl group, methylaminocarbonyl group, dimethylaminocarbonyl group, propylaminocarbonyl group, pentylaminocarbonyl group, cyclohexylaminocarbonyl group, octylaminocarbonyl group, 2-ethylhexylaminocarbonyl group, dodecylaminocarbonyl group, phenylaminocarbonyl group, naphthylaminocarbonyl group and 2-pyridylaminocarbonyl group), an ureido group (for example, methylureido group, ethylureido group, pentylureido group, cyclohexylureido group, octylureido group, dodecylureido group, phenylureido group, naphthylureido group and 2-pyridylaminoureido group), a sulfinyl group (for example, methylsulfinyl group, ethylsulfinyl group, butylsulfinyl group, cyclohexylsulfinyl group, 2-ethylhexylsulfinyl group, dodecylsulfinyl group, phenylsulfinyl group, naphthylsulfinyl group and 2-pyridylsulfinyl group), an alkylsulfonyl group (for example, methylsulfonyl group, ethylsulfonyl group, butylsulfonyl group, cyclohexylsulfonyl group, 2-ethylhexylsulfonyl group and dodecylsulfonyl group), an arylsulfonyl group (for example, phenylsulfonyl group and naphthylsulfonyl group), a heteroarylsulfonyl group (for example, 2-pyridylsulfonyl group), an amino group (such as amino group, ethylamino group, dimethylamino group, butylamino group, cyclopentylamino group, 2-ethylhexylamino group, dodecylamino group, anilino group, naphthylamino group, 2-pyridylamino group, piperidyl group (also referred to as a piperidinyl group) and 2,2,6,6-tetramethylpiperidinyl group), a halogen atom (for example, fluorine atom, chlorine atom and bromine atom), a fluorinated hydrocarbon group (for example, fluoromethyl group, trifluoromethyl group, pentafluoroethyl group and pentafluorophenyl group), a cyano group, a nitro group, a hydroxyl group, a mercapto group, a silyl group (for example, trimethylsilyl group, triisopropylsilyl group, triphenylsilyl group and phenyldiethylsilyl group), a phosphoric acid ester group (for example, dihexylphosphoryl group), a phosphorous acid ester group (for example, diphenylphosphinyl group), a phosphono group, and the like.

In addition, in the above-described various substituents, a substitutable site in the inside thereof may be further substituted by the various substituents. Furthermore, a ring may be formed by causing a plurality of the various substituents to bind to each other.

Furthermore, examples of an n1-valent linking group represented by “Y1” in the general formula (2) include a divalent linking group, a trivalent linking group and a tetravalent linking group, and the like.

Examples of the divalent linking group represented by “Y1” in the general formula (2) include: an alkylene group (for example, ethylene group, trimethylene group, tetramethylene group, propylene group, ethylethylene group, pentamethylene group, hexamethylene group, 2,2,4-trimethylhexamethylene group, heptamethylene group, octamethylene group, nonamethylene group, decamethylene group, undecamethylene group, dodecamethylene group, a cyclohexylene group (for example, 1,6-cyclohexanediyl group and the like) and a cyclopenthylene group (for example, 1,5-cyclopentanediyl group and the like)), an alkenylene group (for example, vinylene group, propenylene group, butenylene group, pentenylene group, 1-methylvinylene group, 1-methylpropenylene group, 2-methylpropenylene group, 1-methylpentenylene group, 3-methylpentenylene group, 1-ethylvinylene group, 1-ethylpropenylene group, 1-ethylbutenylene group, 3-ethylbutenylene group and the like), an alkynylene group (for example, ethynylene group, 1-propynylene group, 1-butynylene group, 1-pentynylene group, 1-hexynylene group, 2-butynylene group, 2-pentynylene group, 1-methylethynylene group, 3-methyl-1-propynylene group, 3-methyl-1-butynylene group and the like), an arylene group (for example, o-phenylene group, p-phenylene group, naphthalenediyl group, anthracenediyl group, naphthacenediyl group, pyrenediyl group, naphthylnaphthalenediyl group, a biphenyldiyl group (for example, [1,1′-biphenyl]-4,4′-diyl group, 3,3′-biphenyldiyl group, 3,6-biphenyldiyl group and the like), terphenyldiyl group, quaterphenyldiyl group, quinquephenyldiyl group, sexiphenyldiyl group, septiphenyldiyl group, octiphenyldiyl group, nobiphenyldiyl group, deciphenyldiyl group and the like), a heteroarylene group (for example, a divalent group derived from a group consisting of carbazole group, carboline ring, diazacarbazole ring (also referred to as monoazacarboline group, exhibiting a ring structure obtained by substituting one carbon atom constituting the carboline ring, with a nitrogen atom), triazole ring, pyrrole ring, pyridine ring, pyrazine ring, quinoxaline ring, thiophene ring, oxadiazole ring, dibenzofuran ring, dibenzothiophene ring, indole ring and the like), a chalcogen atom such as oxygen or sulfur, a group or the like derived from a condensed aromatic heterocyclic ring obtained by condensing three or more rings (here, the condensed aromatic heterocyclic ring formed by condensing three or more rings preferably contains a hetero atom selected from N, O and S as an element constituting a condensed ring, for example, acridine ring, benzoquinoline ring, carbazole ring, phenazine ring, phenanthridine ring, phenanthroline ring, carboline ring, cycladine ring, quindoline ring, thebenidine ring, quinindoline ring, triphenodithiazine ring, triphenodioxazine ring, phenanthrazine ring, anthrazine ring, perimizine ring, diazacarbazole ring (exhibiting a ring obtained by substituting optional one of carbon atoms constituting the carboline ring, with a nitrogen atom), phenanthroline ring, dibenzofuran ring, dibenzothiophene ring, naphthofuran ring, naphthothiophene ring, benzodifuran ring, benzodithiophene ring, naphthodifuran ring, naphthodithiophene ring, anthrafuran ring, anthradifuran ring, anthrathiophene ring, anthradithiophene ring, thianthrene ring, phenoxathiin ring, thiophanthrene ring (naphthothiophene ring) and the like).

Examples of the trivalent linking group represented by “Y1” in the general formula (2) include ethanetriyl group, propanetriyl group, butanetriyl group, pentanetriyl group, hexanetriyl group, heptanetriyl group, octanetriyl group, nonanetriyl group, decanetriyl group, undecanetriyl group, dodecanetriyl group, cyclohexanetriyl group, cyclopentanetriyl group, benzenetriyl group, naphthalenetriyl group, pyridinetriyl group, carbazoletriyl group, and the like.

The tetravalent linking group represented by “Y1” in the general formula (2) is a group having a combining group added to the above-mentioned trivalent linking group. Examples include propandiylidene group, 1,3-propandiyl-2-ylidene group, butanediylidene group, pentanediylidene group, hexanediylidene group, heptanediylidene group, octanediylidene group, nonanediylidene group, decanediylidene group, undecanediylidene group, dodecanediylidene group, cyclohexanediylidene group, cyclopentanediylidene group, benzenetetrayl group, naphthalenetetrayl group, pyridinetetrayl group, carbazoletetrayl group, and the like.

Meanwhile, each of the aforementioned divalent, trivalent and tetravalent linking groups may further have a substituent represented by “Y1” in the general formula (2).

As the aspect of the compound represented by the general formula (2), it is preferable that “Y1” represent a group which is derived from a condensed aromatic heterocyclic ring constituted by condensing three or more rings. Furthermore, examples of the condensed aromatic heterocyclic ring constituted by condensing three or more rings preferably include dibenzofuran ring or dibenzothiophene ring. In addition, preferably “n1” is 2 or more.

Furthermore, the compound represented by the general formula (2) has, in a molecule, at least two condensed aromatic heterocyclic rings constituted by condensing three or more rings, described above.

Moreover, when “Y1” represents an n1-valent linking group, “Y1” is preferably non-conjugated in order to keep the triplet excitation energy of the compound represented by the general formula (2) high, and is preferably constituted of aromatic rings (aromatic hydrocarbon ring+aromatic heterocyclic ring) from the viewpoint of improving Tg (also referred to as glass transition point, or glass transition temperature). The “non-conjugated” referred to herein means a case where a linking group cannot be expressed by repetition of a single bond (single bond) and a double bond, or a case where a conjugation of aromatic rings constituting a linking group is sterically broken.

### (2) Specific Examples of “Ar1”

“Ar1” in the general formula (2) represents the group represented by the general formula (A) below.

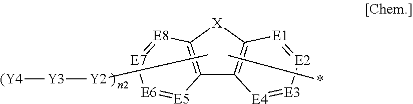

“X” in the general formula (A) represents —N(R)—, —O—, —S— or —Si(R)(R′)—, E1 to E8 each represent —C(R1)= or —N═. Meanwhile, R, R′ and R1 each represent hydrogen atom, a substituent or a linking moiety with “Y1.” Furthermore, “*” in the general formula (A) represents a linking moiety with “Y1.” “Y2” represents simply a bond or a divalent linking group. “Y3” and “Y4” each represent a group derived from a five-membered or six-membered aromatic ring. Meanwhile, at least one of “Y3” and “Y4” represents a group derived from an aromatic heterocyclic ring containing nitrogen atom as a ring constituent atom. n2 represents an integer of 1 to 4.

Here, in —N(R)— or —Si(R)(R′)— represented by “X”, and in —C(R1)=represented by “E1” to “E8” in the general formula (A), the substituent represented by each of R, R′ and R1 has the same meaning as that of the substituent represented by “Y1” in the general formula (2). In addition, the divalent linking group represented by “Y2” in the general formula (A) has the same meaning as that of the divalent linking group represented by “Y1” in the general formula (2).

Furthermore, examples of a five-membered or six-membered aromatic ring which is used for the formation of a group derived from a five-membered or six-membered aromatic ring represented by each of “Y3” and “Y4” in the general formula (A) include benzene ring, oxazole ring, thiophene ring, furan ring, pyrrole ring, pyridine ring, pyridazine ring, pyrimidine ring, pyrazine ring, diazine ring, triazine ring, imidazole ring, isoxazole ring, pyrazole ring, triazole ring, and the like. Moreover, the group derived from five-membered or six-membered aromatic rings represented by at least one of “Y3” and “Y4” represents a group derived from the aromatic heterocyclic ring containing a nitrogen atom as a ring constituent atom. Meanwhile, examples of the aromatic heterocyclic ring containing a nitrogen atom as a ring constituent atom include oxazole ring, pyrrole ring, pyridine ring, pyridazine ring, pyrimidine ring, pyrazine ring, diazine ring, triazine ring, imidazole ring, isoxazole ring, pyrazole ring, triazole ring, and the like.

### (3) Preferred Aspect of the Group Represented by“Y3”

In the general formula (A), the group represented by “Y3” is preferably a group derived from the aforementioned six-membered aromatic ring, and is more preferably a group derived from a benzene ring.

### (4) Preferred Aspect of the Group Represented by “Y4”

In the general formula (A), the group represented by “Y4” is preferably a group derived from the aforementioned six-membered aromatic ring, is more preferably a group derived from the aromatic heterocyclic ring containing nitrogen atom as a ring constituent atom, and is Particularly preferably a group derived from a pyridine ring.

(5) Preferred Aspect of the Group Represented by the General Formula (A)

The preferable aspect of the group represented by the general formula (A) includes a group represented by the general formulae (A-1), (A-2), (A-3) or (A-4) below.

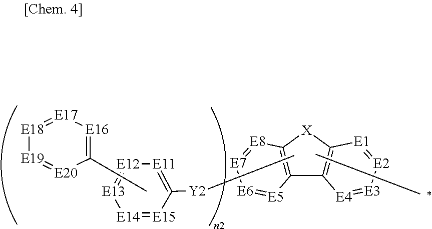

In the general formula (A-1), “X” represents —N(R)—, —O—, —S— or —Si(R)(R′)—. “E1” to “E8” each represent —C(R1)= or —N═. Meanwhile, R, R′ and R1 each represent hydrogen atom, a substituent or a linking moiety with “Y1.” In addition, “Y2” in the general formula (A-1) represents simply a bond or a divalent linking group. “E11” to “E20” each represent —C(R2)= or —N═, and at least one represents —N═. Meanwhile, R2 represents hydrogen atom, a substituent or a linking moiety. Furthermore, at least one of “E11” and “E12” represents —C(R2)=, and in this case, R2 represents a linking moiety. Furthermore, “n2” in the general formula (A-1) represents an integer of from 1 to 4, and “*” represents a linking moiety with Y1 in the general formula (2).

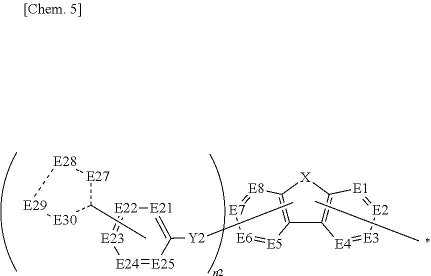

In the general formula (A-2), “X” represents —N(R)—, —O—, —S— or —Si(R)(R′)—. “E1” to “E8” each represent —C(R1)= or —N═. Meanwhile, R, R′ and R1 each represent hydrogen atom, a substituent or a linking moiety with “Y1.” In addition, “Y2” in the general formula (A-2) represents simply a bond or a divalent linking group. “E21” to “E25” each represent —C(R2)= or —N═, and “E26” to “E30” each represent —C(R2)=, —N═, —O—, —S— or —Si(R3)(R4)-. At least one of “E21” to “E30” represents —N═. Meanwhile, R2 represents hydrogen atom, a substituent or a linking moiety, and R3 and R4 each represent hydrogen atom or a substituent. Furthermore, at least one of “E21” and “E22” represents —C(R2)=, and R2 represents a linking moiety. Furthermore, “n2” in the general formula (A-2) represents an integer of 1 to 4, and “*” represents a linking moiety with Y1 in the general formula (2).

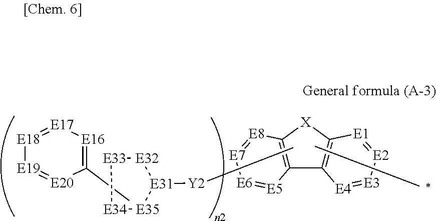

In the general formula (A-3), “X” represents —N(R)—, —O—, —S— or —Si(R)(R′)—. “E1” to “E8” each represent —C(R1)= or —N═.

Meanwhile, R, R′ and R1 each represent hydrogen atom, a substituent or a linking moiety with “Y1.” In addition, “Y2” in the general formula (A-3) represents simply a bond or a divalent linking group. “E31” to “E35” each represent —C(R2)=, —N═, —O—, —S— or —Si(R3) (R4)-, and “E36” to “E40” each represent —C(R2)= or —N═. At least one of “E31” to “E40” represents —N═. Meanwhile, R2 represents hydrogen atom, a substituent or a linking moiety, and R3 and R4 each represent hydrogen atom or a substituent. Furthermore, at least one of “E32” and “E33” represents —C(R2)=, and in this case, R2 represents a linking moiety. Furthermore, “n2” in the general formula (A-3) represents an integer of 1 to 4, and “*” represents a linking moiety with Y1 in the general formula (2).

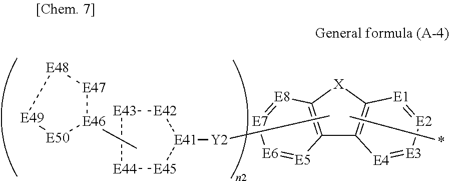

In the general formula (A-4), “X” represents —N(R)—, —O—, —S— or —Si(R)(R′)—. “E1” to “E8” each represent —C(R1)= or —N═. Meanwhile, R, R′ and R1 each represent hydrogen atom, a substituent or a linking moiety with “Y1.” In addition, “Y2” in the general formula (A-4) represents simply a bond or a divalent linking group. “E41” to “E50” each represent —C(R2)=, —N═, —O—, —S— or —Si(R3) (R4)-, and “E41” to “E50” each represent —C(R2)= or —N═. At least one of “E41” to “E50” represents —N═. Meanwhile, R2 represents hydrogen atom, a substituent or a linking moiety, and R3 and R4 each represent hydrogen atom or a substituent. Furthermore, at least one of “E42” and “E43” represents —C(R2)=, and R2 represents a linking moiety. Furthermore, “n2” in the general formula (A-4) represents an integer of 1 to 4, and “*” represents a linking moiety with Y1 in the general formula (2).

Meanwhile, in —N(R)— or —Si(R)(R′)— represented by “X” in the general formulae (A-1) to (A-4), and in —C(R1)=represented by “E1” to “E8”, a substituent represented by each of R, R′ and R1 has the same meaning as that the substituent represented by “Y1” in the general formula (2). Furthermore, in the general formulae (A-1) to (A-4), the divalent linking group represented by “Y2” has the same meaning as that of the divalent linking group represented by “Y1” in the general formula (2). Moreover, the substituent represented by R2 in —C(R2)= in each of “E11” to “E20” in the general formula (A-1), each of “E21” to “E30” in the general formula (A-2), each of “E31” to “E40” in the general formula (A-3) and each of “E41” to “E50” in the general formula (A-4) the same meaning as that of the substituent represented by “Y1” in the general formula (2).

[Heterocyclic Compound Represented by General Formula (3)]

Next, a more preferable aspect in the heterocyclic compound represented by the general formula (2) will be explained. In the present embodiment, the use of the heterocyclic compound represented by a general formula (3) below is preferable, among heterocyclic compounds represented by the general formula (2). Hereinafter, the heterocyclic compound represented by the general formula (3) will be explained.

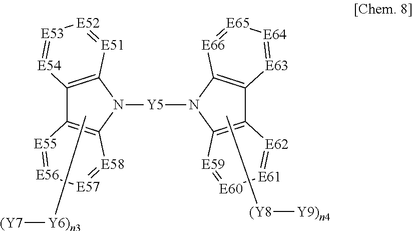

In the general formula (3), “Y5” represents a divalent linking group formed of an arylene group, a heteroarylene group or a combination thereof. “E51” to “E66” each represent —C(R3)= or —N═. Meanwhile, R3 represents hydrogen atom or a substituent. Furthermore, “Y6” to “Y9” each in the general formula (3) represent a group derived from an aromatic hydrocarbon ring or a group derived from an aromatic heterocyclic ring. Meanwhile, at least one of “Y6” and “Y7” and at least one of “Y8” and “Y9” each represent a group derived from an aromatic heterocyclic ring containing N atom. Moreover, “n3” and “n4” each in the general formula (3) represent an integer of 0 to 4, and “n3”+“n4” is an integer of 2 or more.

In the general formula (3), an arylene group and a heteroarylene group represented by “Y5” has the same meaning as that of the arylene group and the heteroarylene group, respectively, described as an example of the divalent linking group represented by “Y1” in the general formula (2). Meanwhile, as the aspect of the divalent linking group formed of the arylene group or the heteroarylene group represented by “Y5” or the combination thereof, it is preferable to contain a group derived from a condensed aromatic heterocyclic ring constituted by the condensation of rings of tri- or more cyclic ring among heteroarylene groups, and the group derived from a condensed aromatic heterocyclic ring constituted by the condensation of rings of tri- or more cyclic ring is preferably a group derived from a dibenzofuran ring or a group derived from a dibenzothiophene ring.

Meanwhile, in the general formula (3), the substituent represented by R3 in —C(R3)=represented by each of “E51” to “E66” has the same meaning as that of the substituent represented by “Y1” in the general formula (2). Furthermore, in the group represented by each of “E51” to “E66” in the general formula (3), preferably 6 or more among “E51” to “E58” and 6 or more among “E59” to “E66” respectively are represented by —C(R3)=.

In the general formula (3), examples of the aromatic hydrocarbon ring used for the formation of a group derived from the aromatic hydrocarbon ring represented by each of “Y6” to “Y9” include benzene ring, biphenyl ring, naphthalene ring, azulene ring, anthracene ring, phenanthrene ring, pyrene ring, chrysene ring, naphthalene ring, triphenylene ring, o-terphenyl ring, m-terphenyl ring, p-terphenyl ring, acenaphthene ring, coronene ring, fluorene ring, fluoranthrene ring, naphthacene ring, pentacene ring, perylene ring, pentaphene ring, picene ring, pyrene ring, pyranthrene ring, anthranthrene ring, and the like. Furthermore, the aromatic hydrocarbon ring may have a substituent represented by “Y1” in the general formula (2).

In the general formula (3), examples of the aromatic heterocyclic ring used for the formation of a group derived from the aromatic heterocyclic ring represented by each of “Y6” to “Y9” include furan ring, thiophene ring, oxazole ring, pyrrole ring, pyridine ring, pyridazine ring, pyrimidine ring, pyrazine ring, triazine ring, benzimidazole ring, oxadiazole ring, triazole ring, imidazole ring, pyrazole ring, triazole ring, indole ring, indazole ring, benzimidazole ring, benzothiazole ring, benzoxazole ring, quinoxaline ring, quinazoline ring, cinnoline ring, quinoline ring, isoquinoline ring, phthalazine ring, naphthylidine ring, carbazole ring, carboline ring, diazacarbazole ring (represents a ring obtained by further substituting one of carbon atoms constituting the carboline ring by a nitrogen atom), and the like. Furthermore, the aromatic hydrocarbon ring may have a substituent represented by “Y1” in the general formula (2).

In the general formula (3), examples of the aromatic heterocyclic ring containing N atom used for the formation of a group derived from the aromatic heterocyclic ring containing N atom represented by at least one of “Y6” and “Y7” and at least one of “Y8” and “Y9” include oxazole ring, pyrrole ring, pyridine ring, pyridazine ring, pyrimidine ring, pyrazine ring, triazine ring, benzimidazole ring, oxadiazole ring, triazole ring, imidazole ring, pyrazole ring, thiazole ring, indole ring, indazole ring, benzimidazole ring, benzothiazole ring, benzoxazole ring, quinoxaline ring, quinazoline ring, cinnoline ring, quinoline ring, isoquinoline ring, phthalazine ring, naphthylidine ring, carbazole ring, carboline ring, diazacarbazole ring (represents a ring obtained by further substituting one of carbon atoms constituting the carboline ring by a nitrogen atom), and the like. In addition, in the general formula (3), the group represented by each of “Y7” and “Y9” is preferably a group derived from a pyridine ring. Furthermore, in the general formula (3), the group represented by each of “Y6” and “Y8” is preferably a group derived from a benzene ring.

[Heterocyclic Compound Represented by General Formula (4)]

Next, a more preferable form in the heterocyclic compound represented by the general formula (3) will be explained. In the present embodiment, among heterocyclic compounds represented by the general formula (3), the use of a heterocyclic compound represented by a general formula (4) below is preferable. Hereinafter, the heterocyclic compound represented by the general formula (4) will be explained.

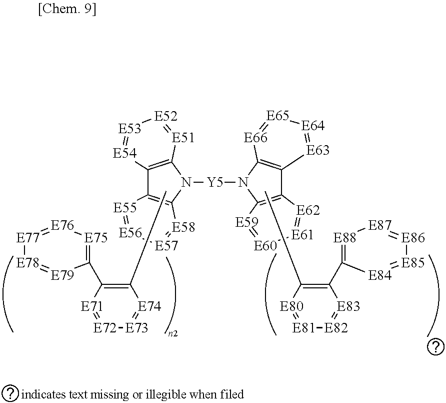

“Y5” in the general formula (4) represents a divalent linking group formed of an arylene group, a heteroarylene group or a combination thereof. “E51” to “E66” and “E71” to “E88” each represent —C(R3)= or —N═. Meanwhile, R3 represents a hydrogen atom or a substituent. In addition, at least one of “E71” to “E79” and at least one of “E80” to “E88” respectively represent —N═. Furthermore, each of “n3” and “n4” in the general formula (4) is an integer of from 0 to 4, and “n3”+“n4” is an integer of 2 or more.

An arylene group and a heteroarylene group represented by “Y5” in the general formula (4) has the same meaning as that of the arylene group and the heteroarylene group, respectively, described as an example of the divalent linking group represented by “Y1” in the general formula (2). Meanwhile, as the form of the divalent linking group formed of the arylene group or the heteroarylene group represented by “Y5” or the combination thereof, it is preferable to contain a group derived from a condensed aromatic heterocyclic ring constituted by the condensation of rings of tri- or more cyclic ring among heteroarylene groups, and the group derived from a condensed aromatic heterocyclic ring constituted by the condensation of rings of tri- or more cyclic ring is preferably a group derived from a dibenzofuran ring or a group derived from a dibenzothiophene ring.

A substituent represented by R3 in —C(R3)=represented by each of “E51” to “E66” and “E71” to “E88” in the general formula (4) has the same meaning as that of the substituent represented by “Y1” in the general formula (2). In addition, preferably 6 or more among “E51” to “E58” and 6 or more among “E59” to “E66” respectively are represented by —C(R3)= in the general formula (4). Furthermore, preferably at least one of “E75” to “E79” and at least one of “E84” to “E88” respectively are represented by —N═ in the general formula (4). Moreover, preferably any one of “E75” to “E79” and any one of “E84” to “E88” respectively are represented by —N═ in the general formula (4).

“E71” to “E74” and “E80” to “E83” each are preferably represented by —C(R3)= in the general formula (4). In addition, in a heterocyclic compound represented by the general formula (3) or the general formula (4), preferably “553” is represented by —C(R3)= and R3 represents a linking site, and furthermore, preferably, “E61” is also represented simultaneously by —C(R3)= and R3 represents a linking site. Moreover, preferably, “E75” and “E84” each are represented by —N═ and preferably, “E71” to “E74” and “E80” to “E83” each are represented by —C(R3)= in the general formula (4).

### Specific Examples of Heterocyclic Compound

Hereinafter, specific examples of heterocyclic compounds represented by the general formula (2), (3) or (4) (structural formulae HC1 to HC118 below) will be illustrated. Meanwhile, the heterocyclic compound that is usable in the present embodiment is not limited to the following specific examples.

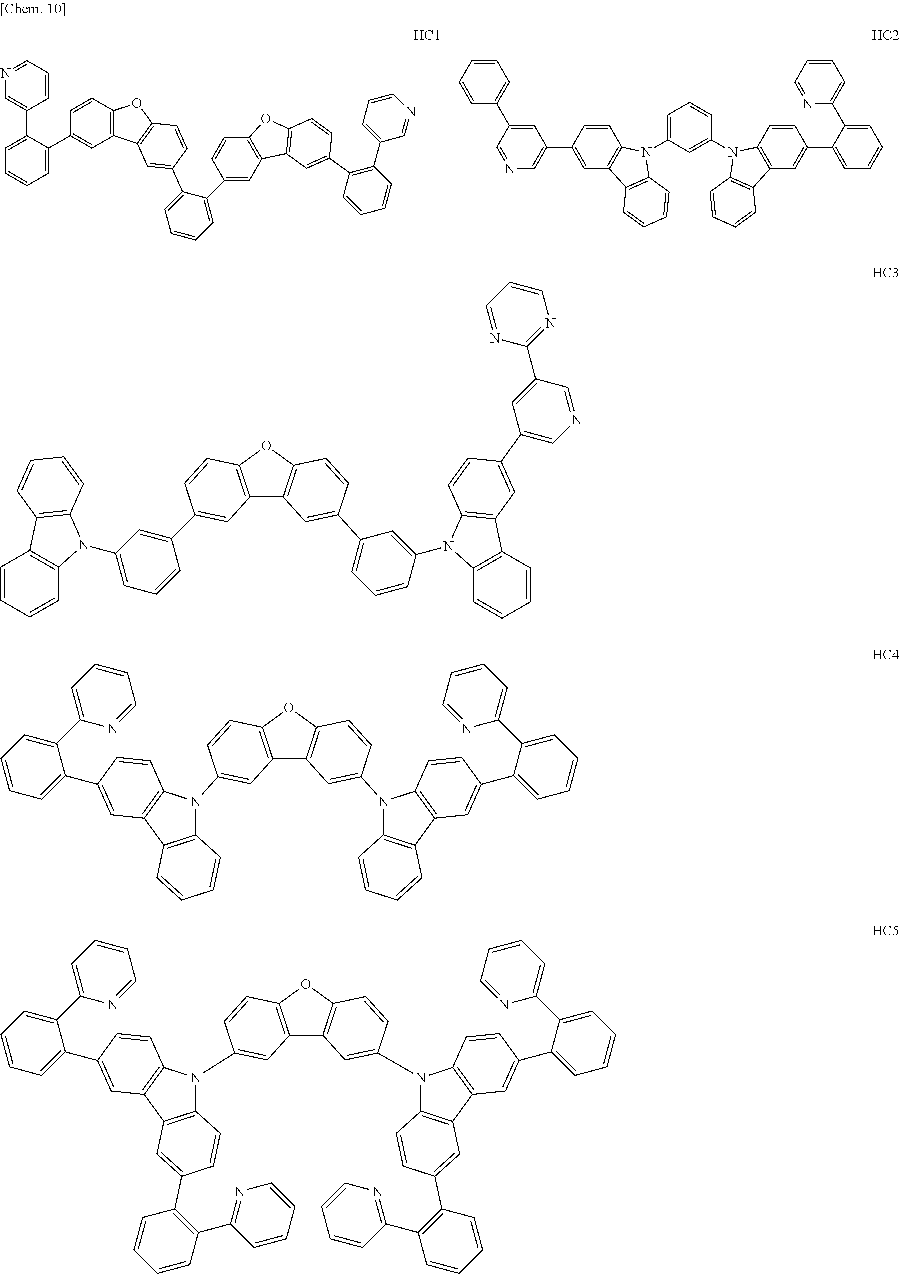

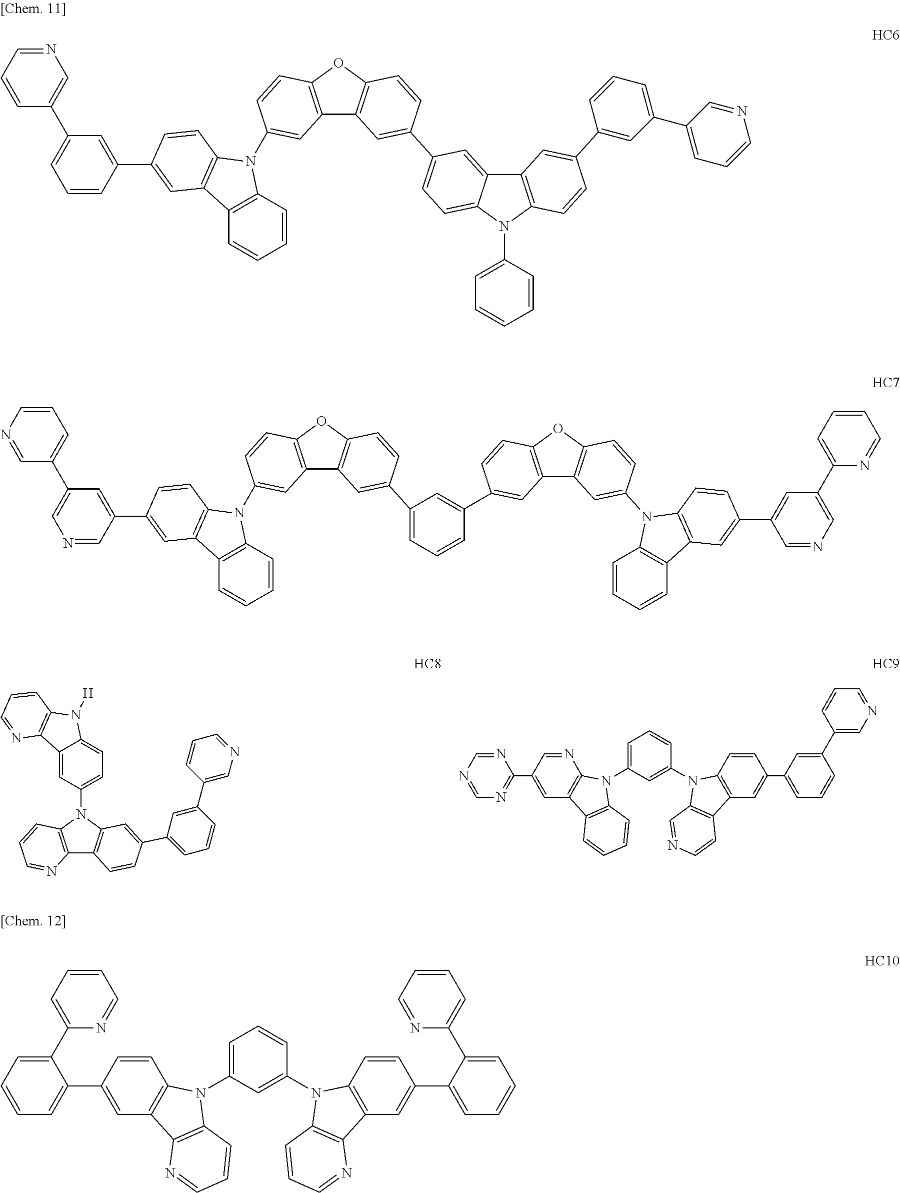

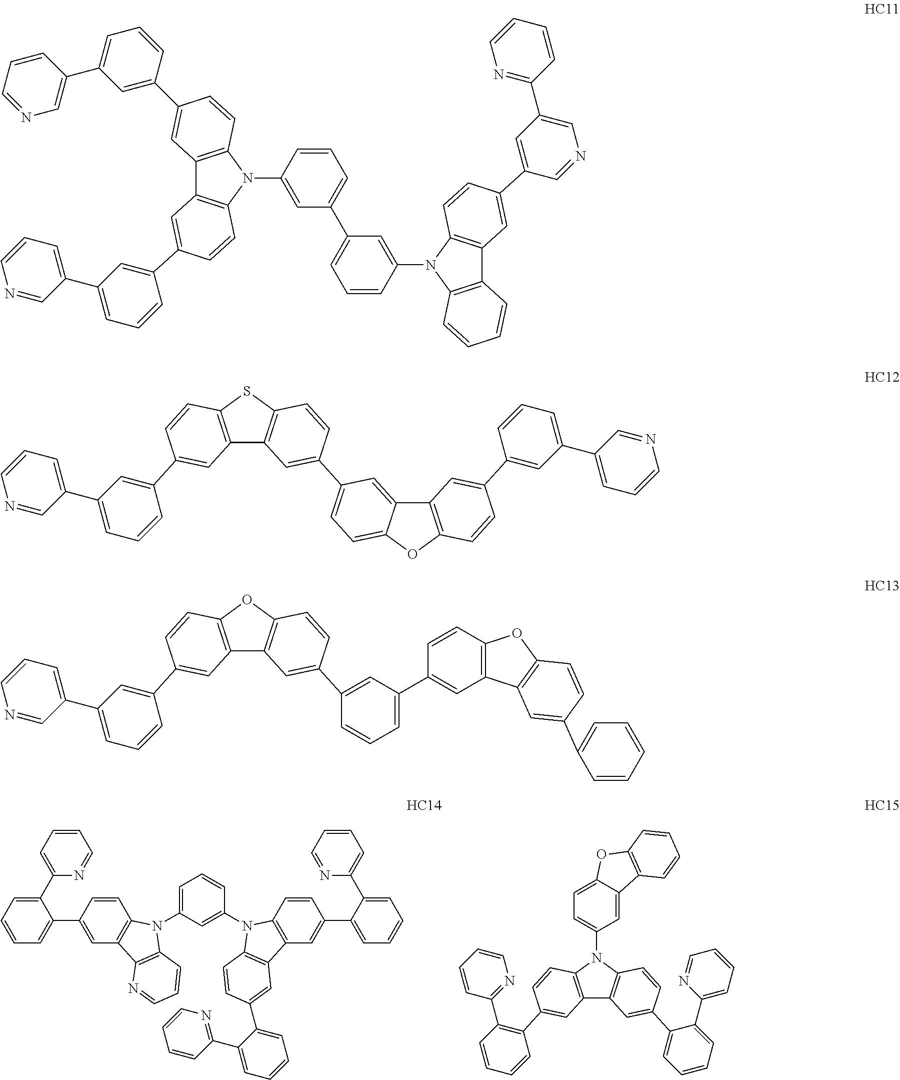

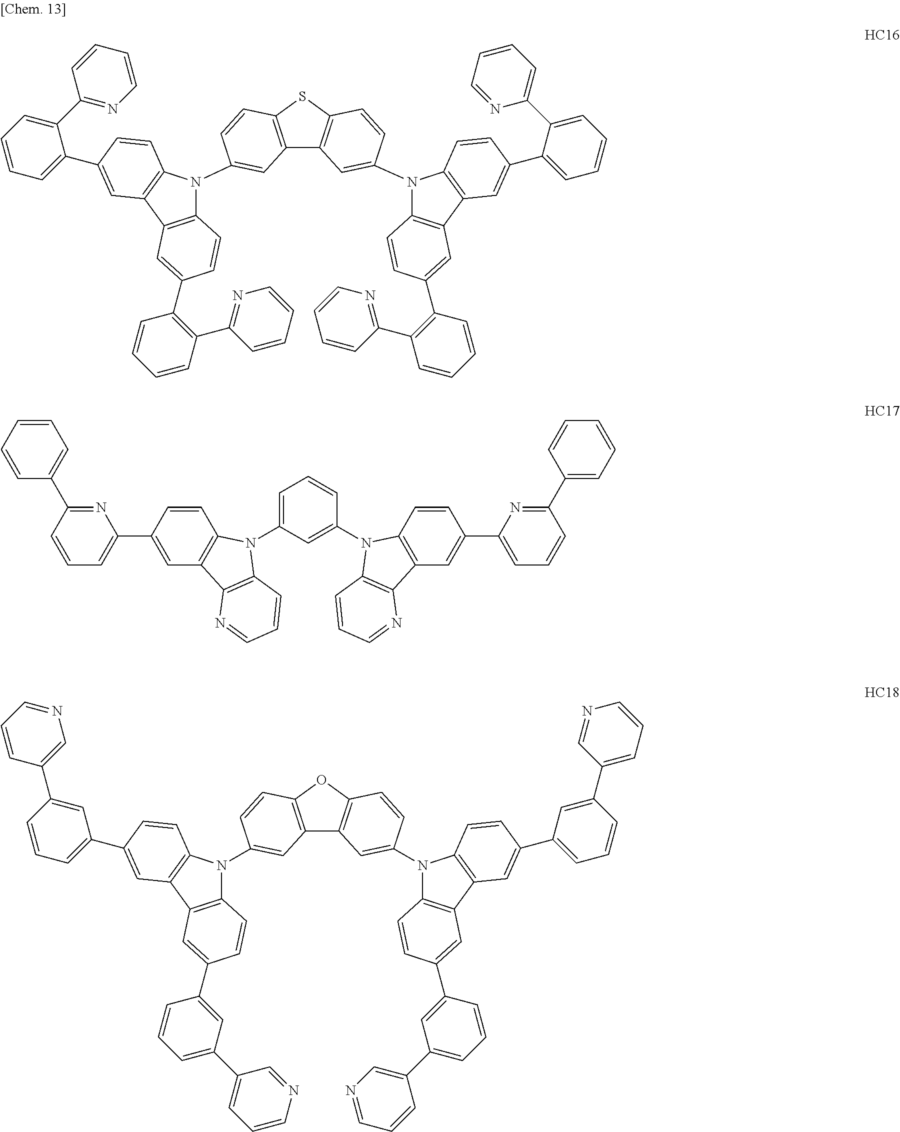

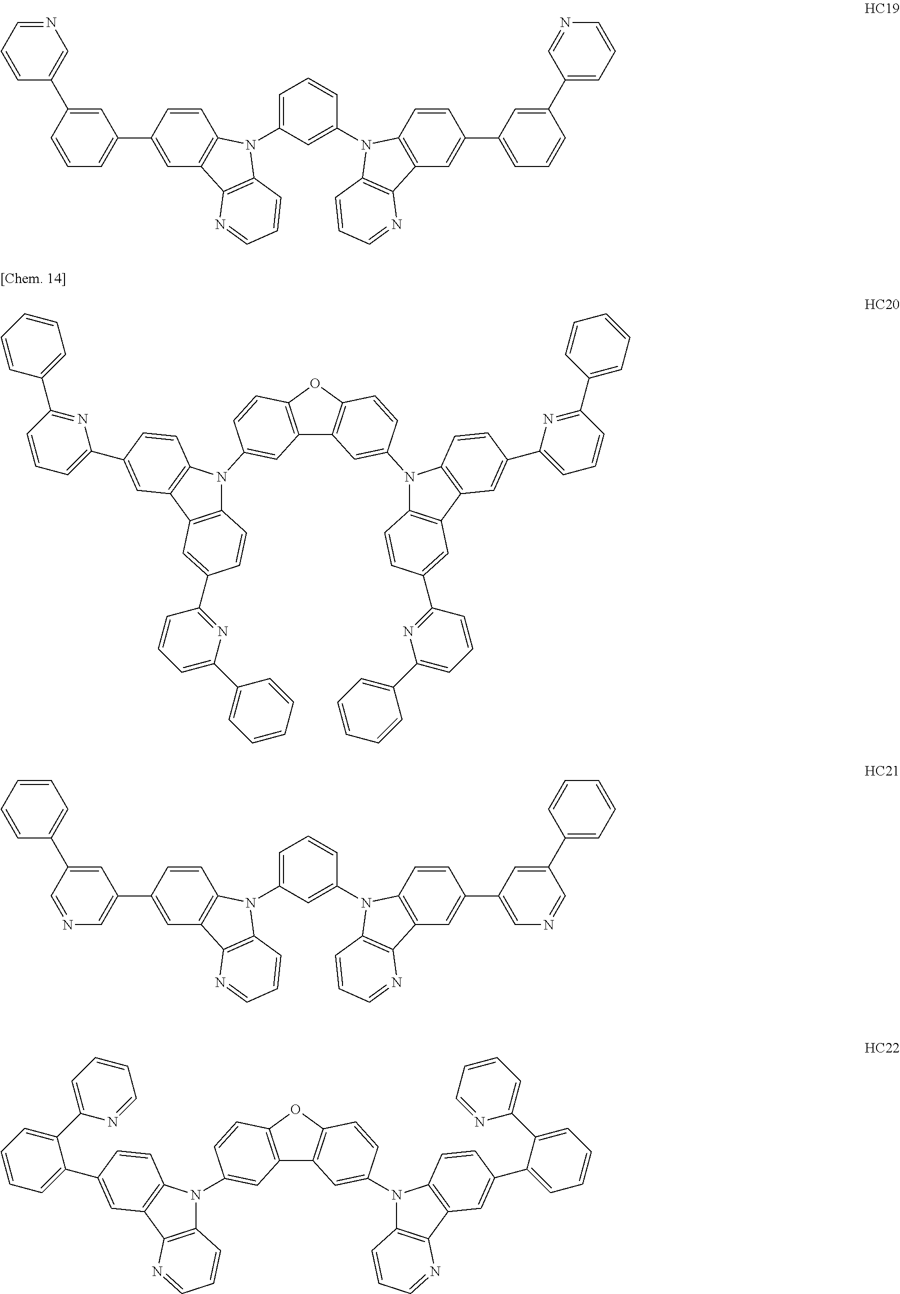

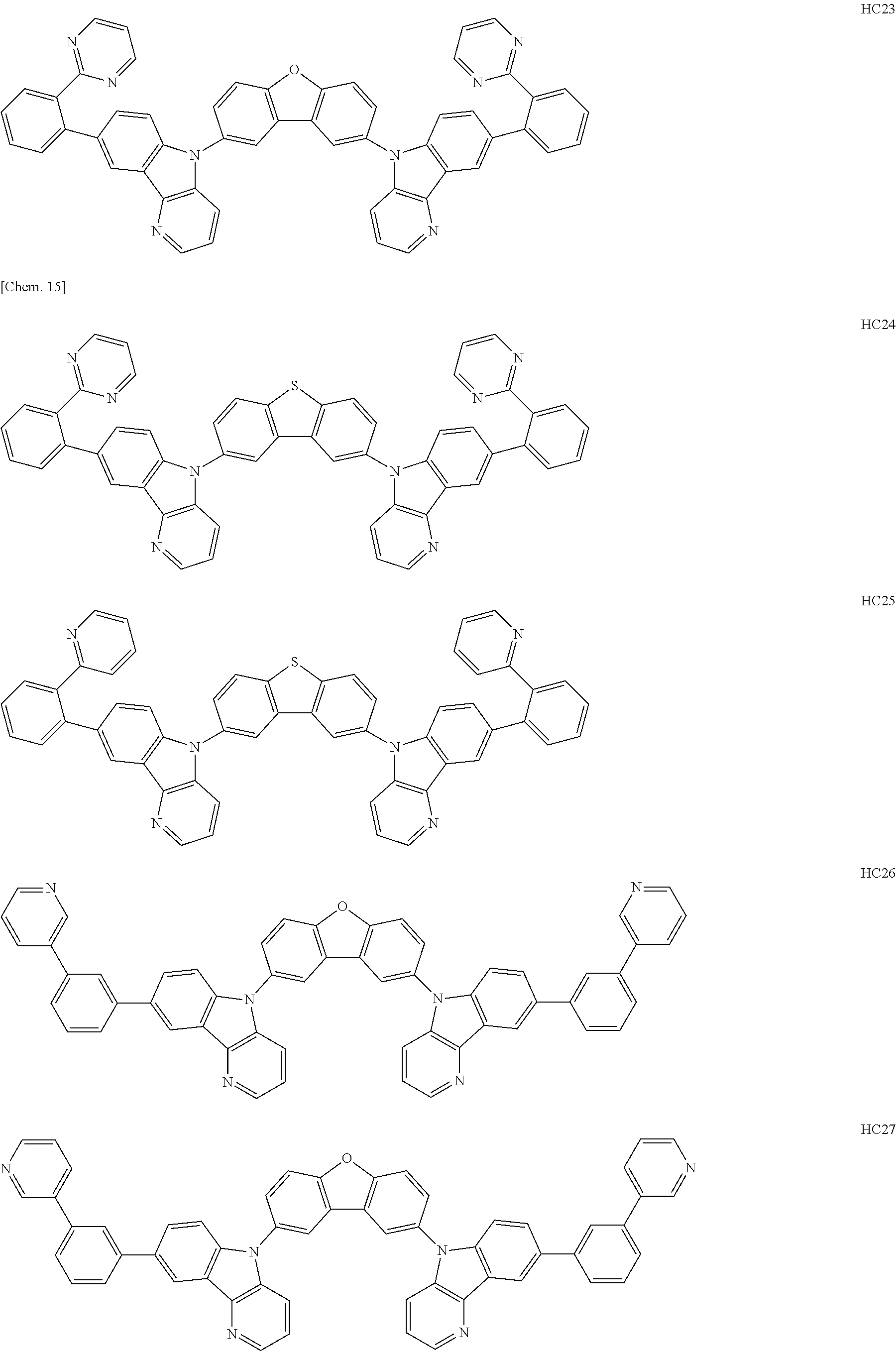

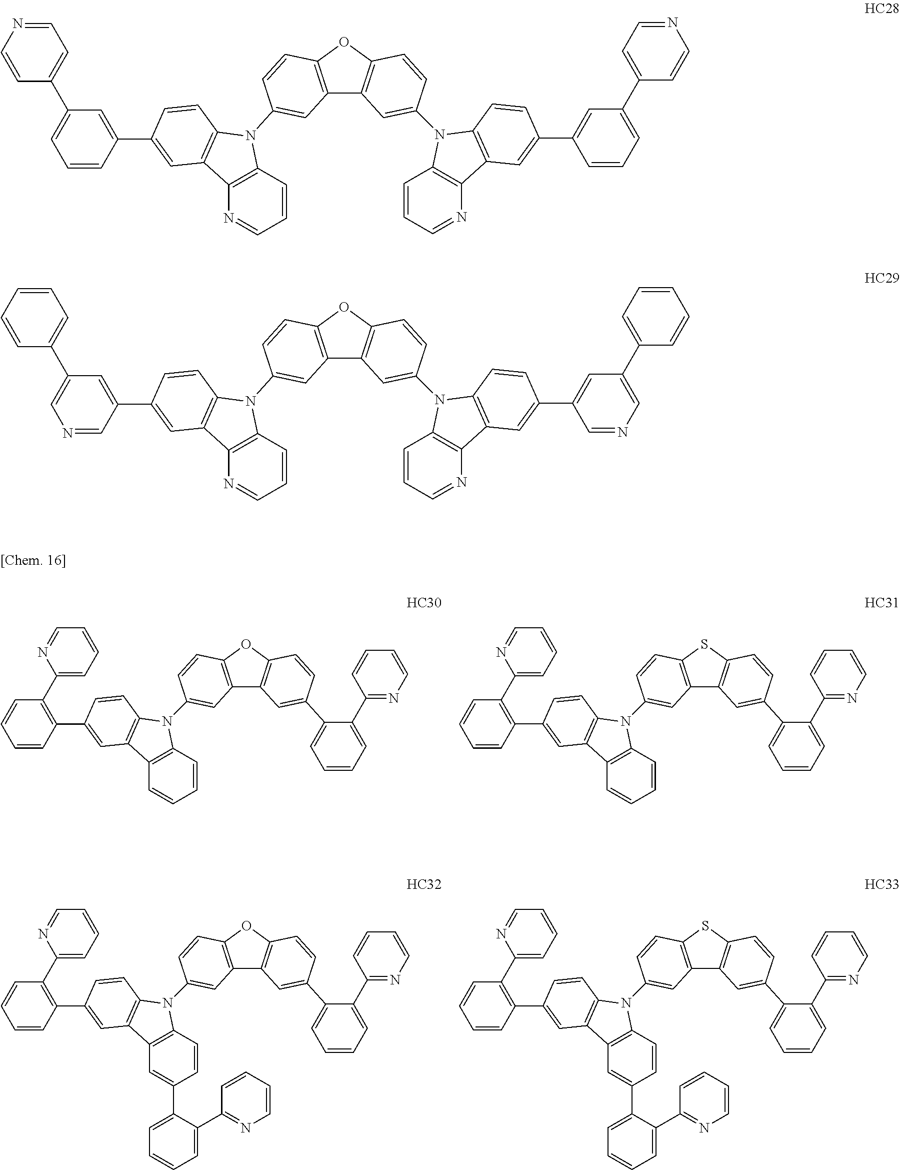

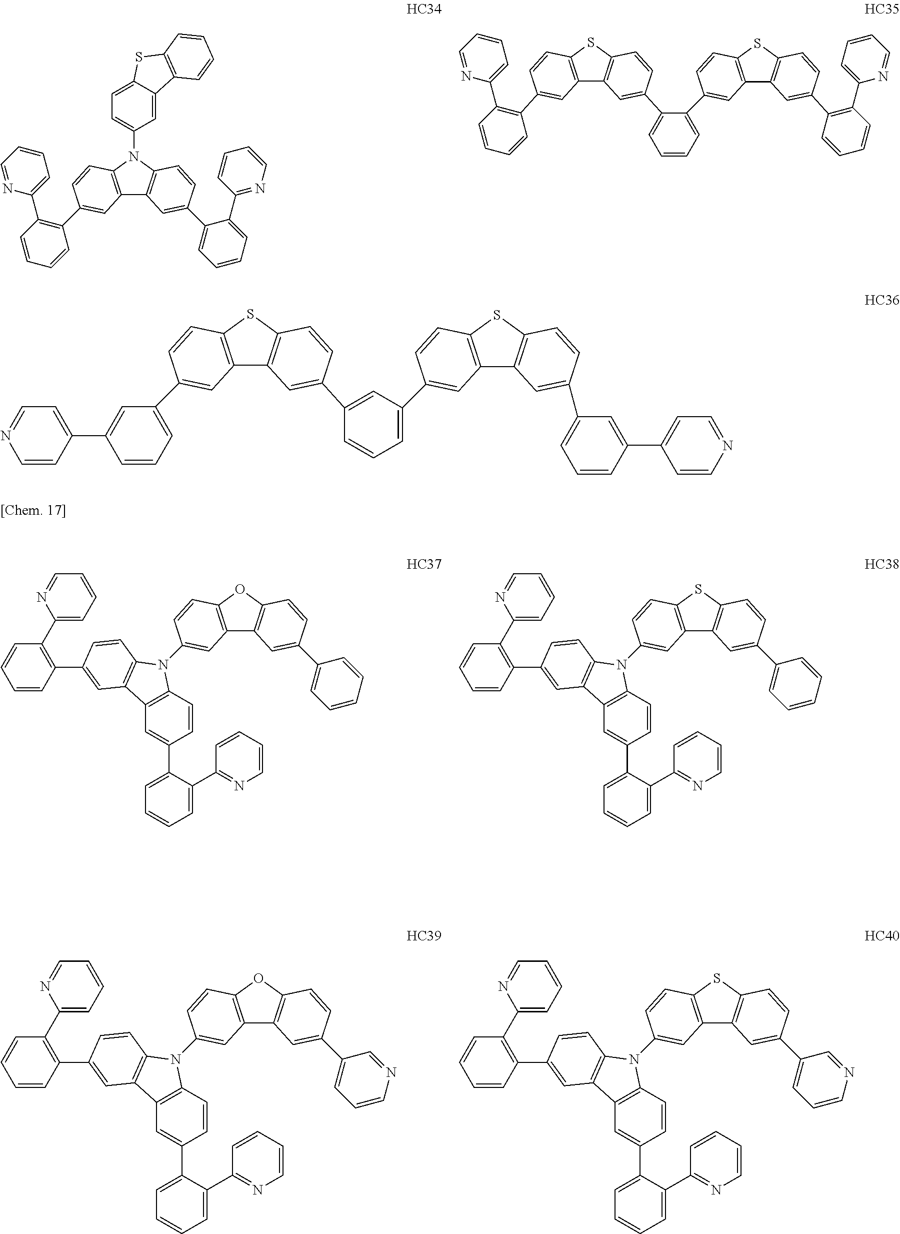

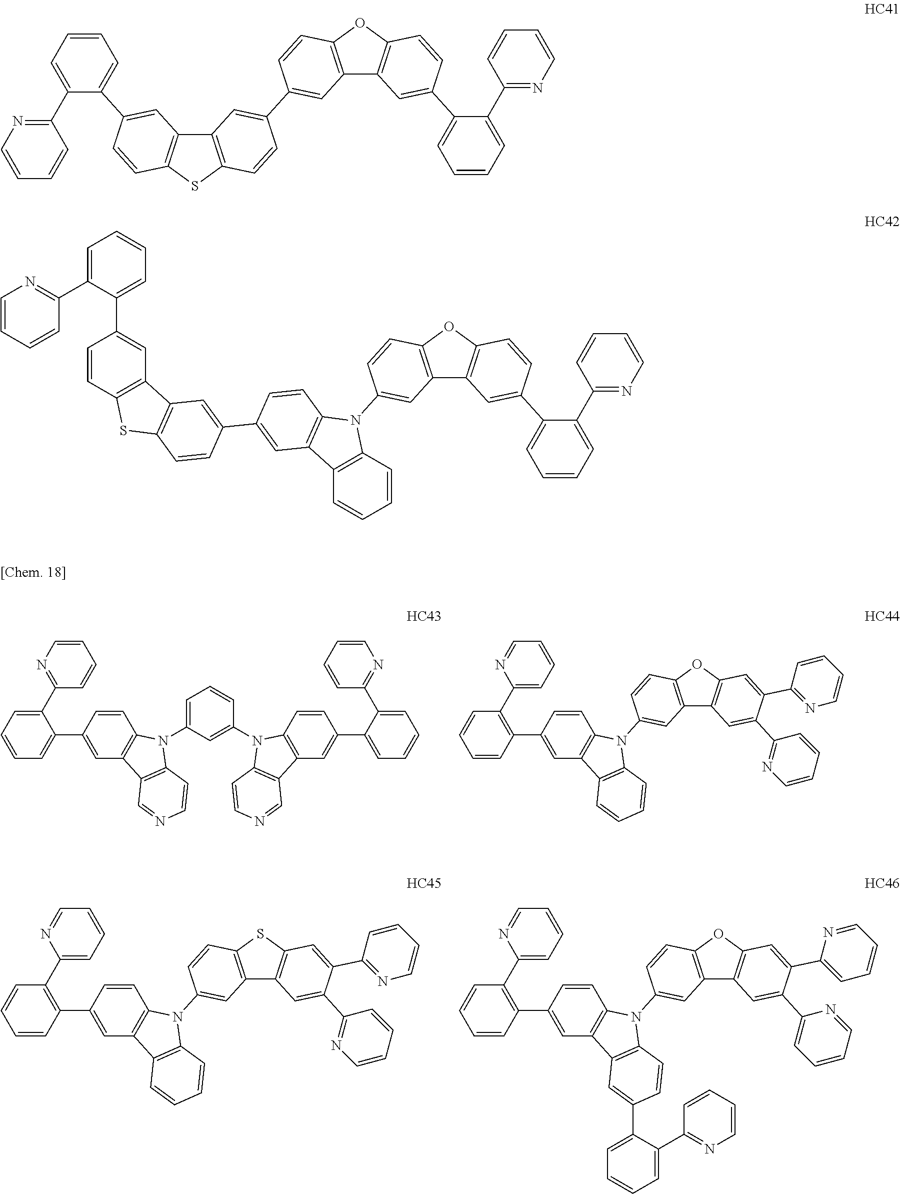

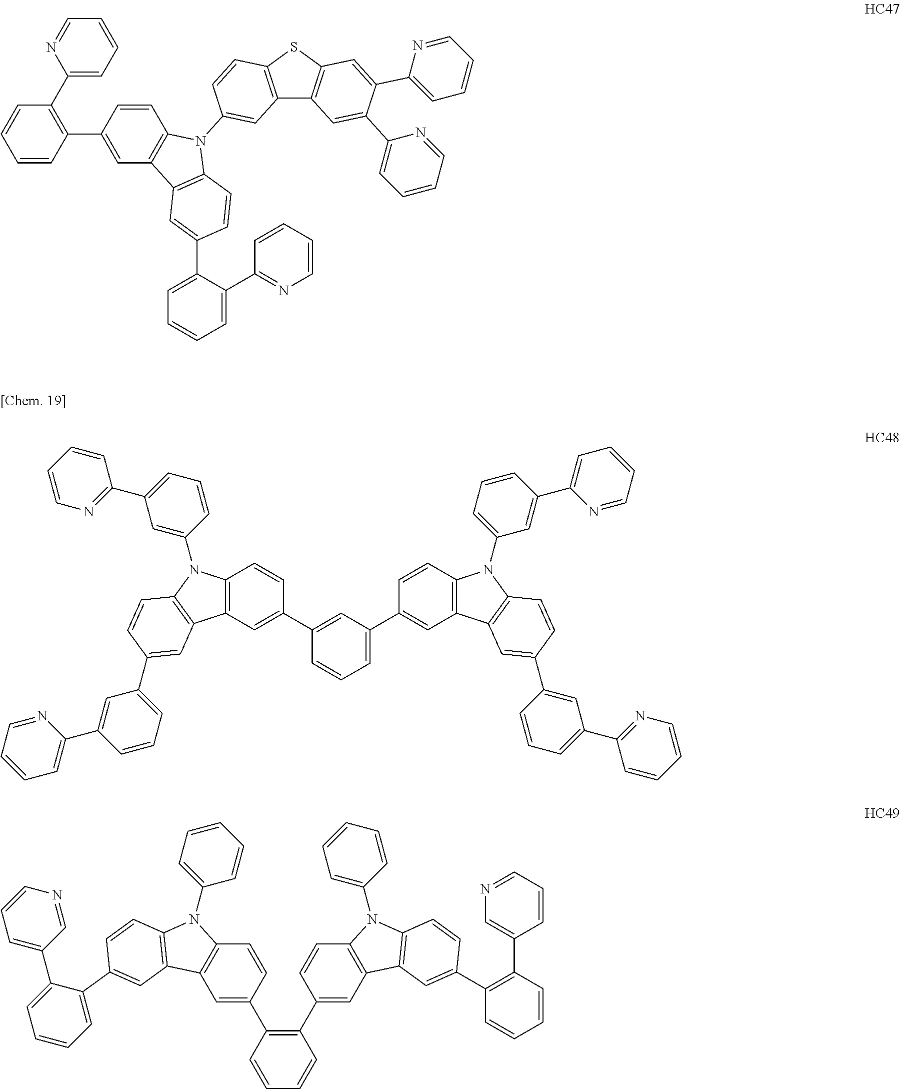

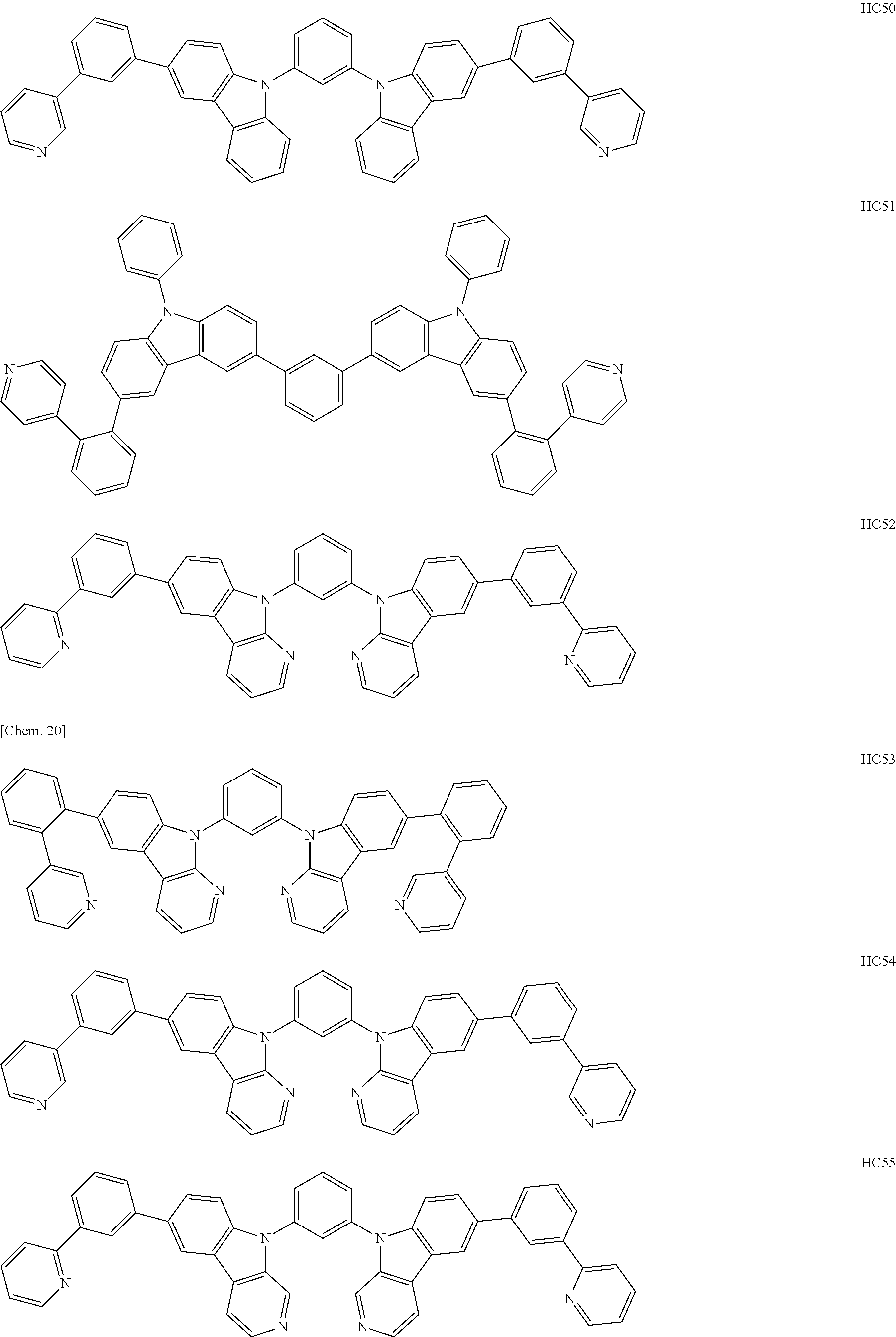

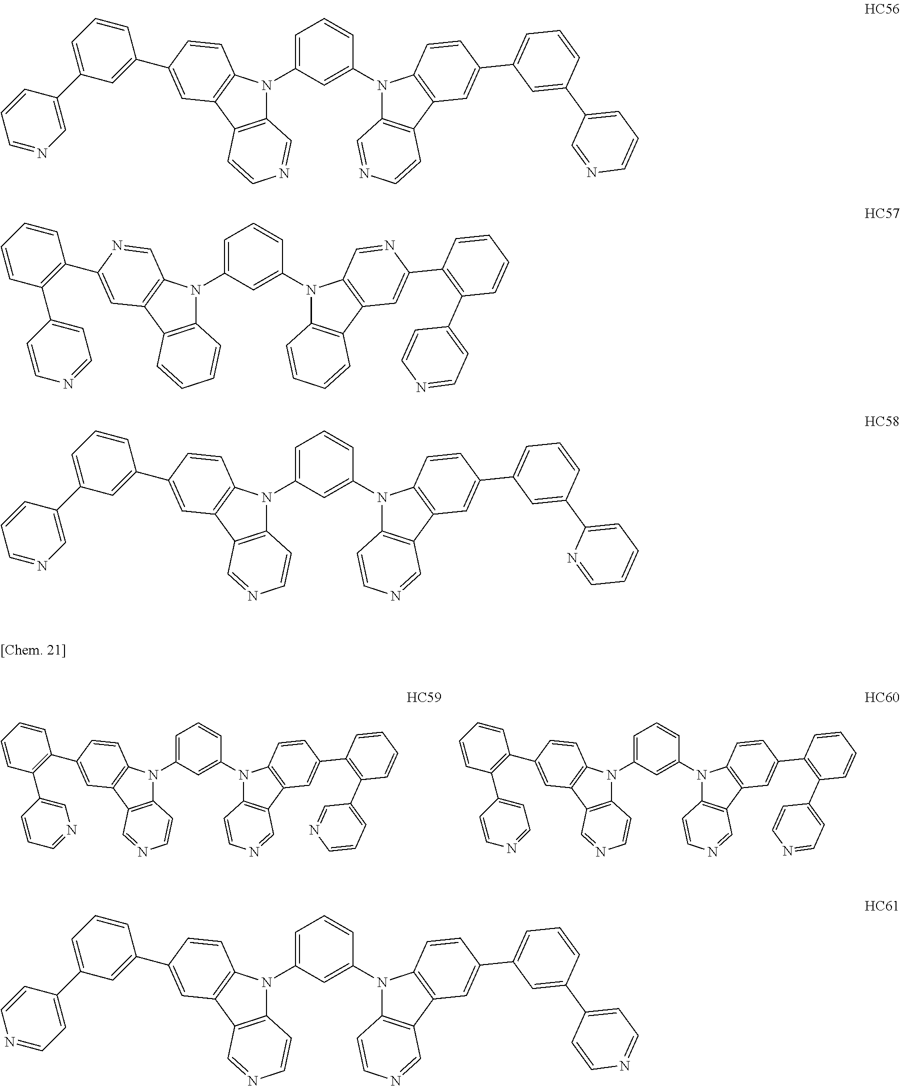

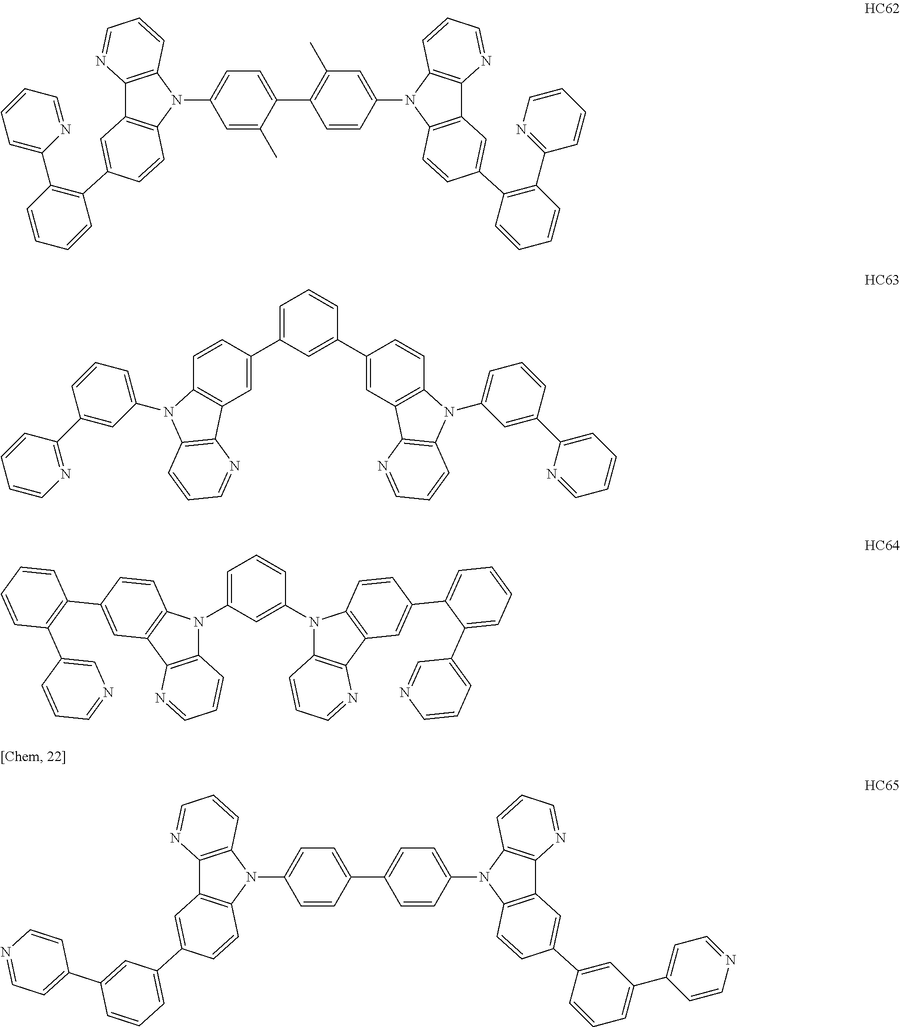

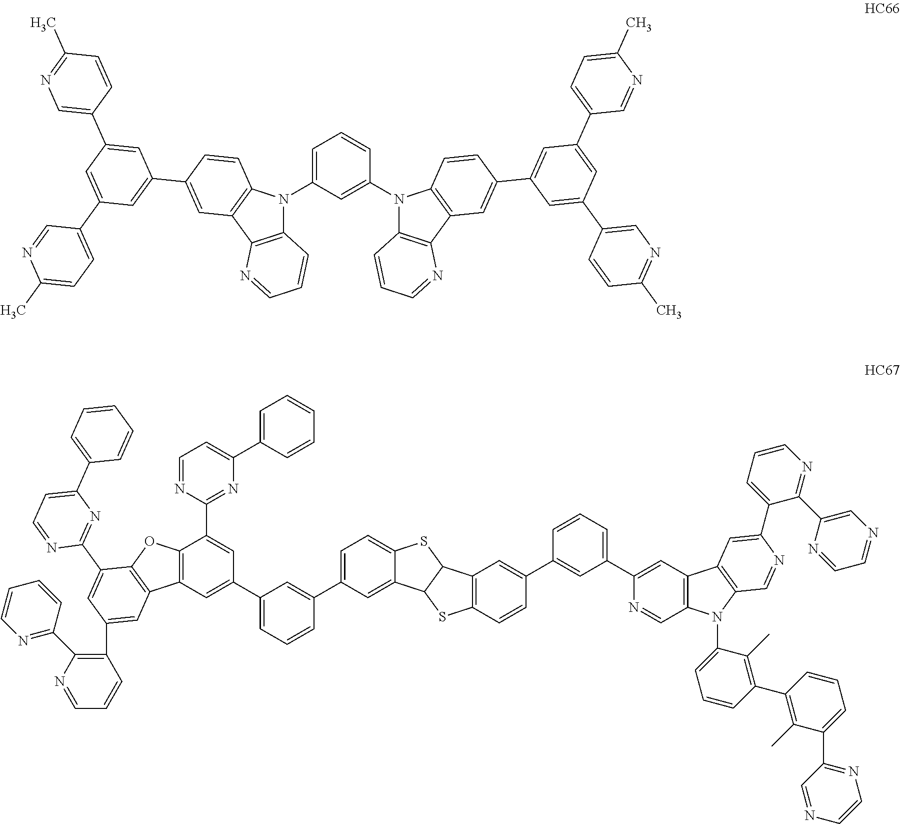

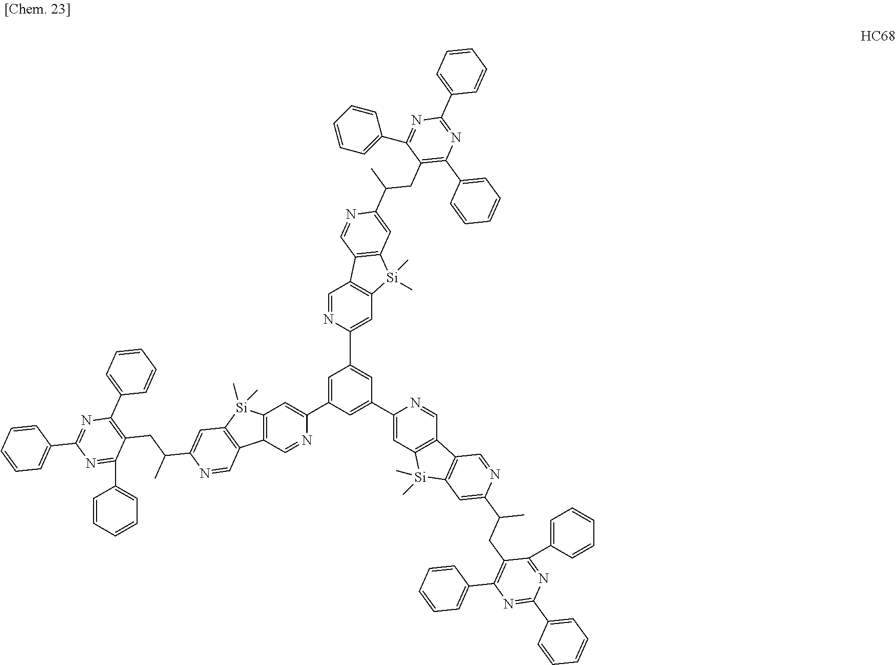

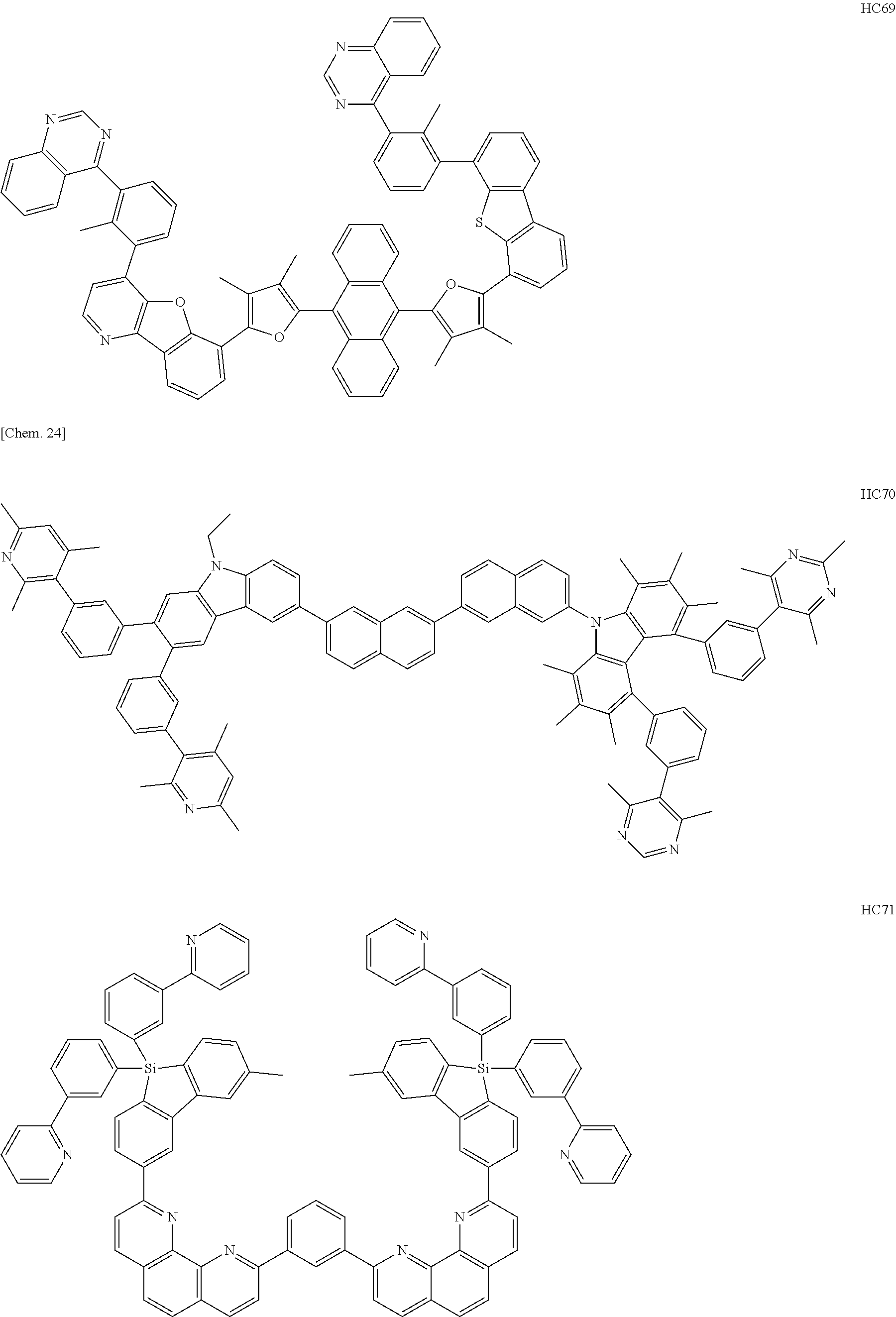

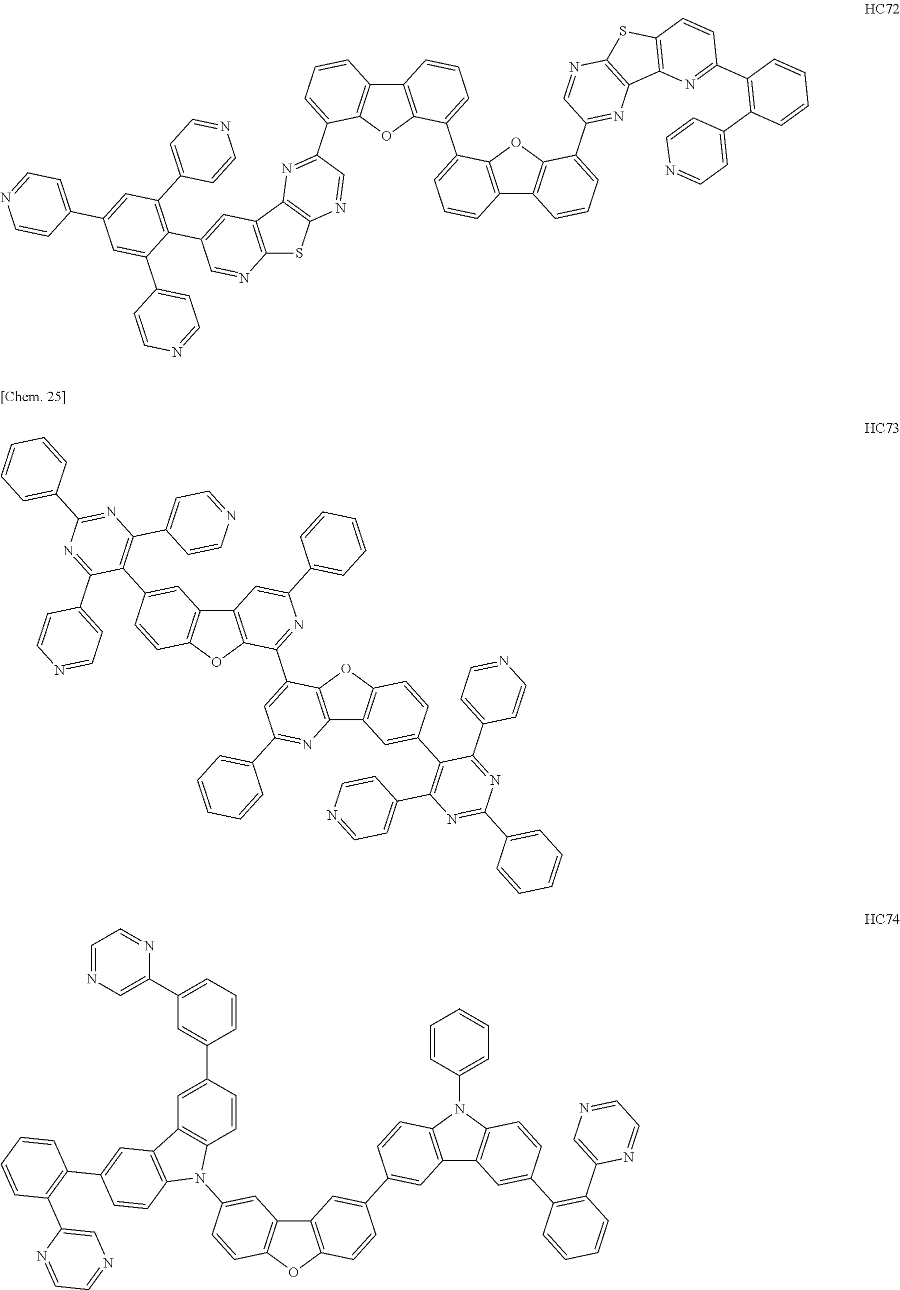

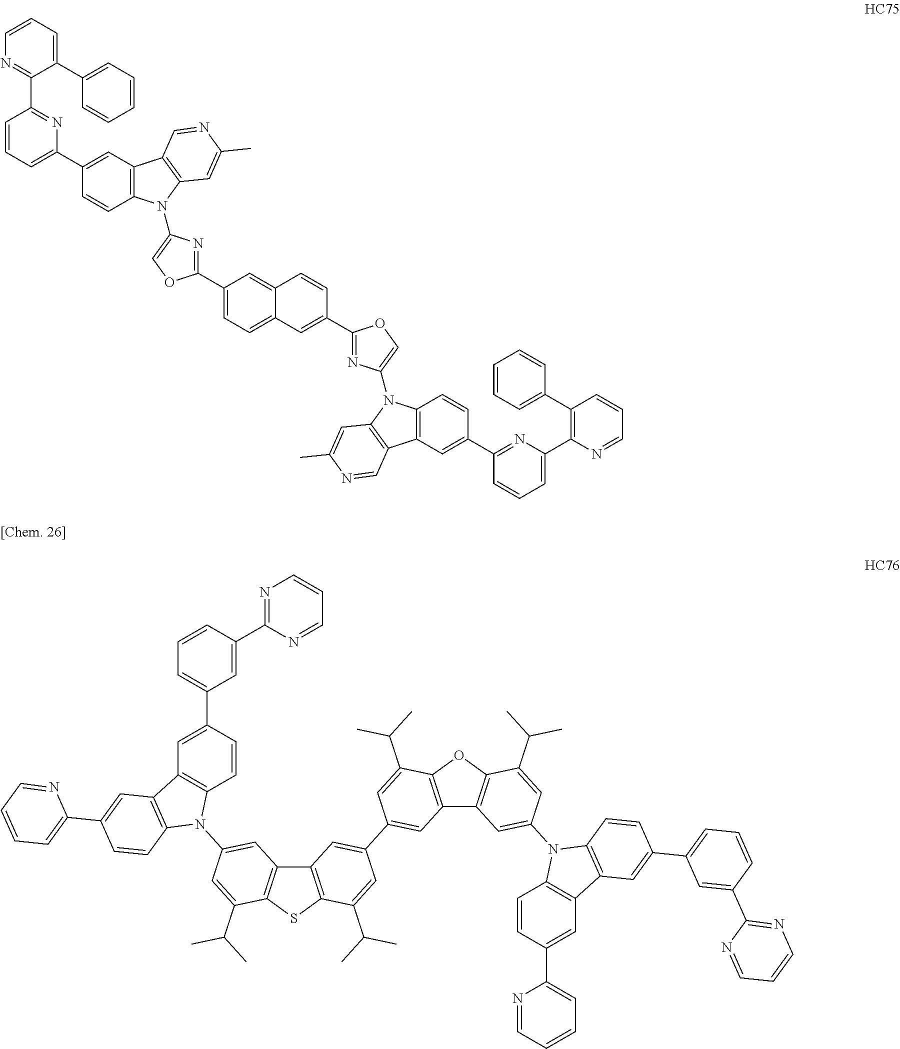

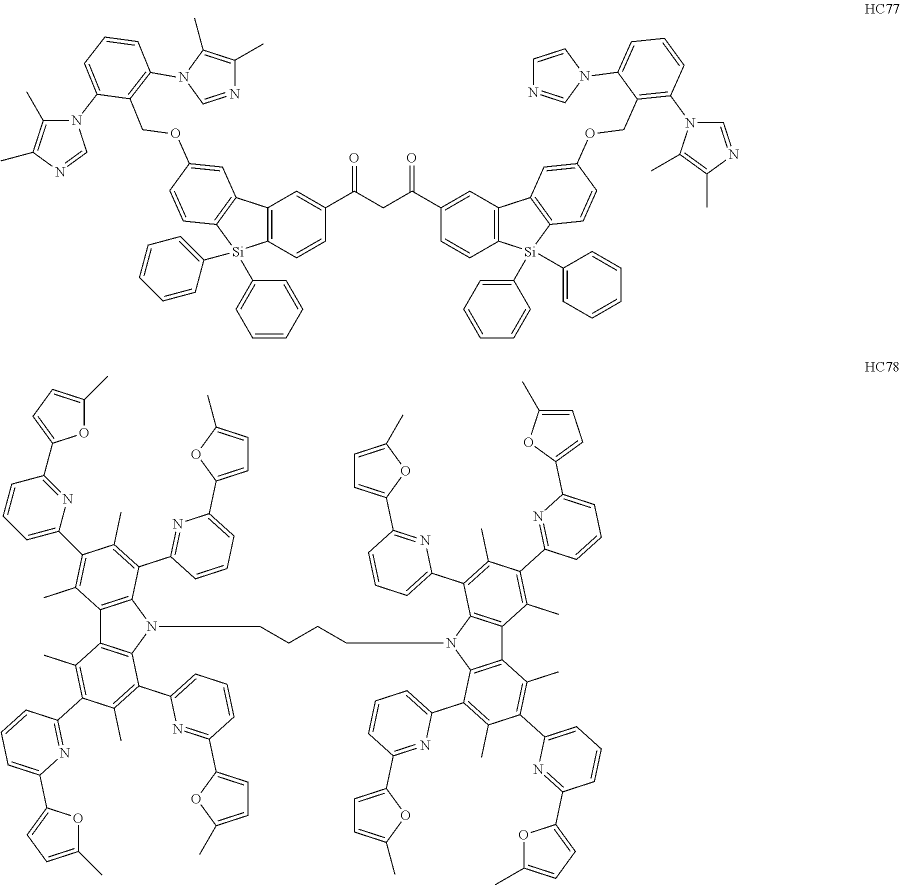

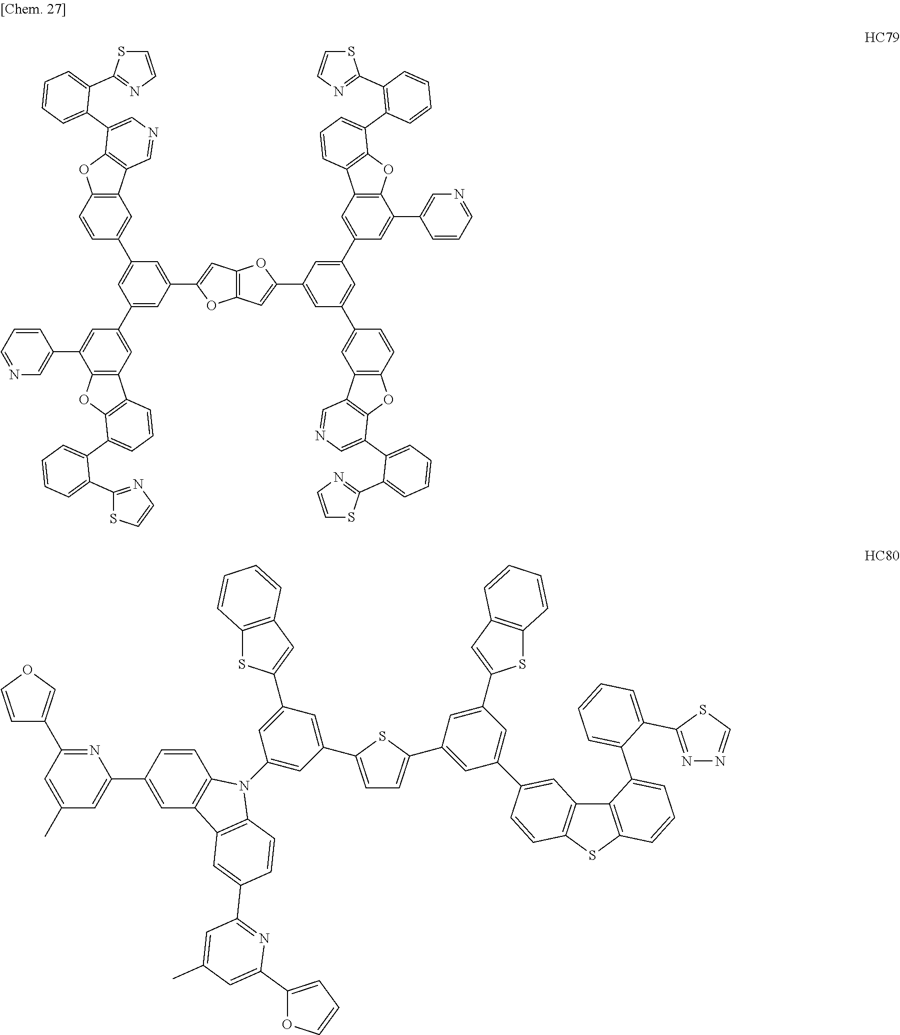

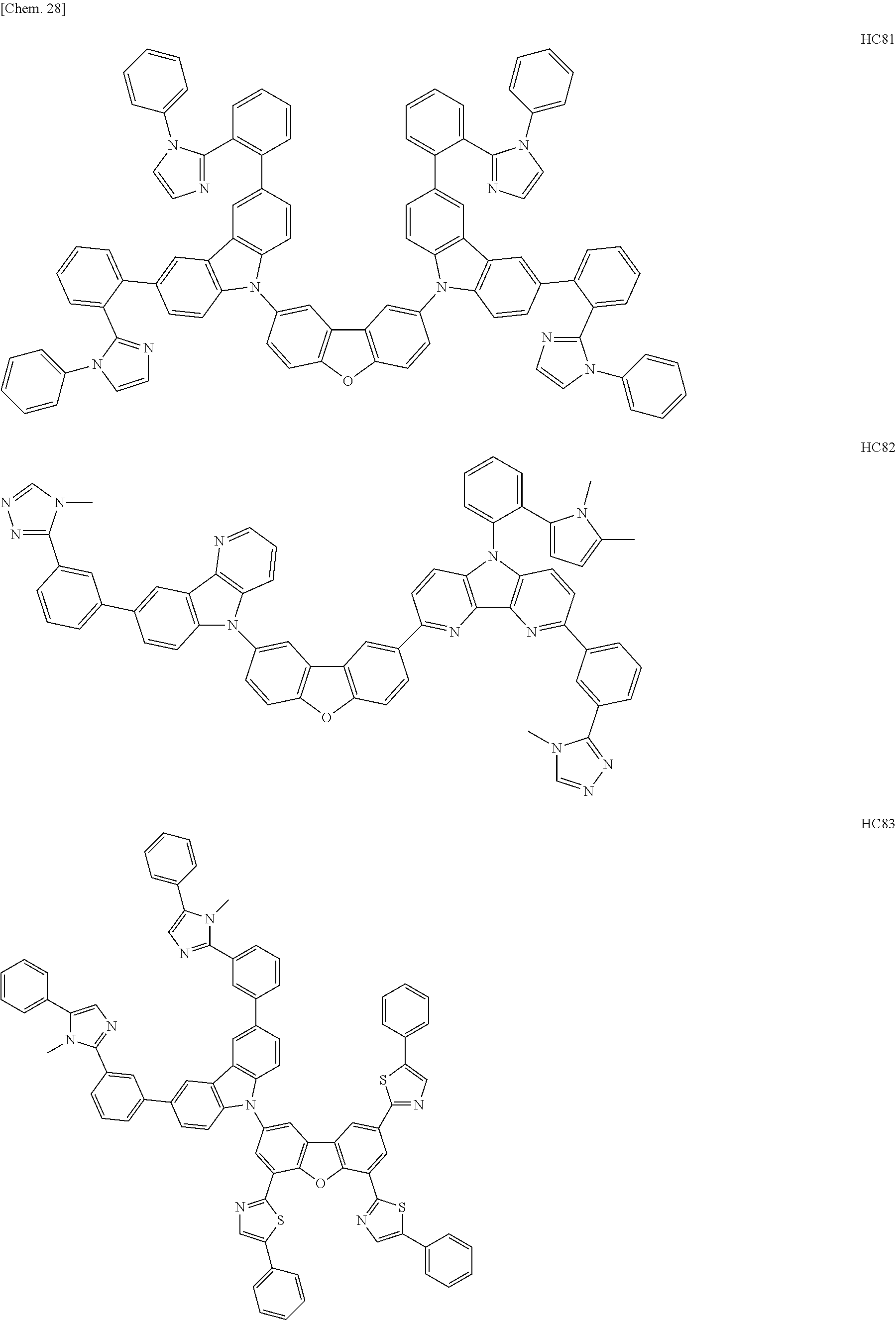

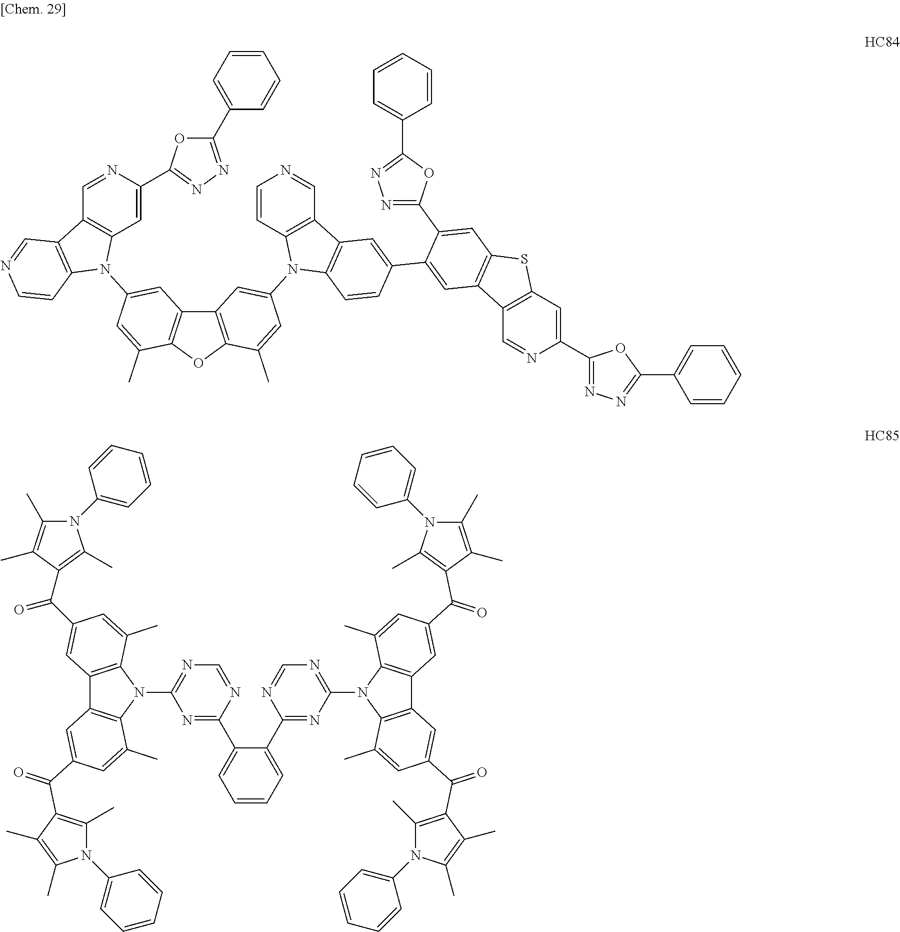

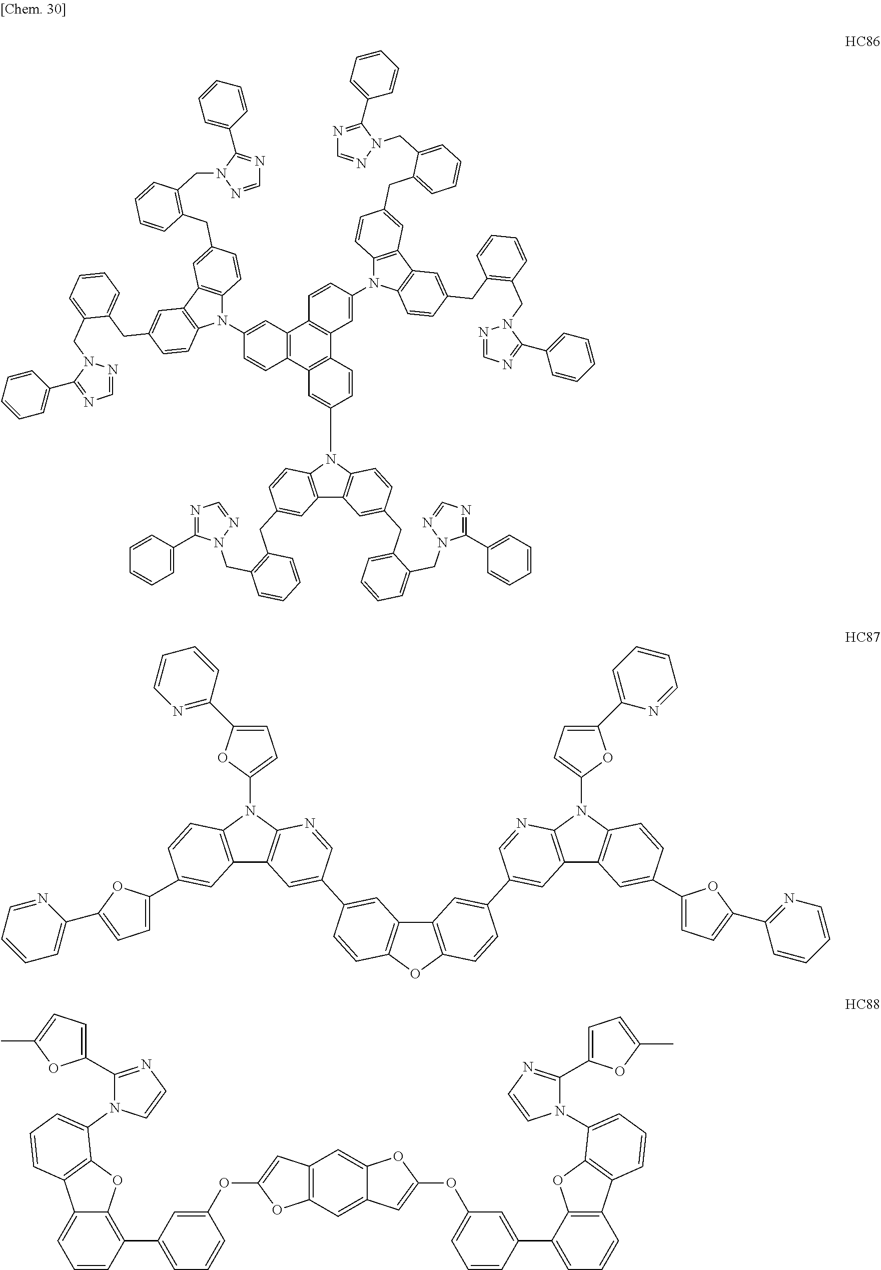

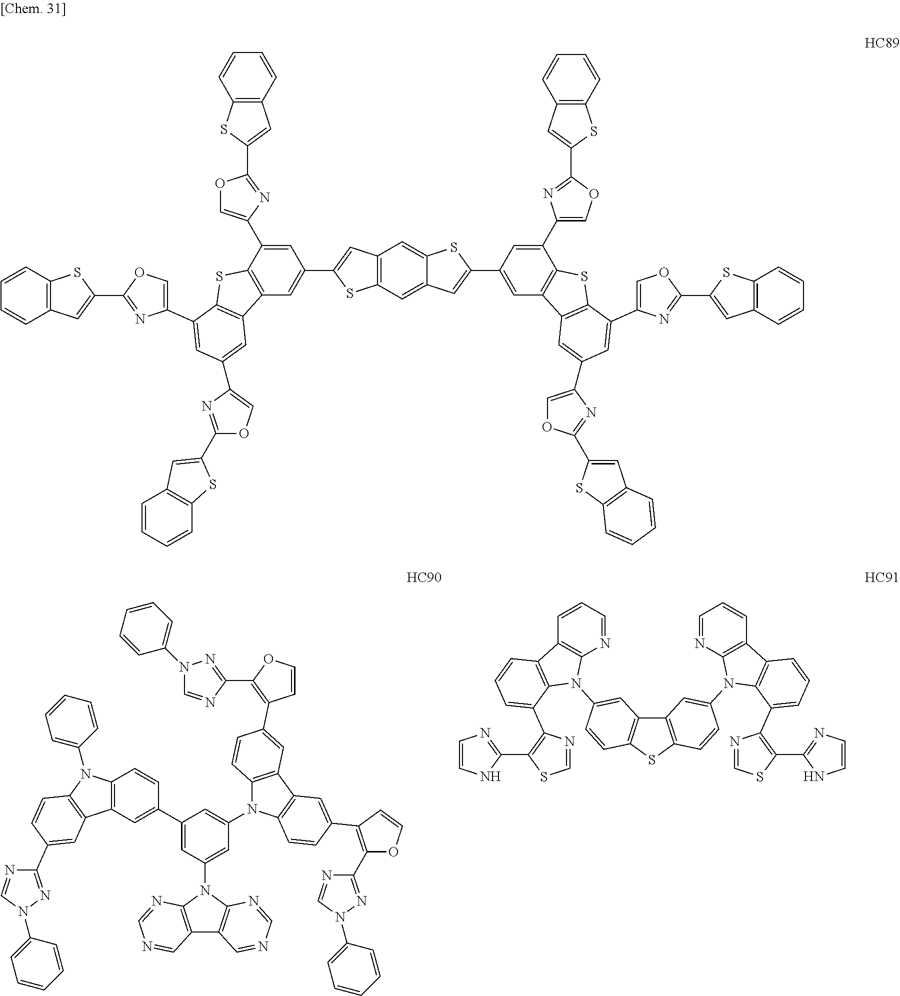

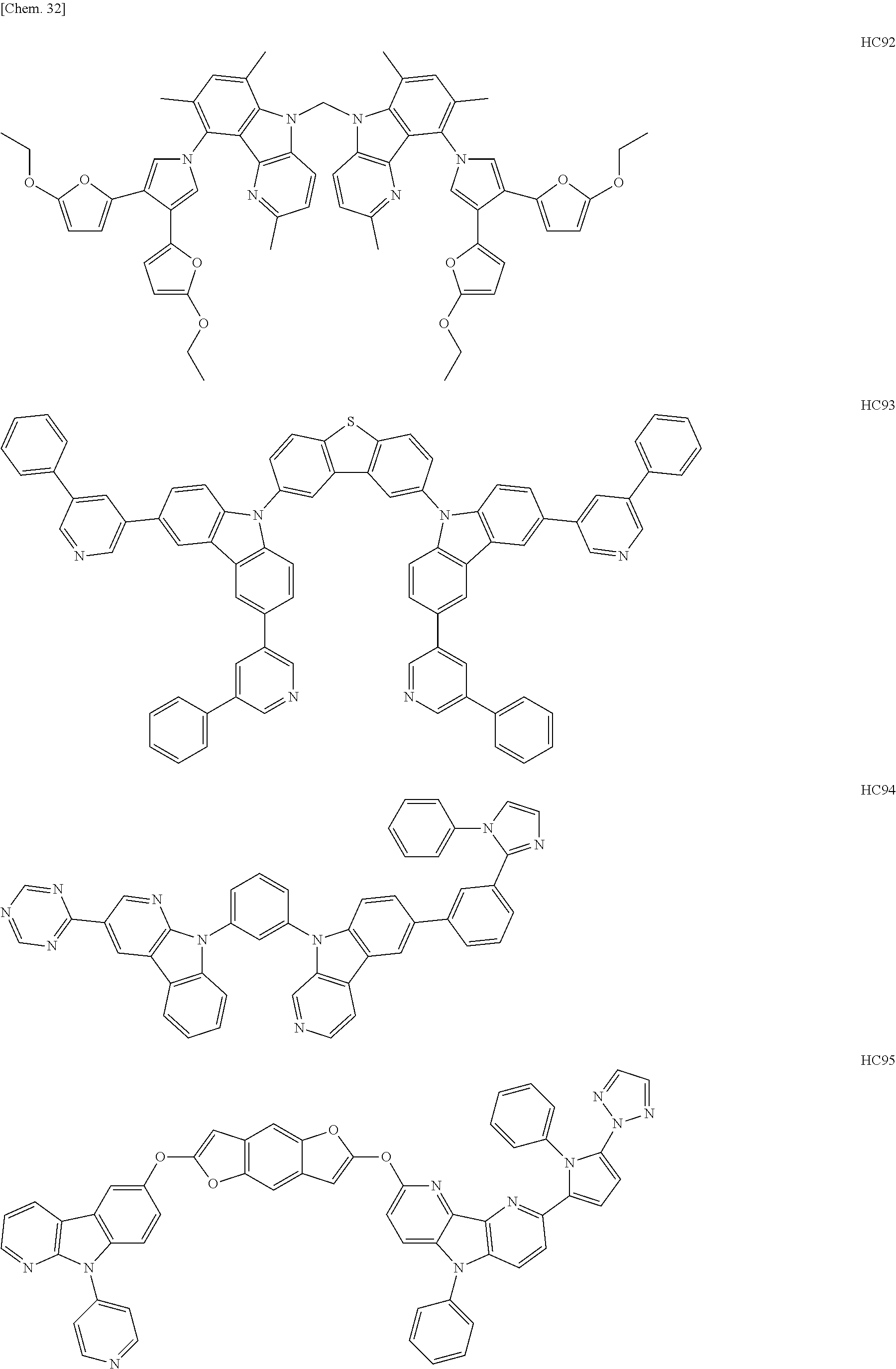

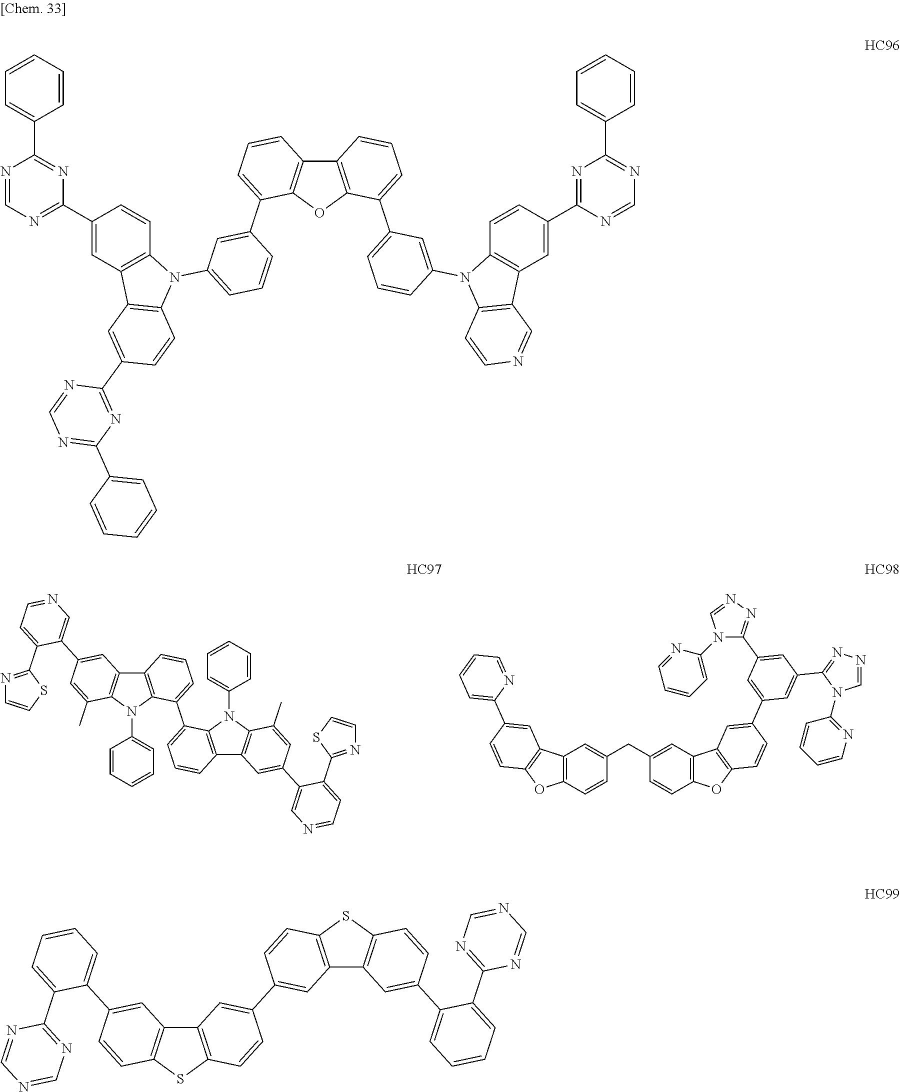

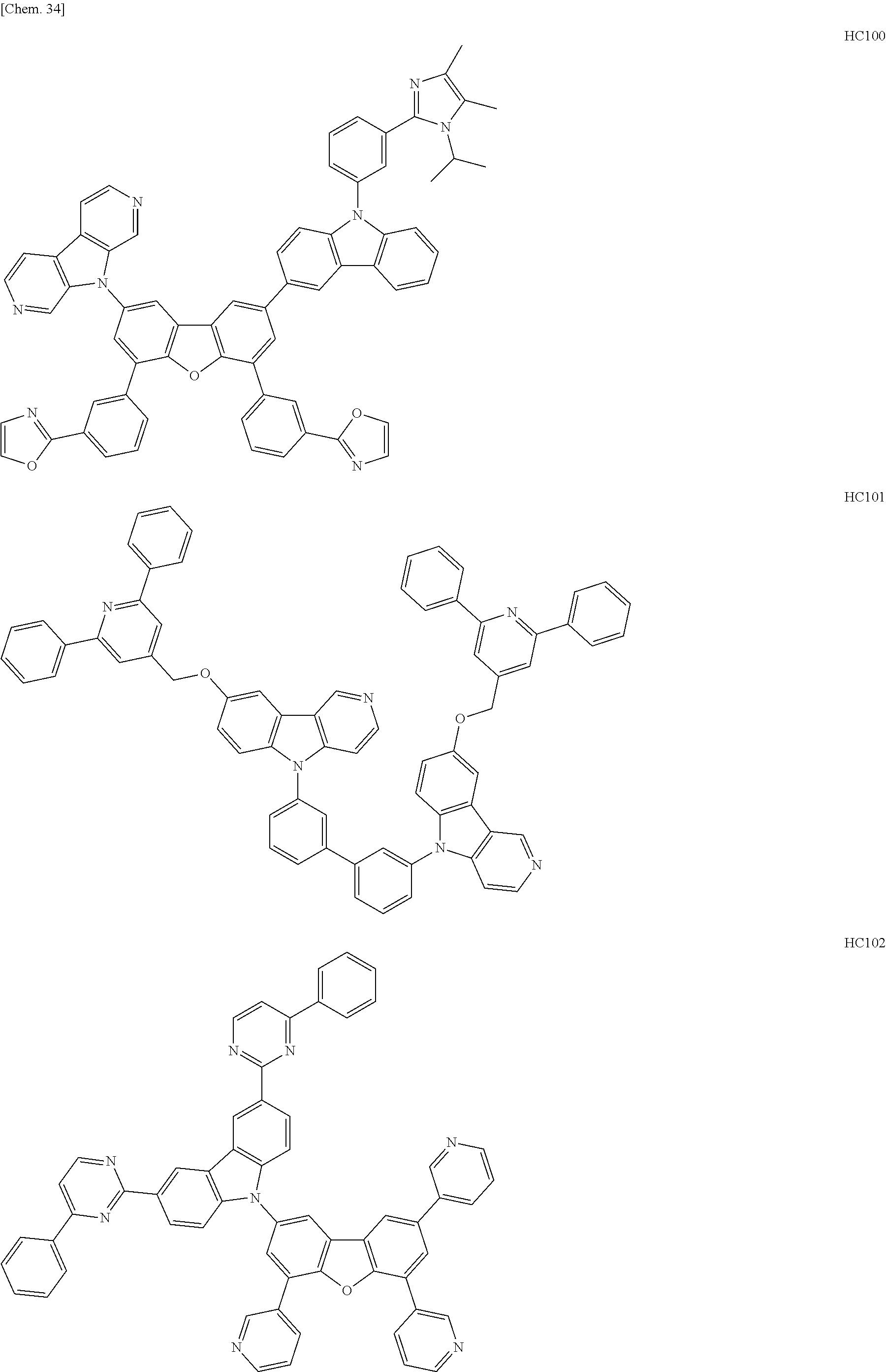

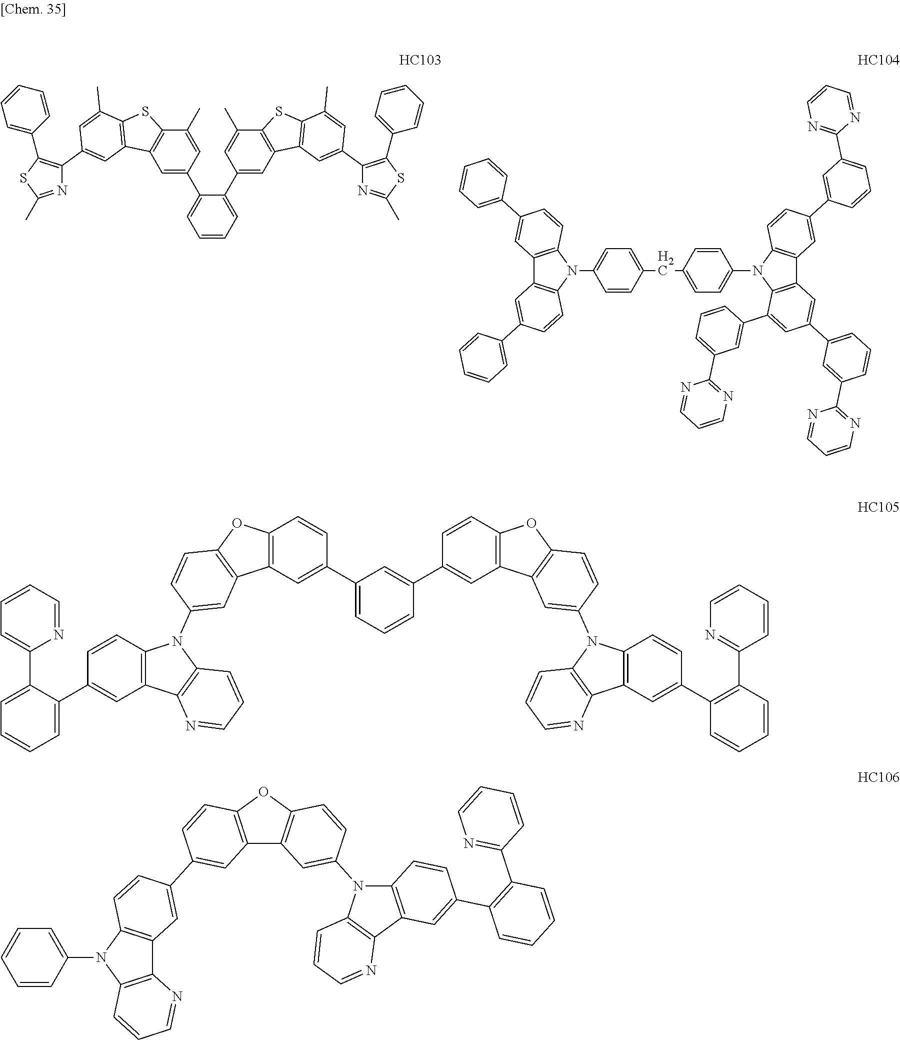

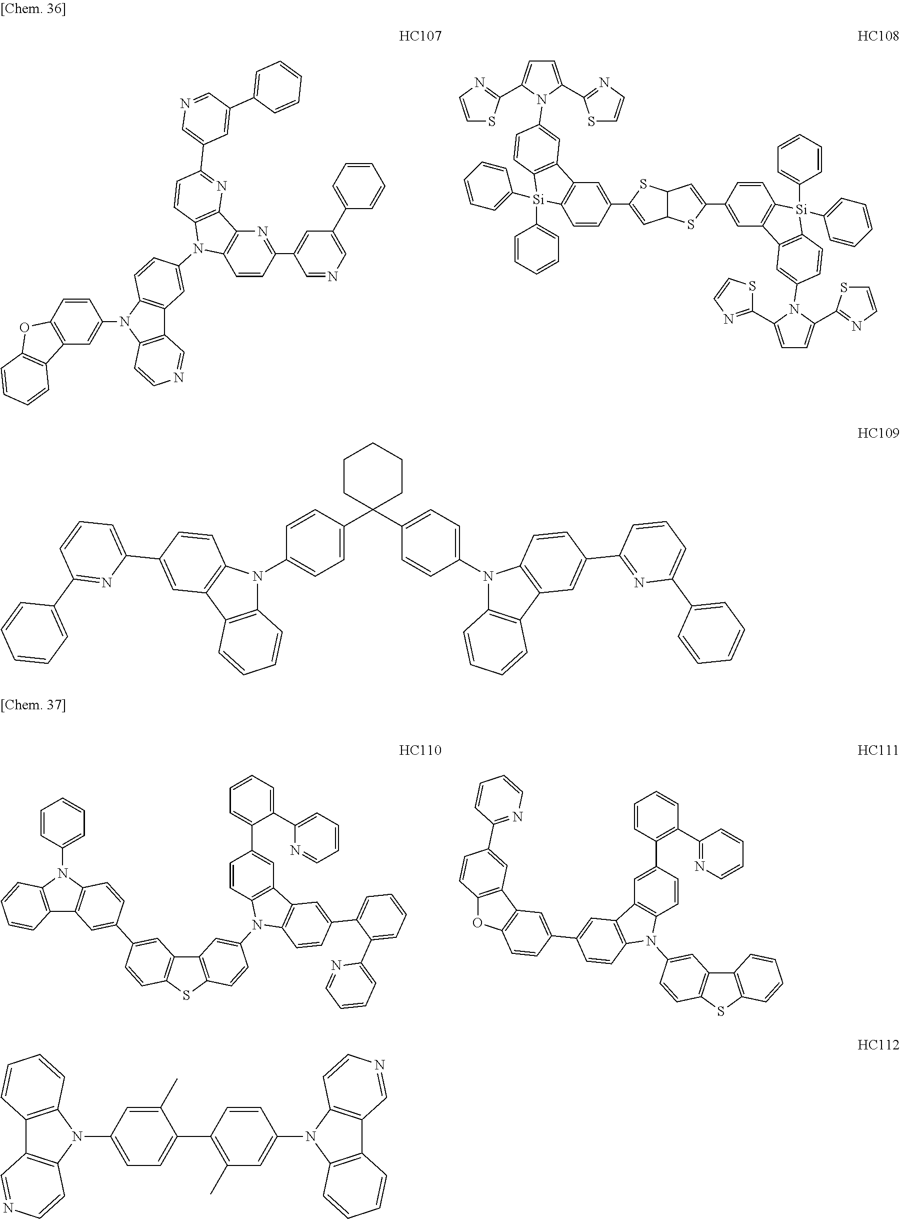

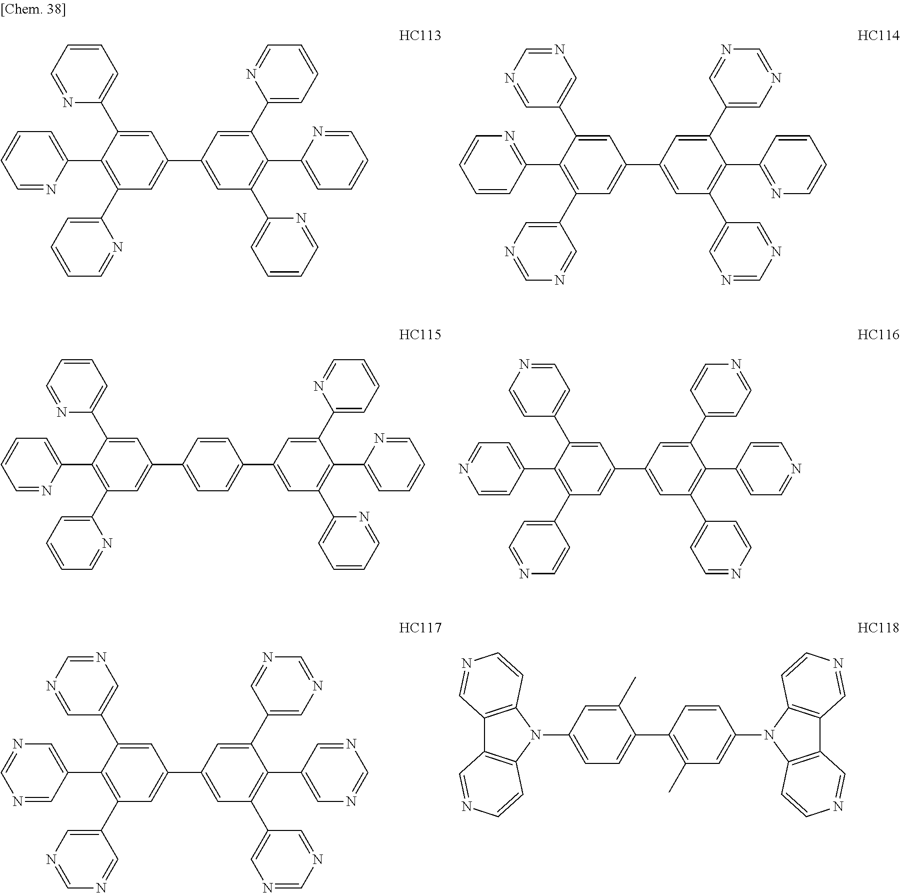

### Various Effects of Second Embodiment

As described above, the transparent conductive film 20 of the present embodiment has a configuration in which the heterocyclic compound layer 21 (the compound layer having a heterocyclic ring in which a nitrogen atom is used as a hetero atom) is provided between the modified compound layer 12 and the metal layer 13 formed of silver or an alloy containing silver as the main component. Therefore, in the transparent conductive film 20 of the present embodiment, the metal layer 13 of a uniform thin film (continuous film) can be formed, mainly by the interaction between the silver in the metal layer 13 and a compound having a nitrogen atom in the heterocyclic compound layer 21 in the process for forming the metal layer 13. Furthermore, since the transparent conductive film 20 of the present embodiment includes the modified compound layer 12 in the same way as in the first embodiment, the transparent conductive film 20 excellent in a water vapor barrier property can be obtained. That is, also in the present embodiment, the transparent conductive film 20 having all of excellent conductivity, light transmission property and a water vapor barrier property can be obtained in the same way as in the first embodiment.

Furthermore, in the configuration of the present embodiment, the main layer that bears a thin film growth action of the single layer growth type of the metal layer 13 is the heterocyclic compound layer 21, and as described above, the thickness thereof is preferably set to be about 1 nm to 500 nm, and it is preferable to further make the thickness thinner for the purpose of obtaining more excellent light transmission property. In the present embodiment, since the layer containing a silazane compound (the silazane compound layer 14 or the modified compound layer 12) is provided in the lower layer of the heterocyclic compound layer 21, the thickness of the heterocyclic compound layer 21 can be made thinner. For example, the heterocyclic compound layer 21 can have a thickness as very thin as about 1 nm to 10 nm.

Meanwhile, it is considered that, when the thickness of the heterocyclic compound layer 21 is made very thin as described above, the generation of defects and the like are generated in the layer weakens the interaction between the silver in the metal layer 13 and the compound having a nitrogen atom in the heterocyclic compound layer 21 and thus the maintenance of the thin film growth action of the single layer growth type of the metal layer 13 becomes difficult. However, actually, as will be explained in Example 1 later, even when the thickness of the heterocyclic compound layer 21 is set to be 5 nm (a transparent conductive film 5 to be described), excellent properties are obtained in both conductivity and light transmission property of the transparent conductive film. That is, it is known that the thin film growth action of the single layer growth type of the metal layer 13 is maintained even when the thickness of the heterocyclic compound layer 21 is made very thin and the uniform metal layer 13 (continuous film) is formed.

The cause thereof is presumed to be the fact that, in the formation process of the metal layer 13, an interaction arises between a compound having a nitrogen atom (such as a silazane compound or a silicon oxynitride compound) in the compound layer (the silazane compound layer 14 or the modified compound layer 12) provided in the lower portion of the heterocyclic compound layer 21 and the silver in the metal layer 13 in portions of a defect and the like in the heterocyclic compound layer 21, to thereby support the thin film growth of the single layer growth type of the metal layer 13. That is, it is considered that, when the thickness of the heterocyclic compound layer 21 is thin, the thin film growth of the single layer growth type of the metal layer 13 is maintained by the support function of the compound layer containing a nitrogen atom (the silazane compound layer 14 or the modified compound layer 12) provided in the lower portion of the heterocyclic compound layer 21 for the interaction and the above-described effect can be obtained.

Furthermore, by laminating the heterocyclic compound layer 21 on the compound layer (the silazane compound layer 14 or the modified compound layer 12), a pinhole in the compound layer can be repaired with the heterocyclic compound layer 21 by the interaction between a nitrogen atom in the compound layer and a nitrogen atom in the heterocyclic compound layer 21, and the penetration of water or oxygen can be suppressed more effectively.

Therefore, in the present embodiment, even when the thickness of the heterocyclic compound layer 21 is made very thin, the transparent conductive film 20 having all of excellent conductivity, light transmission property and water vapor barrier property can be obtained.

Furthermore, since the compound layer having a nitrogen atom (the silazane compound layer 14 or the modified compound layer 12) is provided in the lower layer of the heterocyclic compound layer 21, the heterocyclic compound layer 21 can be formed into a more uniform film even when the heterocyclic compound layer 21 is formed at a thin thickness on the compound layer. The cause thereof is presumed to be the fact that the affinity between the layer containing a silazane compound (the silazane compound layer 14 or the modified compound layer 12) and the heterocyclic compound layer 21 is high.

### 3. Third Embodiment

### Configuration Example of Electronic Device

As described above, the transparent conductive films in the first and second embodiments are excellent not only in conductivity and light transmission property but also in a water vapor barrier property, and can maintain stably the properties after bending. Therefore, the transparent conductive films of the first and second embodiments can be applied to various electronic devices.

Examples of the electronic device to which the transparent conductive films of the first and second embodiments are applicable include liquid crystal display elements (LCD), photovoltaics (PV), organic EL elements and the like. Furthermore, when the transparent conductive films of the first and second embodiments are to be applied to these electronic devices, the transparent conductive films can be used, for example, as a base material of an electronic device, a lower portion electrode member, a sealing member and an upper portion electrode member.

In a third embodiment, an organic EL element (an organic EL panel) will be included as an example of electronic devices, and an example in which the transparent conductive film 20 of the second embodiment is applied to the organic EL element will be explained. Meanwhile, the configuration of the electronic device of the present invention is not limited to the example, and for example, the transparent conductive film 10 of the first embodiment may be applied to an organic EL element.

[Configuration of Organic EL Element]

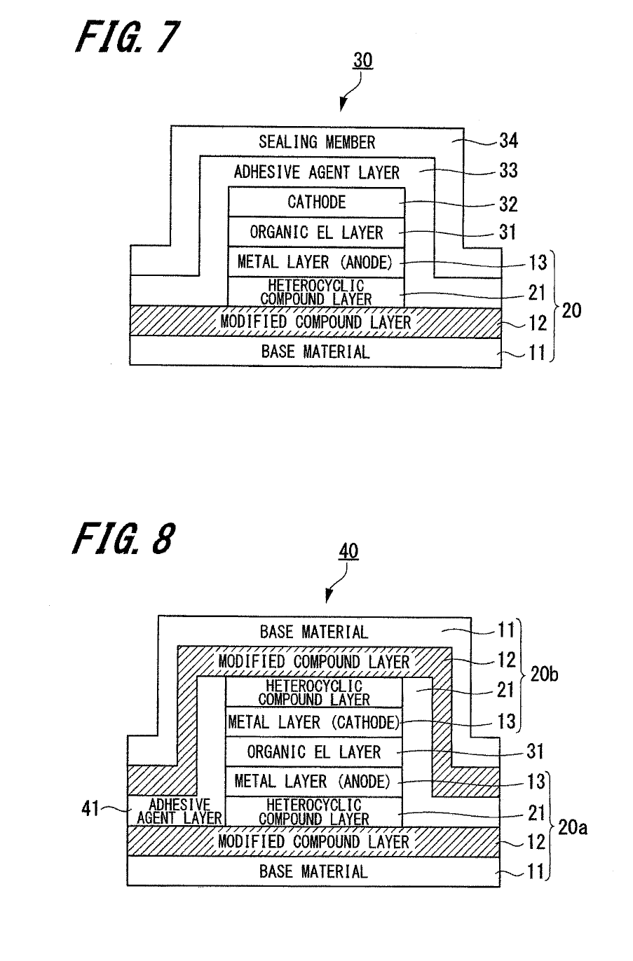

In FIG. 7, a schematic configuration cross-sectional view of the organic EL element according to the third embodiment is illustrated. Meanwhile, in an organic EL element 30 of the present embodiment illustrated in FIG. 7, the same reference sign is attached to the same configuration as that of the transparent conductive film 20 of the second embodiment illustrated in FIG. 5.

As illustrated in FIG. 7, the organic EL element 30 is provided with the base material 11, the modified compound layer 12, the heterocyclic compound layer 21, the metal layer 13, an organic EL layer 31, a cathode 32, an adhesive agent layer 33 and a sealing member 34. Meanwhile, although not illustrated in FIG. 7, a bleed-out preventing layer is provided on the surface on the modified compound layer 12 side of the base material 11 in the same way as in the second embodiment. Furthermore, although not illustrated in FIG. 7, the organic EL layer 31 is constituted by laminating various organic compound layers such as an emitting layer, a positive hole injection layer, a positive hole transport layer, an electron transport layer, and an electron injection layer, as will be described later.

In the organic EL element 30, the modified compound layer 12, the heterocyclic compound layer 21, the metal layer 13, the organic EL layer 31 and the cathode 32 are laminated in this order on the base material 11. That is, in the present embodiment, the transparent conductive film 20 formed of the base material 11, the modified compound layer 12, the heterocyclic compound layer 21 and the metal layer 13 is used as a base material with a lower portion electrode, and the organic EL layer 31 and the cathode 32 are laminated in this order on the transparent conductive film 20. In the configuration, the metal layer 13 of the transparent conductive film 20 acts as an anode.

In addition, in the organic EL element 30, a sealing member 34 is provided so as to cover the organic EL element main body formed of the metal layer 13, the organic EL layer 31 and the cathode 32, and the heterocyclic compound layer 21, via an adhesive agent layer 33 therebetween. In the example, therefore, the organic EL element main body formed of the metal layer 13, the organic EL layer 31 and the cathode 32 is sealed inside the organic EL element 30. Meanwhile, the sealing member 34 is not limited to the illustrated configuration of covering the side surfaces of the heterocyclic compound layer 21 to the cathode 32 and the upper surface of the cathode 32. The sealing member 34 may have a configuration of further covering up to the side surfaces of the adhesive agent layer 33 and the modified compound layer 12, or may have a configuration of being placed on the upper surface of the cathode 32 via the adhesive agent layer 33.

In the present embodiment, since the transparent conductive film 20 having a water vapor barrier property is used as a base material with a lower portion electrode, the deterioration of the organic EL element 30 due to water vapor can be further suppressed. Therefore, in the organic EL element 30 of the present embodiment, the lifetime thereof can be made longer.

### Modification 3

The configuration example of an organic EL element using the transparent conductive film 20 of the second embodiment is not limited to the example illustrated in FIG. 7. For example, the transparent conductive film 20 of the second embodiment may be used not only as the base material with a lower portion electrode but also as a base material with an upper portion electrode.

In FIG. 8, one configuration example thereof (modification 3) is illustrated. Meanwhile, FIG. 8 is a schematic configuration cross-sectional view of an organic EL element 40 of the modification 3. Furthermore, in an organic EL element 40 of the modification 3 illustrated in FIG. 8, the same reference sign is attached to the same configuration as that of the organic EL element 30 of the third embodiment illustrated in FIG. 7.

The organic EL element 40 of the example is provided with a first transparent conductive film 20a, a second transparent conductive film 20b, the organic EL layer 31 and an adhesive agent layer 41.

In addition, in the example, the first transparent conductive film 20a (the base material with a lower portion electrode) is provided on one surface of the organic EL layer 31 (the lower surface in FIG. 8), and the second transparent conductive film 20b (the base material with an upper portion electrode) is provided on the other surface of the organic EL layer 31 (the upper surface). At this time, the respective transparent conductive films are arranged so that the metal layer 13 of the first transparent conductive film 20a faces the metal layer 13 of the second transparent conductive film 20b with the organic EL layer 31 sandwiched therebetween, and that the respective metal layers 13 are in contact with the corresponding surfaces of the organic EL layer 31. Furthermore, in the configuration of the example, the metal layer 13 of the first transparent conductive film 20a acts as an anode, and the metal layer 13 of the second transparent conductive film 20b acts as a cathode.

Meanwhile, each of the first transparent conductive film 20a and the second transparent conductive film 20b has the same configuration as that of the transparent conductive film 20 explained in the second embodiment. Moreover, the adhesive agent layer 41 is provided between the first transparent conductive film 20a and the second transparent conductive film 20b so that the organic EL element main body formed of the metal layer 13 of the first transparent conductive film 20a (anode), the organic EL layer 31 and the metal layer 13 of the second transparent conductive film 20b (cathode), and the heterocyclic compound layers 21 of the respective transparent conductive films are sealed.

The organic EL element 40 of the configuration is produced, for example, in the following way. First, the organic EL layer 31 is formed on the metal layer 13 of one transparent conductive film. Subsequently, two transparent conductive films are bonded via the adhesive agent layer 41 so that the organic EL layer 31 formed on one transparent conductive film and the metal layer 13 of the other transparent conductive film contact with each other, and thus the organic EL element 40 of the example is produced.

In the configuration of the example, since the second transparent conductive film 20b having a water vapor barrier property is used not only as the base material with an upper portion electrode but also as a water vapor barrier base material or a sealing base material, the deterioration of the organic EL element due to water vapor can be further suppressed. Therefore, in the organic EL element 40 of the present embodiment, the lifetime thereof can be made longer. Furthermore, in the configuration of the example, since a process for providing separately a cathode on the organic EL layer 31 is not necessary, the process for manufacturing the organic EL element becomes simpler.

Meanwhile, the organic EL element main body of the organic EL element according to the present invention generally has, for example, a film configuration as described below. In film configurations (1) to (5) below, the layer configuration of the organic EL layer to be provided between the anode and the cathode varies from one another.

(1) anode/emitting layer/cathode

(2) anode/positive hole transport layer/emitting layer/cathode

(3) anode/emitting layer/electron transport layer/cathode

(4) anode/positive hole transport layer/emitting layer/electron transport layer (positive hole blocking layer)/cathode

(5) anode/positive hole injection layer (anode buffer layer)/positive hole transport layer/emitting layer/electron transport layer/electron injection layer (cathode buffer layer)/cathode

Here, the respective portions constituting the organic EL element main body will be explained in more detail.

[Anode (Metal Layer)]

In the present embodiment, the metal layer 13 formed of silver (Ag) or an alloy containing silver as the main component, provided on the transparent conductive film according to the present invention can be used as the anode. Meanwhile, in the present invention, since it is possible to cause the transparent conductive film to have a water vapor barrier property, when patterning previously the metal layer 13 in the manufacturing process of the transparent conductive film, the transparent conductive film can be applied to an organic EL element as it is, as an barrier base material with an electrode. Meanwhile, when the transparent conductive film of the present invention is applied to the cathode, an anode may be produced separately by a conventionally known technique.

[Cathode (Metal Layer)]

In the present embodiment, in the same way as in the anode, the metal layer 13 formed of silver (Ag) or an alloy containing silver as the main component provided on the transparent conductive film according to the present invention can be used as the cathode. Meanwhile, when the transparent conductive film of the present invention is applied to the anode, a cathode may be produced separately by a conventionally known technique.

The transparent conductive film of the present invention is excellent in light transmission property, and thus, as described above, may be applied to any of the cathode and the anode irrespective of the configuration of the organic EL element main body, and in particular, when the transparent conductive film of the present invention is applied to both of the cathode and anode, a device capable of extracting the light emitted in the emitting layer from both sides of the organic EL element can be produced.

[Injection Layer: Electron Injection Layer and Positive Hole Injection Layer]

Injection layers include an electron injection layer (cathode buffer layer) and a positive hole injection layer (anode buffer layer), and the electron injection layer and/or positive hole injection layer is provided appropriately in an organic EL element as necessary. Specifically, the positive hole injection layer is provided between the anode and the emitting layer, or between the anode and the positive hole transport layer. Furthermore, the electron injection layer is provided between the cathode and the emitting layer, or between the cathode and the electron transport layer.

The injection layer is a layer provided between the electrode and an organic layer (emitting layer, transport layer) for lowering a drive voltage or enhancing emission brightness. The detail of the injection layer is described in, for example, “Electrode Material” (pp 123 to 166) in the second chapter, second edition of “Organic EL Element and Forefront of Industrialization Thereof” (published by NTS INC., Nov. 30, 1998).

The detail of the positive hole injection layer (anode buffer layer) is described in, for example, Japanese Patent Application Laid-Open Nos. 09-45479, 09-260062, 08-288069 and the like. Specific examples of the positive hole injection layer include a phthalocyanine buffer layer represented by copper-phthalocyanine, an oxide buffer layer represented by vanadium oxide, an amorphous carbon buffer layer, a polymer buffer layer using a conductive polymer such as polyaniline (emeraldine) or polythiophene, and the like.

Moreover, the detail of the electron injection layer (cathode buffer layer) is described in, for example, Japanese Patent Application Laid-Open Nos. 06-325871, 09-17574, 10-74586 and the like. Specific examples of the electron injection layer include a metal buffer layer represented by strontium, aluminum or the like, an alkali metal compound buffer layer represented by lithium fluoride, an alkali earth metal compound buffer layer represented by magnesium fluoride, an oxide buffer layer represented by aluminum oxide and the like.

Meanwhile, the above-described various injection layers (buffer layer) each are preferably formed of a film having a very thin thickness. Specifically, the thickness of various injection layers is preferably about 0.1 nm to 5 although it differs depending on the formation material of various injection layers.

[Light Emitting Layer]

The emitting layer is a layer that emits light due to the recombination of an electron and a positive hole injected from each of the electrode (cathode, anode) and the transport layer (electron transport layer, positive hole transport layer), and the portion where light is emitted may be the inside of the emitting layer, or may be the interface between the emitting layer and an adjacent layer. Furthermore, from the viewpoint of further increasing the emission efficiency in the emitting layer, the incorporation of a dopant compound (light emitting dopant) and a host compound (light emitting dopant) in the emitting layer is preferable.

(1) Light Emitting Dopant

The light emitting dopant is roughly classified into two kinds of a fluorescent dopant that emits fluorescence and a phosphorescent dopant that emits phosphorescence.

As the fluorescent dopant, although not particularly limited, for example, coumarin-based dye, pyran-based dye, cyanine-based dye, croconium-based dye, squarium-based dye, oxobenzanthracene-based dye, fluorescein-based dye, rhodamine-based dye, pyrylium-based dye, perylene-based dye, stilbene-based dye, polythiophene-based dye, a rare earth complex-based fluorescent substance or the like can be used.

On the other hand, as the phosphorescent dopant, although not particularly limited, for example, a complex-based compound containing a metal of Group 8 to Group 10 of the periodic table of elements can be used. Among such complex-based compounds, the use of an iridium compound and/or an osmium compound as the phosphorescent dopant is preferable. In particular, in the present embodiment, the use of an iridium compound as the phosphorescent dopant is preferable. Furthermore, in the present embodiment, these light emitting dopants may be used alone or in combination of two or more kinds thereof.

(2) Light Emitting Dopant

The light emitting dopant means a compound having the largest mixing ratio (mass) in the light emitting layer containing 2 or more kinds of compounds, and other compounds are dopant compounds. For example, when a light emitting layer is formed of two kinds of compounds of a compound A and a compound B, and the mixing ratio thereof is A:B=10:90, the compound A is the dopant compound and the compound B is the host compound. Furthermore, for example, when a light emitting layer is formed of three kinds of compounds of a compound A, a compound B and a compound C, and the mixing ratio thereof is A:B:C=5:10:85, each of the compound A and the compound B is the dopant compound and the compound C is the host compound.

As the light emitting dopant, although not particularly limited, for example, a material having a basic skeleton such as a carbazole derivative, a triarylamine derivative, an aromatic borane derivative, a nitrogen-containing heterocyclic compound, a thiophene derivative, a furan derivative or an oligoarylene compound, or a carboline derivative, a diazacarbazole derivative (here, the diazacarbazole derivative represents one in which at least one carbon atoms of a hydrocarbon ring constituting a carboline ring of a carboline derivative is substituted with a nitrogen atom), or the like can be used. In the present embodiment, among these light emitting dopants, the use of a carboline derivative, a diazacarbazole derivative or the like as the light emitting dopant is preferable.

(3) Technique for Forming Light Emitting Layer

The light emitting layer can be formed at a thin thickness by film-forming the above-described compound through the use of a known technique such as a vacuum evaporation method, a spin coating method, a cast method, an LB (Langmuir-Blodgett) method or an inkjet method. Furthermore, the thickness of the light emitting layer is not particularly limited, and is usually set to be about 5 nm to 5 μm, and is preferably set to be about 5 to 200 nm. Meanwhile, in the present embodiment, it may also be possible to set the light emitting layer to have a one-layer structure and to incorporate one kind or two or more kinds of light emitting dopants and light emitting hosts, respectively, in the layer. Furthermore, in the present embodiment, the light emitting layer may be set to have a multilayer structure. Meanwhile, in this case, compositions of respective layers constituting the multilayer structure may be the same or may be different.

[Positive Hole Transport Layer]

The positive hole transport layer is formed of a positive hole transport material having a function of transporting positive holes, and a positive hole injection layer and an electron blocking layer are also included in the positive hole transport layer in the broad sense of the word. The positive hole transport layer may be constituted of one layer, or the positive hole transport layer may be provided in a plurality of numbers.

As to a material for forming the positive hole transport layer, an arbitrary material can be used as long as the material has any of injection capability of positive holes, transport capability of positive holes and barrier capability against electrons, and either an organic material or an inorganic material may be used.

Specifically, examples of the material for forming the positive hole transport layer include a triazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline-based copolymer, a conductive high molecular oligomer such as a thiophene oligomer, a porphyrin compound, an aromatic tertiary amine compound, a styrylamine compound, and the like. In the present embodiment, among these materials, the use of an aromatic tertiary amine compound as the positive hole transport material is preferable.

Furthermore, a polymer material having the above-described material introduced into the polymer chain, or a polymer material having the above-described material as the main chain of the polymer may be used as a material for forming the positive hole transport layer. Moreover, an inorganic compound such as p-type Si or p-type SiC may be used as the material for forming the positive hole transport layer.

The positive hole transport layer can be formed at a thin thickness by film-forming the above-described positive hole transport material through the use of a known technique such as a vacuum evaporation method, a spin coating method, a cast method, a printing method including an inkjet method or an LB (Langmuir-Blodgett) method. The thickness of the positive hole transport layer is not particularly limited, and is usually set to be about 5 nm to 5 μm, and is preferably set to be about 5 to 200 nm. Furthermore, when the positive hole transport layer is constituted of one layer, one kind or two or more kinds of the positive hole transport materials can be incorporated in the positive hole transport layer.

[Electron Transport Layer]

The electron transport layer is formed from an electron transport material having a function of transporting electrons, and an electron injection layer and a positive hole blocking layer are included in the electron transport layer in the broad sense of the word. The electron transport layer may be constituted of one layer, or the electron transport layer may be provided in a plurality of numbers.

Any material can be used as a material for forming the electron transport layer, as long as the material has a function of transmitting electrons injected from the cathode to the emitting layer, and for example, known compounds can be used.

Specifically, examples of the material for forming the electron transport layer include a nitro-substituted fluorene derivative, a diphenylquinone derivative, a thiopyrandioxide derivative, carbodiimide, a fluorenylidenemethane derivative, anthraquinodimethane, an anthrone derivative, an oxadiazole derivative, a thiadiazole derivative, a quinoxaline derivative, and the like. Furthermore, a polymer material having the above-described material introduced into the polymer chain, or a polymer material having the above-described material as the main chain of the polymer can also be used as the material for forming the electron transport layer.

Moreover, for example, a metal complex of an 8-quinolinol derivative may be used as a material for forming the electron transport layer. Meanwhile, examples of the metal complex of an 8-quinolinol derivative include tris(8-quinolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, bis(8-quinolinol) zinc (Znq) and the like, and metal complexes in which the center metals of these metal complexes have been replaced with In, Mg, Cu, Ca, Sn, Ga or Pb.

Other than these, for example, metal-free phthalocyanine or metal phthalocyanine, or a material in which a terminal thereof has been substituted by an alkyl group, a sulfonic acid group or the like may be used as the material for forming the electron transport layer. Furthermore, for example, an inorganic semiconductor such as n-type Si, n-type SiC or the like, which can also be the material for forming the positive hole injection layer, may be used as the material for forming the electron transport layer.

The electron transport layer can be formed at a thin thickness by film-forming the above-described electron transport material through the use of a known technique such as a vacuum evaporation method, a spin coating method, a cast method, a printing method including an inkjet method or an LB (Langmuir-Blodgett) method. The thickness of the electron transport layer is not particularly limited, and is usually set to be about 5 nm to 5 μm, and is preferably set to be about 5 to 200 nm. In addition, when the electron transport layer is constituted of one layer, one kind or two or more kinds of the electron transport material can be incorporated in the electron transport layer.

[Technique for Producing Organic EL Element Main Body and Organic EL Element]

Next, a technique for producing the organic EL element main body and an organic EL element will be described simply. Meanwhile, here, an example, in which the film configuration of the organic EL element main body is anode/positive hole injection layer/positive hole transport layer/emitting layer/electron transport layer/electron injection layer/cathode, will be explained.

First, the positive hole injection layer, the positive hole transport layer, the emitting layer, the electron transport layer and the electron injection layer are formed in this order on the metal layer (functions as the anode of the organic EL element) of the transparent conductive film of the present invention prepared as the base material with a lower portion electrode. At this time, an evaporation method, a wet process (spin coating method, cast method, inkjet method, printing method or the like) or the like can be used as a technique for forming each of organic compound thin films, as described above. Meanwhile, in the present embodiment, the use of any of a vacuum evaporation method, a spin coating method, an inkjet method and a printing method, which has advantages that a homogeneous film can be easily obtained and a pinhole hardly arises, as a technique for forming each of organic compound thin films is preferable. Furthermore, at this time, different techniques for forming film may be applied to every layer.

Meanwhile, when adopting an evaporation method as a technique for forming respective organic compound thin films, as to conditions of film formation, generally the boat heating temperature is set to be about 50 to 450° C., the vacuum degree is set to be about 10⁻⁶ to 10⁻² Pa, the evaporation rate is set to be about 0.01 to 50 nm/sec, the substrate temperature is set to be about −50 to 300° C., and the thickness of respective films is set to be about 0.1 nm to 5 μm, preferably from 5 to 200 nm, although they are varied depending on the kind or the like of the compound to be used.

Subsequently, after forming the various organic compound thin films on the metal layer of the transparent conductive film of the present invention by the above-described technique, a thin film formed of a prescribed material for forming the cathode is formed on the electron injection layer in a thickness of about 1 μm or less, preferably about 50 to 200 nm, for example, using a technique such as evaporation or sputtering and thus the cathode is formed. Thereby, the organic EL element main body is produced.

Then, for example, when manufacturing the organic EL element 30 of the configuration illustrated in FIG. 7 using the transparent conductive film including the organic EL element main body produced by the technique, the sealing member is further provided on the cathode via an adhesive agent layer and the like. Thereby, the organic EL element main body is sealed in the organic EL element (see FIG. 7) and thus the organic EL element 30 having the configuration illustrated in FIG. 7 is produced.

Meanwhile, in the production of the organic EL element main body, it is preferable to produce throughout from the positive hole injection layer to the cathode in one film formation chamber and in one vacuuming, but a laminated member may be taken out of the film formation chamber in the middle of the process and a different film formation technique may be provided. At this time, care such as carrying out the operation under dry inert gas or the like becomes necessary. Furthermore, in the present embodiment, the laminating order of respective layers may be reversed, and the electron injection layer, the electron transport layer, the emitting layer, the positive hole transport layer, the positive hole injection layer and the anode may be laminated in this order on the transparent conductive film of the present invention. In this case, the metal layer in the transparent conductive film of the present invention functions as the cathode of the organic EL element.

Further, for example, when producing the organic EL element 40 as illustrated in FIG. 8 using the transparent conductive film including the organic EL element main body produced by the technique, first, the first transparent conductive film of the present invention to be used as the base material with a lower portion electrode, and the second transparent conductive film of the present invention to be used as the base material with an upper portion electrode are prepared. Subsequently, on the metal layer (functions as the anode of the organic EL element) of the first transparent conductive film of the present invention, the positive hole injection layer, the positive hole transport layer, the emitting layer, the electron transport layer and the electron injection layer are formed in this order. Then, the first transparent conductive film and the second transparent conductive film are laminated via the adhesive agent layer so that the metal layer (functions as the cathode of the organic EL element) on the second transparent conductive film of the present invention contacts with the electron injection layer. Thereby, the organic EL element main body is sealed in the organic EL element (see FIG. 8) and thus the organic EL element 40 having the configuration illustrated in FIG. 8 is produced.

In causing a multicolor display device (organic EL panel) provided with the organic EL element produced as described above to emit light, the anode and the cathode are set to have plus and minus polarities respectively, and for example, emission is generated by applying a direct current of about 2 to 40 V between both electrodes. Meanwhile, the voltage to be applied may be an alternating voltage, and in this case, the waveform of the alternating voltage to be applied can be appropriately selected.

### 4. Various Examples

Next, the configuration and characteristics of various transparent conductive films (Example 1) and organic EL elements (Example 2) of the present invention having been actually produced will be explained.

### Example 1

### (1) Production of Base Material (See Table 1 Below)

First, the configuration of the base material used in various transparent conductive films to be explained below, and the technique for producing thereof will be explained. Meanwhile, in the transparent conductive film in Example 1, a resin base material having a smooth layer was used as the base material.

In Example 1, first, a polyester film with a thickness of 100 μm, having performed easy-adhesion processing on both surfaces of the base material (COSMOSHINE A4300: manufactured by Toyobo Co., Ltd.) was prepared as a resin base material. Subsequently, a UV (Ultra-Violet) curable type organic/inorganic hybrid hard coat material (OPSTAR (registered trademark) 27501: manufactured by JSR Corporation) was applied onto one surface of the resin base material. At this time, the coating amount of the UV curable type organic/inorganic hybrid hard coat material was adjusted so that the thickness of the film after drying becomes 4 μm.

Subsequently, the resin base material coated with the UV curable type organic/inorganic hybrid hard coat material was dried at 80° C. for 3 minutes. Then, the curing of the dried resin base material at 1.0 J/cm² by a high pressure mercury lamp under the air atmosphere formed the smooth layer. In the example, the resin base material having the smooth layer was produced in this way.

### (2) Production of Transparent Conductive Film 1

In the example, there was produced a transparent conductive film 1 obtained by having laminated the modified compound layer, the heterocyclic compound layer and the metal layer in this order, on the resin base material with the smooth layer. That is, in the example, the transparent conductive film having the configuration the same as that of the transparent conductive film 20 (FIG. 5) in the second embodiment was produced. Hereinafter, the technique for producing the transparent conductive film 1 will be explained.

(2-1) Preparation of Coating Liquid Containing Silazane Compound

In Example 1, polysilazane was used as a silazane compound. Then, in Example 1, a dibutyl ether solution of 20% by mass of perhydropolysilazane (PHPS) (AZ NN120-20: manufactured by AZ ELECTRONIC MATERIALS) and a solution containing 5% by mass of an amine catalyst (N,N,N′,N′-tetramethyl-1,6-diaminohexane) (AZ NAX120-20, manufactured by AZ ELECTRONIC MATERIALS) were mixed so that the content of the amine catalyst became 1.0% by mass relative to the concentration of perhydropolysilazane (PHPS), and thus a polysilazane-containing coating liquid was prepared.

(2-2) Formation of Silazane Compound Layer (Polysilazane-Containing Layer)

Next, the polysilazane-containing coating liquid prepared by the technique was applied onto the surface on the smooth layer side of the resin base material having the smooth layer produced by the technique, by a spin coating method. Subsequently, the resin base material coated with the polysilazane-containing coating liquid was dried at 80° C. for 1 minute. Therefore, a silazane compound layer (polysilazane-containing layer) having a dry thickness of 300 nm was formed on the surface on the smooth layer side of the resin base material having the smooth layer. Meanwhile, the boundary in measuring the thickness of the silazane compound layer was checked through the use of a cross-sectional photograph by a TEM (transmission Electron Microscope).

(2-3) Formation of Heterocyclic Compound Layer

Then, the resin base material including the silazane compound layer formed by the formation technique was fixed to a base material holder of a commercially available vacuum evaporation apparatus. Furthermore, among the above-described various specific examples of the heterocyclic compounds (among the structural formulae HC1 to HC118), the heterocyclic compound (hetero ring compound) represented by the structural formula HC10 was placed in a resistance heating boat formed of tantalum. In addition, the substrate holder and the heating boat were attached to a first vacuum chamber of the vacuum evaporation apparatus.

Moreover, after placing silver (Ag) in a resistance heating boat formed of tungsten, the heating boat was attached inside a second vacuum chamber. In the state, first, the pressure of the first vacuum chamber was reduced to 4×10⁻⁴ Pa.

After that, the heterocyclic compound was heated by supplying a power to the heating boat in which the heterocyclic compound represented by the structural formula HC10 was placed, and the heterocyclic compound was deposited on the silazane compound layer at an evaporation rate of 0.1 nm/sec to 0.2 nm/sec. Therefore, a heterocyclic compound layer having a thickness of 25 nm was formed on the silazane compound layer.

(2-4) Formation of Metal Layer (Thin Film Silver Layer)

Next, the resin base material obtained by forming the silazane compound layer and the heterocyclic compound layer was moved into the second vacuum chamber while maintaining the vacuum environment, and the pressure of the second vacuum chamber was reduced to 4×10⁻⁴ Pa. Subsequently, silver was heated by supplying a power to the heating boat in which the silver was placed, and the silver was deposited on the heterocyclic compound layer at an evaporation rate of 0.1 nm/sec to 0.2 nm/sec. Therefore, a metal layer of 8 nm in thickness (thin film silver layer) was formed on the heterocyclic compound layer.

(2-5) Formation of Modified Compound Layer (Polysilazane Modified Layer)

Then, the resin base material obtained by forming the silazane compound layer, the heterocyclic compound layer and the metal layer in this order was irradiated with the VUV (vacuum ultraviolet ray), and the modification treatment of the silazane compound layer (polysilazane-containing layer) generates the modified compound layer. The modification treatment corresponds to the second modification treatment in Table 1 below. Meanwhile, in the example, the modification treatment was performed so as to reach a state where the silazane compound and a compound having a siloxane bond generated by modifying the silazane compound coexisted inside the modified compound layer. In the example, the transparent conductive film 1 was produced in this way.

Meanwhile, in the irradiation treatment of VUV (vacuum ultraviolet ray) (modification treatment), a stage movable type xenon excimer irradiation apparatus (MECL-M-1-200: manufactured by M.D.Excimer, Inc.) was used as a vacuum ultraviolet ray irradiation apparatus. In addition, in the modification treatment, a sample was placed so that the space (Gap) between the excimer lamp and the sample became 3 mm and irradiation with the vacuum ultraviolet ray was performed under the following conditions (hereinafter, the irradiation condition is denoted by VUV-1).

Illuminance: 140 mW/cm² (wavelength 172 nm)

Stage temperature: 100° C.

Treatment environment: under dry nitrogen gas atmosphere

Oxygen concentration in treatment environment: 0.1%

Stage movable speed and number of times of conveyance: conveyed 12 times at 10 mm/sec

Accumulated amount of excimer light exposure: 5000 mJ/cm²

Furthermore, in the modification treatment, the irradiation time of the vacuum ultraviolet ray was adjusted by changing appropriately the movable speed of the movable stage. Furthermore, oxygen concentration at the time of the irradiation with the vacuum ultraviolet ray was adjusted by measuring the respective flow rates of nitrogen gas and oxygen gas to be introduced into an irradiation vessel, with a flow meter, and by using flow rate of gases (nitrogen gas/oxygen gas) to be introduced into the vessel.

### (3) Production of Transparent Conductive Film 2

In a transparent conductive film 2, the modification treatment (first modification treatment in Table 1) was carried out by irradiating not only the resin base material on which the silazane compound layer, the heterocyclic compound layer and the metal layer were formed in this order but also a laminated member before the formation of the heterocyclic compound layer on the silazane compound layer, with the vacuum ultraviolet ray. Meanwhile, as to the irradiation condition of the vacuum ultraviolet ray in the modification treatment (first modification treatment), in various conditions in the modification treatment of the transparent conductive film 1, only conditions of stage movable speed and number of times of conveyance, and the accumulated amount of excimer light exposure were changed as follows (hereinafter, the irradiation condition is denoted by VUV-2).

Stage movable speed and number of times of conveyance: conveyed 3 times at 10 mm/sec

Accumulated amount of excimer light exposure: 1500 mJ/cm²

Here, the transparent conductive film 2 was produced in the same way as in the production technique of the transparent conductive film 1 except for adding the modification treatment (first modification treatment). Meanwhile, here, the modification treatment in the production technique of the transparent conductive film 1 was carried out as the second modification treatment (irradiation condition was EUV-1).

### (4) Production of Transparent Conductive Film 3

In a transparent conductive film 3, a plasma treatment in the presence of oxygen was adopted in place of the irradiation treatment of the vacuum ultraviolet ray, as a modification treatment (second modification treatment in Table 1) to be performed on the resin base material on which the silazane compound layer, the heterocyclic compound layer and the metal layer were formed in this order. Meanwhile, the plasma treatment was carried out through the use of an oxygen plasma apparatus PC-300 manufactured by SAMCO Inc. The transparent conductive film 3 was produced in the same way as in the case of the transparent conductive film 1 except for changing the technique of the modification treatment.

### (5) Production of Transparent Conductive Film 4

In a transparent conductive film 4, a heating treatment (120° C., 30 minutes) was adopted in place of the irradiation of the vacuum ultraviolet ray, as the modification treatment (second modification treatment in Table 1) to be performed on the resin base material on which the silazane compound layer, the heterocyclic compound layer and the metal layer were formed in this order. The transparent conductive film 4 was produced in the same way as in the case of the transparent conductive film 1 except for changing the technique of the modification treatment. Meanwhile, in the example, the heating treatment (modification treatment) was performed so that almost the whole silazane compound layer became a modified state.

### (6) Production of Transparent Conductive Film 5

In the transparent conductive film 5, the thickness of the heterocyclic compound layer was set to be 5 nm. The transparent conductive film 5 was produced in the same way as in the case of the transparent conductive film 2 except for changing the thickness of the heterocyclic compound layer.

### (7) Production of Transparent Conductive Film 6

As to a transparent conductive film 6, the transparent conductive film 6 was produced in the same way as in the case of the manufacturing technique in the modification 1 explained in FIGS. 3A to 3C. Specifically, after forming the silazane compound layer and before forming the heterocyclic compound layer on the silazane compound layer, the modification treatment (first modification treatment in Table 1) was carried out by irradiating the silazane compound layer with the vacuum ultraviolet ray, and the modified compound layer was generated on the resin base material. Meanwhile, the irradiation condition of the vacuum ultraviolet ray in the modification treatment at this time was set to be the same irradiation condition (EUV-1) as that in the modification treatment (second modification treatment) of the transparent conductive film 1.

After that, the heterocyclic compound layer and the metal layer were formed in this order on the modified compound layer in the same way as in the transparent conductive film 1. In addition, in the transparent conductive film 6, the modification treatment was not performed on the resin base material on which the modified compound layer, the heterocyclic compound layer and the metal layer were formed in this order. In the example, the transparent conductive film 6 was produced in this way.

### (8) Production of Transparent Conductive Film 7

In a transparent conductive film 7, the transparent conductive film 7 was produced in the same way as in the case of the transparent conductive film 2 except for not having formed the heterocyclic compound layer.

### (9) Production of Transparent Conductive Films (Transparent Conductive Films 8 to 11) in Comparative Example 1

In the example, transparent conductive films 8 to 11 in Comparative Example 1 as described below were produced in order to compare characteristics with the transparent conductive films 1 to 7 according to the present invention.

(9-1) Transparent Conductive Film 8

In a transparent conductive film 8, a formation treatment of the silazane compound layer and a modification treatment of the silazane compound layer were not carried out. The transparent conductive film 8 was produced in the same way as in the case of the transparent conductive film 1 except for the above.

(9-2) Transparent Conductive Film 9

In a transparent conductive film 9, the thickness of the heterocyclic compound layer was set to be 100 nm. The transparent conductive film 9 was produced in the same way as in the case of the transparent conductive film 8 except for changing the thickness of the heterocyclic compound layer.

(9-3) Transparent Conductive Film 10

In a transparent conductive film 10, a metal layer constituted of an indium-tin oxide (ITO) film was formed directly on a smooth layer surface of the resin base material having a smooth layer, and a formation treatment of the silazane compound layer and the heterocyclic compound layer was omitted. Meanwhile, the thickness of the metal layer formed of an ITO film was set to be 100 nm.

(9-4) Transparent Conductive Film 11

In a transparent conductive film 11, a evaporated film constituted of silicon oxynitride (SiON) was formed in a thickness of 350 nm on a smooth layer surface of the resin base material having a smooth layer through the use of a plasma CVD apparatus, which was used as a barrier layer.

At this time, silane gas (flow rate: 7.5 sccm), ammonia gas (flow rate: 100 sccm) and nitrous oxide gas (flow rate: 50 sccm) were used as raw material gases. Furthermore, film formation conditions were set as follows. High-frequency power source: 27.12 MHz, distance between electrodes: 20 mm, substrate temperature at the time of film formation: 100° C., gas pressure at the time of film formation: 100 Pa.

After that, the first modification treatment (irradiation condition of EUV-2) was performed on the evaporated film, and then, the formation of the heterocyclic compound layer, the formation of the metal layer, and the second modification treatment (irradiation condition of EUV-1) of the evaporated film were carried out in this order. The transparent conductive film 11 was produced by the formation of the heterocyclic compound layer and the formation of the metal layer in the same way as in the case of the transparent conductive film 1.

### Evaluation of Characteristics of Transparent Conductive Films in Example 1

In the example, a sheet resistance value, light transmittance, and water vapor barrier property after a bending treatment were evaluated in terms of each of transparent conductive films 1 to 11 produced as described above.

(1) Evaluation of Sheet Resistance Value

In the evaluation of the sheet resistance value, the sheet resistance value of the metal layer of each of transparent conductive films was measured. The sheet resistance value was measured by a 4-terminal 4-probe method constant current application system through the use of a resistivity meter (MCP-T610, manufactured by Mitsubishi Chemical Corporation).

The sheet resistance value was evaluated in accordance with the standard described below.

A: sheet resistance value was less than 10 Ω/sq.

B: sheet resistance value was 10 Ω/sq. or more and less than a measurement limit value.

C: sheet resistance value was a measurement limit value or more.

(2) Evaluation of Light Transmittance

In the evaluation of light transmittance, the light transmittance at a wavelength of 550 nm was measured for each of transparent conductive films.

The light transmittance was evaluated in accordance with the standard described below.

A: the light transmittance was 70% or more.

B: the light transmittance was 50% or more and less than 70%.

C: the light transmittance was less than 50%.

(3) Evaluation of Water Vapor Barrier Property after Bending Treatment

In the evaluation, first, a bending treatment was performed on each of transparent conductive films. Specifically, an action of bending at an angle of 180 degrees so as to give a curvature of 10 mm of radius was repeated 100 times for each of transparent conductive films.

Subsequently, water vapor transmittance (WVTR) was measured for each of transparent conductive films after the bending treatment through the use of a calcium method. Then, on the basis of measurement results of the water vapor transmittance, the water vapor barrier property of each of transparent conductive films was evaluated. Meanwhile, in the evaluation, the water vapor barrier property of each of transparent conductive films after the bending treatment was measured by an apparatus and technique shown below.

(3-1) Measurement Apparatus of Water Vapor Transmittance

In the measurement of the water vapor transmittance, following vacuum evaporation apparatus and constant temperature and humidity oven were used.

Vacuum evaporation apparatus: vacuum evaporation apparatus JEE-400 manufactured by JEOL Ltd.

Constant temperature and humidity oven: Yamato Humidic Chamber IG47M

(3-2) Raw Materials of Cell for Evaluating Water Vapor Barrier Property

Raw materials of metal films provided in a cell for evaluating a water vapor barrier property were as follows.

Metal film that reacts with humidity and corrodes: calcium (granular)

Water vapor-impermeable metal film: aluminum (diameter of 3 to 5 mm, granular)

(3-3) Production of Cell for Evaluating Water Vapor Barrier Property

Next, a technique for producing a cell for evaluating a water vapor barrier property will be explained. First, through the use of a vacuum evaporation apparatus (vacuum evaporation apparatus JEE-400, manufactured by JEOL Ltd.), calcium was evaporated by masking regions other than a prescribed region (region in which a calcium film is required to be evaporated) of the surface on the metal layer side of each of transparent conductive films having been subjected to the bending treatment. At this time, on the surface on the metal layer side of each of transparent conductive films, the calcium film was provided in nine regions. Meanwhile, the size of formation region of each of calcium films was set to be 12 mm×12 mm. Furthermore, in the example, a metal evaporation source of calcium and a metal evaporation source of aluminum were provided separately in the vacuum evaporation apparatus, and the metal evaporation source of calcium was used in the evaporation treatment of a calcium film.

Subsequently, while maintaining the vacuum state, the mask was removed. Subsequently, aluminum was evaporated using the metal evaporation source of aluminum over the whole surface of the transparent conductive film on which the calcium film had been formed. Thereby, the calcium film was sealed with the aluminum film.

Subsequently, after the sealing treatment, the vacuum state was released, and promptly, quartz glass having a thickness of 0.2 mm and the transparent conductive film provided with the calcium film and the aluminum film were stuck to each other via an ultraviolet ray-curable resin (manufactured by Nagase ChemteX Corporation) under a dry nitrogen gas atmosphere. Meanwhile, at this time, the quartz glass and the transparent conductive film were stuck to each other so that the quartz glass and the aluminum film faced each other. Then, irradiation of the laminated member with ultraviolet rays cures the ultraviolet ray-curable resin for sealing. In the example, a cell for evaluating a water vapor barrier property was produced in this way.

(3-4) Calculation Method of Water Vapor Transmittance

The cell, produced as described above, for evaluating a water vapor barrier property of each of transparent conductive films was stored under high temperature and high humidity of 60° C. and 90% RH, and the amount of moisture having passed through the cell was calculated from the corrosion amount of the calcium film on the basis of the technique described in Japanese Patent Application Laid-Open No. 2005-283561. Then, at this time, the water vapor transmittance was calculated from the corrosion speed until the corrosion area of the cell became 1%, and on the basis of the calculated water vapor transmittance, the water vapor barrier property of each of transparent conductive films after the bending treatment was evaluated.

The water vapor barrier property was evaluated in accordance with the standard described below.

S: the water vapor transmittance was less than 0.003 g/(m²·24 h).

A: the water vapor transmittance was 0.003 g/(m²·24 h) or more and less than 0.01 g/(m²·24 h).

B: the water vapor transmittance was 0.01 g/(m²·24 h) or more and less than 0.1 g/(m²-24 h).

C: the water vapor transmittance was 0.1 g/(m²·24 h) or more.

(4) Evaluation Results

Configurations of the transparent conductive films 1 to 11 and various evaluation results are shown in Table 1 below. Meanwhile, the numeral in the column of “Number” in Table 1 below is a sample number of the transparent conductive films.

TABLE 1

| | Silazane compound | | Heterocyclic | | | | | | |
|---|---|---|---|---|---|---|---|---|---|
| | | First | compound | | Second | Sheet | Light | Water vapor | |
| | Config- | modification | layer | Metal | modification | resistance | transmission | barrier | |
| No. | uration | treatment | Thickness | layer | treatment | value | property | property | Content |
| 1 | PHPS | — | 25 nm | Ag | VUV-1 | A | A | A | Present |
| | | | | | | | | | invention |
| 2 | PHPS | VUV-2 | 25 nm | Ag | VUV-1 | A | A | S | Present |
| | | | | | | | | | invention |
| 3 | PHPS | — | 25 nm | Ag | Plasma | A | A | A | Present |
| | | | | | | | | | invention |
| 4 | PHPS | — | 25 nm | Ag | Heat | A | A | B | Present |
| | | | | | | | | | invention |
| 5 | PHPS | VUV-2 | 5 nm | Ag | VUV-1 | A | A | S | Present |
| | | | | | | | | | invention |
| 6 | PHPS | VUV-1 | 25 nm | Ag | — | A | A | S | Present |
| | | | | | | | | | invention |
| 7 | PHPS | VUV-2 | — | Ag | VUV-1 | B | A | A | Present |
| | | | | | | | | | invention |
| 8 | — | — | 25 nm | Ag | — | A | A | C | Comparative |
| | | | | | | | | | Example 1 |
| 9 | — | — | 100 nm | Ag | — | A | B | C | Comparative |
| | | | | | | | | | Example 1 |
| 10 | — | — | — | ITO | — | B | A | C | Comparative |
| | | | | | | | | | Example 1 |
| 11 | Evaporated | VUV-2 | 25 nm | Ag | VUV-1 | B | B | B | Comparative |
| | film | | | | | | | | Example 1 |

### <VUV-1>

Illuminance: 140 mW/cm² (wavelength: 172 nm)

Stage temperature: 100° C.

Treatment environment: under dry nitrogen atmosphere

Oxygen concentration in treatment environment: 0.1%

Stage movable rate and conveyance times: conveyed 12 times at 10 mm/sec

Accumulated amount of excimer light exposure: 5000 mJ/cm²

### <VUV-2>

Illuminance: 140 mW/cm² (wavelength: 172 nm)

Stage temperature: 100° C.

Treatment environment: under dry nitrogen atmosphere

Oxygen concentration in treatment environment: 0.1%

Stage movable rate and conveyance times: conveyed 3 times at 10 mm/sec

Accumulated amount of excimer light exposure: 1500 mJ/cm²

As is clear from Table 1, in all of the transparent conductive films 1 to 7 of the present invention, the obtained evaluation result of not only the sheet resistance value and the light transmittance but also the water vapor barrier property was at least “B”. On the other hand, in all of the transparent conductive films 8 to 10 in Comparative Example 1, the evaluation result of the water vapor barrier property was “C” (water vapor transmittance was high), and a transparent conductive film having an intended property was not able to be obtained. Furthermore, in the transparent conductive film 11 in Comparative Example 1, all evaluation results of the sheet resistance value, the light transmittance and the water vapor barrier property were “B.” From the result, it was confirmed that the transparent conductive film of the present invention was not only provided with high light transmittance and conductivity but also had an excellent property in the water vapor barrier property.

Moreover, it was known that in the transparent conductive films 1, 2, 3, 5, 6 and 7 of the present invention, which were in a state where the silazane compound and the compound having a siloxane bond coexisted inside the modified compound layer, the evaluation result of the water vapor barrier property was at least “A”, and that a more excellent water vapor barrier property was obtained as compared with in the transparent conductive film 4 of the present invention that was in a state where the compound having a siloxane bond was generated over approximately the whole inside of the modified compound layer.

Furthermore, in the transparent conductive films 1, 2, 3, 4, 5 and 6 in which the heterocyclic compound was formed, the evaluation result of the sheet resistance value and light transmission property was at least “A”, and good characteristics was exhibited as a transparent conductive film. Furthermore, it was known that in the transparent conductive films 2, 5 and 6 of the present invention, for which the modification treatment (first modification treatment) was executed by using the vacuum ultraviolet ray (VUV) before the formation of the metal layer and then the hetero compound layer was formed, the evaluation result of the water vapor barrier property was “S”, and a very excellent water vapor barrier property was obtained.

Meanwhile, although not exemplified here, as to the transparent conductive film of the present invention not provided with the heterocyclic compound layer (configuration in FIG. 1), the same result as the evaluation result in Example 1 was obtained. Furthermore, also in the case where the metal layer was formed by an alloy containing silver as the main component, the same result as the evaluation result in Example 1 was obtained.

### Example 2

In Example 2, an organic EL element was produced using any of the transparent conductive films 5, 8 and 10 produced in Example 1. Then, in Example 2, emission characteristics of produced various organic EL elements were evaluated.

### (1) Production of Organic EL Element 1

In an organic EL element 1, the transparent conductive film 5 produced in Example 1 was used as the base material with a lower portion electrode, and an organic EL element of the configuration illustrated in FIG. 7 was produced. In an organic EL element 1, first, the transparent conductive film 5 produced in Example 1 was cut into a size of 100 mm×80 mm. Subsequently, the cut transparent conductive film 5 was subjected to ultrasonic cleaning with isopropyl alcohol, and after that, the transparent conductive film 5 was dried with dry nitrogen gas. Then, the transparent conductive film 5 after the cleaning was fixed to a substrate holder of a commercially available vacuum evaporation apparatus.

Furthermore, 200 mg of a positive hole transport material represented by a general formula (5) below (α-NPD: triarylamine derivative) was thrown into a first molybdenum resistance heating boat. Moreover, 200 mg of a host compound represented by a general formula (6) below (CBP: carbazole derivative) was thrown into a second molybdenum resistance heating boat, and 100 mg of a dopant compound represented by a general formula (7) below (Ir-1: iridium compound) was thrown into a third molybdenum resistance heating boat. In addition, 200 mg of a positive hole blocking material represented by a general formula (8) below (BCP: bathocuproine) was thrown into a fourth molybdenum resistance heating boat, and 200 mg of an electron transfer material represented by a general formula (9) below (Alq3: aluminum quinolinol complex) was thrown into a fifth molybdenum resistance heating boat. Then, each of molybdenum resistance heating boat into which the corresponding material was thrown was fixed to the vacuum evaporation apparatus.

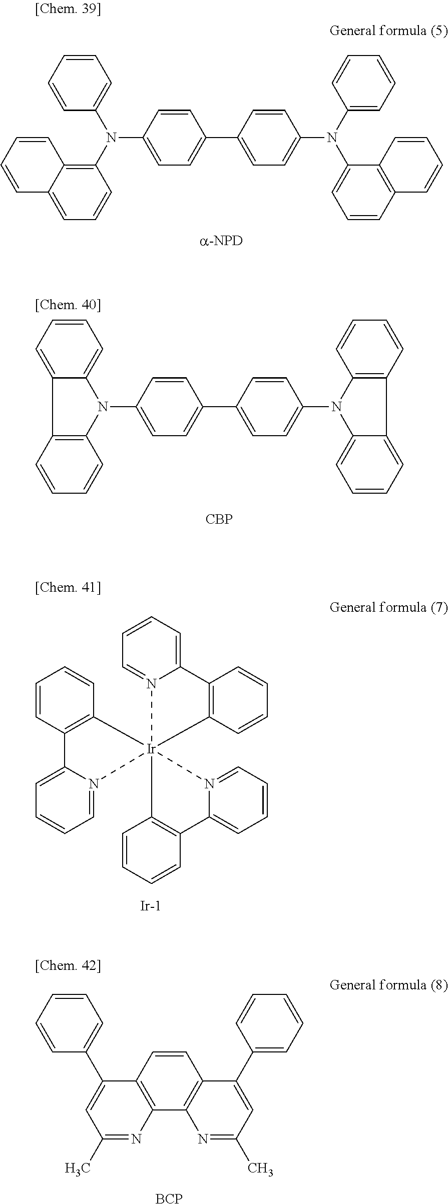

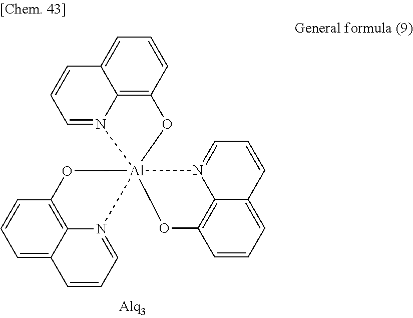

Next, the pressure of the vacuum chamber was reduced to 4×10⁻⁴ Pa, and after that, the positive hole transport material was heated by supplying power to the first molybdenum resistance heating boat in which the positive hole transport material (α-NPD) was charged, and the positive hole transport layer having a thickness of 30 nm was formed by evaporating the positive hole transport material on the metal layer of the transparent conductive film 5 at a evaporation rate of 0.1 nm/sec. Meanwhile, at this time, the positive hole transport layer was formed so that the positive hole transport layer is to be arranged in the center of the surface of the transparent conductive film 5, and the size of the formation region of the positive hole transport layer was set to be 80 mm×60 mm.

Subsequently, respective compounds were heated by supplying power to the second molybdenum resistance heating boat in which the host compound (CBP) was charged and to the third molybdenum resistance heating boat in which the dopant compound (Ir-1) was charged, and the emitting layer having a thickness of 70 nm was formed by co-evaporating the host compound (CBP) and the dopant compound (Ir-1) on the positive hole transport layer at the evaporation rate of 0.2 nm/sec and 0.012 nm/sec, respectively. Meanwhile, the temperature of the transparent conductive film 5 at the time of the evaporation was room temperature.

Then, the positive hole blocking material was heated by supplying power to the fourth molybdenum resistance heating boat in which the positive hole blocking material (BCP) was charged, and the positive hole blocking layer having a thickness of 10 nm was formed by evaporating the positive hole blocking material on the emitting layer at an evaporation rate of 0.1 nm/sec. Subsequently, the electron transport material was heated by supplying power to the fifth molybdenum resistance heating boat in which the electron transport material (Alq3) was charged, and an electron transport layer having a thickness of 40 nm was formed by evaporating the electron transport material on the positive hole blocking layer at an evaporation rate of 0.1 nm/sec. Meanwhile, the temperature of the transparent conductive film 5 at the time of the evaporation was room temperature.

After that, a lithium fluoride film having a thickness of 0.5 nm and an aluminum film having a thickness of 110 nm were formed in this order on the electron transport layer by an evaporation method and thus a cathode was formed. In the example, in this way, a film member (laminated member) in which the organic EL layer and the cathode were laminated in this order on the metal layer (anode) of the transparent conductive film 5 was produced.

Then, the film member produced by the technique was subjected to the following sealing treatment. First, the film member and the aluminum foil were arranged under an environment purged by nitrogen gas (inert gas) so that the surface on the aluminum film (cathode) side of the film member produced by the technique and one surface of an aluminum foil (sealing member) having a thickness of 100 μm in thickness faced each other. Next, the organic EL element was sealed by laminating the film member and the aluminum foil with an epoxy-based adhesive agent (manufactured by Nagase ChemteX Corporation) sandwiched therebetween. Meanwhile, at this time, both were laminated so that the width from each of end portions of 4 sides of the laminated member (organic EL element) to the organic EL element main body became about 10 mm. In the example, the organic EL element 1 was produced in this way.

### (2) Production of Organic EL Element 2

In an organic EL element 2, the transparent conductive film 5 produced in Example 1 was used as the base material with a lower electrode and as the base material with an upper electrode, and an organic EL element having the configuration illustrated in FIG. 8 was produced.

In the organic EL element 2, first, in the same way as in the organic EL element 1, the positive hole transport layer, the emitting layer, the positive hole blocking layer and the electron transport layer are formed in this order on the metal layer (silver thin film: anode) of one of the transparent conductive films 5. Subsequently, two transparent conductive films 5 were stuck to each other using a sealing agent (adhesive agent) so that the metal layer (silver thin film: cathode) of the other transparent conductive film 5 was in contact with the electron transport layer. In the example, the organic EL element 2 was produced in this way.

### (3) Production of Organic EL Element of Comparative Example 2

Here, the following organic EL elements 3 and 4 of Comparative Example 2 were produced for making a comparison between properties of the organic EL elements 1 and 2 according to the present invention.

(3-1) Organic EL Element 3

In an organic EL element 3, the transparent conductive film 8 produced in Comparative Example 1 was used as the base material with a lower portion electrode, and an organic EL element having the configuration illustrated in FIG. 7 was produced. Meanwhile, in the example, the organic EL element 3 was produced in the same way as in the organic EL element 1, except for changing the transparent conductive film used as the base material with a lower portion electrode.

(3-2) Organic EL Element 4 In an organic EL element 4, the transparent conductive film 10 produced in Comparative Example 1 was used as the base material with an electrode, and an organic EL element having the configuration illustrated in FIG. 7 was produced. Meanwhile, in the example, the organic EL element 4 was produced in the same way as in the organic EL element 1, except for changing the transparent conductive film used as the base material with an electrode.

### (4) Technique for Evaluating Properties of Organic EL Element

In Example 2, a dark spot was observed for each of the organic EL elements 1 to 4, and emission properties of each of the organic EL elements were evaluated on the basis of the observation result.

Specifically, first, the presence or absence of generation of the dark spot was checked before performing a bending treatment, for each of organic EL elements. Subsequently, the bending treatment was performed on each of the organic EL elements in the same way as the bending treatment performed on the transparent conductive film in Example 1. Then, the presence or absence of generation of the dark spot was observed for each of the organic EL elements after the bending treatment. Meanwhile, the presence or absence of generation of the dark spot was observed with eyes.

Then, properties of organic EL elements 1 to 4 were evaluated (dark spot evaluation) on the basis of the presence or absence of generation of the dark spot observed before and after the bending treatment. Meanwhile, the dark spot evaluation was carried out in accordance with the standard described below.

A: dark spot was not observed at all.

B: dark spot was observed.

C: light was not emitted.

### (5) Evaluation Results

The configurations and evaluation results of the organic EL elements 1 to 4 are shown in Table 2 below. Meanwhile, the numeral in the column “Element” in Table 2 below is a sample number of the organic EL element.

TABLE 2

| | Configuration of organic | | Emission property | | |
|---|---|---|---|---|---|
| | EL element | | Evaluation of dark spot | | |
| | Configuration of | | Before | After | |
| Ele- | electrode | | bending | bending | |
| ment | Anode | Cathode | treatment | treatment | Content |
| 1 | Transparent | Al | A | A | Present |
| | conductive | | | | invention |
| | film 5 | | | | |
| 2 | Transparent | Transparent | A | A | Present |
| | conductive | conductive | | | invention |
| | film 5 | film 5 | | | |
| 3 | Transparent | Al | C | C | Compar- |
| | conductive | | | | ative |
| | film 8 | | | | Example 2 |
| 4 | Transparent | Al | B | C | Compar- |
| | conductive | | | | ative |
| | film 10 | | | | Example 2 |

As is clear from Table 2, the dark spot evaluation result of each of the organic EL elements 1 and 2 of the present invention was “A” both before and after the bending treatment. On the other hand, the dark spot evaluation results of all of the organic EL elements 3 and 4 in Comparative Example 2 were “B” or less both before and after the bending treatment, and the organic EL elements 3 and 4 have poor bending properties, and stable emission properties were not able to be obtained. From the above results, it was known that, by using the transparent conductive film of the present invention as the base material with an electrode just like the organic EL element of the present invention, the element was resistant to the bending and was able to maintain stably good emission properties (element properties).

### REFERENCE SIGNS LIST

10, 20: transparent conductive film, 11: base material, 12: modified compound layer, 13: metal layer, 14: silazane compound layer, 15: modified compound layer, 20a: first transparent conductive film, 20b: second transparent conductive film, 21: heterocyclic compound layer, 30, 40: organic EL element, 31: organic EL layer, 32: cathode, 33, 41: adhesive agent layer, 34: sealing member

1. A method for manufacturing a transparent conductive film, comprising the steps of:
forming a compound layer comprising a silazane compound on a base material;
modifying the compound layer by supplying energy to the compound layer and by converting at least a part of the silazane compound into a compound having a siloxane bond; and
forming a metal layer that is formed of silver or an alloy comprising silver as a main component and that has transparency, on the compound layer before modification or on the compound layer after modification.

2. The method for manufacturing a transparent conductive film according to claim 1, wherein modification of the compound is carried out at least either before forming the metal layer or after forming the metal layer.

3. The method for manufacturing a transparent conductive film according to claim 1 or 2, wherein the silazane compound is polysilazane.

4. The method for manufacturing a transparent conductive film according to claim 3, wherein energy is given to the compound layer by any method of ultraviolet ray irradiation, plasma irradiation and heating.

5. The method for manufacturing a transparent conductive film according to claim 4, wherein the ultraviolet-ray irradiation is vacuum ultraviolet-ray irradiation.

6. The method for manufacturing a transparent conductive film according to claim 5, further comprising forming a heterocyclic compound layer having a heterocyclic ring including a nitrogen atom as a hetero atom between the compound layer and the metal layer.

7. (canceled)

8. A transparent conductive film comprising:
a base material;
a modified compound layer that is provided on the base material and that comprises a compound having a siloxane bond obtained by modifying a silazane compound; and
a metal layer that is provided on the modified compound layer, that is formed from silver or an alloy comprising silver as a main component and that has transparency.

9. The transparent conductive film according to claim 8, wherein the modified compound layer comprising a silazane compound and the compound having the siloxane bond.

10. The transparent conductive film according to claim 9, wherein the modified compound layer has a water vapor barrier property.

11. The transparent conductive film according to claim 10, further comprising a heterocyclic compound layer having a heterocyclic ring including a nitrogen atom as a hetero atom between the modified compound layer and the metal layer.

12. An electronic device, comprising a base material; a modified compound layer that is provided on the base material and that comprises a compound having a siloxane bond obtained by modifying a silazane compound; and a metal layer that is provided on the modified compound layer, that is formed from silver or an alloy comprising silver as a main component and that has transparency.

13. The method for manufacturing a transparent conductive film according to claim 1, wherein the silazane compound is polysilazane.

14. The method for manufacturing a transparent conductive film according to claim 1, wherein energy is given to the compound layer by any method of ultraviolet ray irradiation, plasma irradiation and heating.

15. The transparent conductive film according to claim 8, further comprising a heterocyclic compound layer having a heterocyclic compound including a nitrogen atom as a hetero atom between the modified compound layer and the metal layer.

16. The transparent conductive film according to claim 8, wherein the metal layer has a thickness of about 4 nm to 12 nm.

17. The electronic device according to claim 12, further comprising a heterocyclic compound layer having a heterocyclic compound including a nitrogen atom as a hetero atom between the modified compound layer and the metal layer.

18. The method for manufacturing a transparent conductive film according to claim 14, wherein the ultraviolet-ray irradiation is vacuum ultraviolet-ray irradiation.

19. The transparent conductive film according to claim 15, wherein the heterocyclic compound layer has a thickness of about 1 nm to 500 nm.

20. The transparent conductive film according to claim 19, wherein the metal layer has a thickness of about 4 nm to 9 nm.

21. The electronic device according to claim 17, wherein the heterocyclic compound layer has a thickness of about 1 nm to 500 nm and the metal layer has a thickness of about 4 nm to 9 nm.
